(19) United States
(12) Patent Application Publication
(10) Pub. No.: US 2020/0201176 A1
(43) Pub. Date: Jun. 25, 2020

(54) Resist Composition and Resist Pattern Forming Method

(71) Applicant: TOKYO ELECTRON LIMITED, Tokyo (JP)

(72) Inventors: Seiji NAGAHARA, Tokyo (JP); Gousuke SHIRAISHI, Kumamoto (JP); Congque DINH, Kumamoto (JP)

(21) Appl. No.: 16/718,377

(22) Filed: Dec. 18, 2019

(30) Foreign Application Priority Data
Dec. 19, 2018 (JP) 2018-237804

(51) Int. Cl. G03F 7/004

(52) U.S. Cl. CPC G03F 7/0045; G03F 7/162

(57) ABSTRACT

There is provided a resist composition including: a polymer component that is capable of being made soluble or insoluble in a developer by an action of an acid; an acid-generating agent configured to generate the acid by an exposure; and a quencher having a basicity for the acid, wherein, with respect to a first radiation having a wavelength of 300 nm or less and a second radiation having a wavelength of more than 300 nm, at least one of the acid-generating agent and the quencher has a light absorption wavelength, which is shifted so as to absorb the second radiation when irradiated with the first radiation and not irradiated with the second radiation, is decomposed when irradiated with the first radiation and then irradiated with second irradiation, and is not decomposed when not irradiated with the first irradiation and irradiated with the second radiation.

### CROSS-REFERENCE TO RELATED APPLICATION

This application is based upon and claims the benefit of priority from Japanese Patent Application No. 2018-237804, filed on Dec. 19, 2018, the entire contents of which are incorporated herein by reference.

### TECHNICAL FIELD

The present disclosure relates to a resist composition and a resist pattern forming method.

### BACKGROUND

As an elemental technique for manufacturing next-generation semiconductor devices, extreme ultraviolet (EUV) lithography is getting a lot of attention. The EUV lithography is a pattern forming technique using EUV light of a wavelength of 13.5 nm as an exposure light source. The EUV lithography has been demonstrated to be able to form an extremely fine pattern (for example, 20 nm or less) in an exposure step of a semiconductor device manufacturing process.

However, EUV light sources, which have been developed at the present, require a long time for the exposure treatment due to a low output, and therefore EUV lithography lacks practicability. To address this problem, a chemically amplified resist is expected as a leading resist material in EUV lithography (see, e.g., Japanese Patent Laid-Open Publication Nos. H05-173332 and H05-346668).

### PRIOR ART DOCUMENTS

### Patent Documents

(Patent Document 1) Japanese Patent Laid-Open Publication No. H05-173332

(Patent Document 2) Japanese Patent Laid-Open Publication No. H05-346668

However, conventional chemically amplified resists fail to obtain sufficient sensitivity to EUV light even when being used in EUV lithography. Moreover, the improvement in sensitivity to EUV light may result in deterioration in lithographic performance, such as resolution or line-width-roughness (LWR) of resist patterns.

### SUMMARY

According to one embodiment of the present disclosure, there is provided a resist composition including: a polymer component that is capable of being made soluble or insoluble in a developer by an action of an acid; an acid-generating agent configured to generate the acid by an exposure; and a quencher having a basicity for the acid, wherein, with respect to a first radiation having a wavelength of 300 nm or less and a second radiation having a wavelength of more than 300 nm, at least one of the acid-generating agent and the quencher has a light absorption wavelength, which is shifted so as to absorb the second radiation when irradiated with the first radiation and not irradiated with the second radiation, is decomposed when irradiated with the first radiation and then irradiated with second irradiation, and is not decomposed when not irradiated with the first irradiation and irradiated with the second radiation.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing a first embodiment of a resist pattern forming method using a resist composition according to the present disclosure.

FIG. 2 is a flowchart showing a second embodiment of the resist pattern forming method using the resist composition according to the present disclosure.

FIG. 3 is a schematic conceptual view graphically showing the absorptivity of a pattern- exposed portion and the absorptivity of an unexposed portion in a resist film.

FIG. 4A is a schematic conceptual view graphically showing an acid concentration distribution by a resist pattern forming method using a conventional resist composition; and FIG. 4B is a schematic conceptual view graphically showing an acid concentration distribution by the resist pattern forming method using the resist composition according to the present embodiment.

FIGS. 5A to 5C show cross-sectional views illustrating an example of a semiconductor device manufacturing method according to the first embodiment of the present disclosure, FIG. 5A being a cross-sectional view showing a resist pattern forming step, FIG. 5B being a cross-sectional view showing an etching step, and FIG. 5C being a cross-sectional view showing a resist pattern removing step.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Resist Composition>

A resist composition according to an embodiment of the present disclosure is directed to a composition (hereinafter, also referred to as a resist composition) which includes a polymer component that is soluble or insoluble in a developer by the action of an acid, an acid-generating agent which generates an acid by exposure, and a quencher having basicity for acid. Furthermore, with respect to a first radiation having a wavelength of 300 nm or less and a second radiation having a wavelength of more than 300 nm, at least one of the acid-generating agent and the quencher has a light absorption wavelength, which is shifted so as to absorb the second radiation when irradiated with the first radiation and not irradiated with the second radiation, is decomposed when irradiated with the first radiation and then irradiated with second irradiation, and is not decomposed when not irradiated with the first irradiation and irradiated with the second radiation. In the subject specification, at least one of the acid-generating agent and the quencher refers to either or both of the acid-generating agent and the quencher.

### [Polymer Component]

In the resist composition of the present embodiment, the polymer component is a component that is soluble or insoluble in a developer by the action of an acid. In the subject specification, the polymer represents a compound (polymer) obtained by polymerization of two or more monomers, and includes a copolymer obtained by polymerization of two or more kinds of monomers. The action of an acid represents at least one of a case where the acid functions as a reactant or a case where the acid functions as a catalyst.

An example of the polymer compound may include, but is not particularly limited to, a first polymer (hereinafter, also referred to as “polymer (A)”) having a structural unit (hereinafter, also referred to as “structural unit (I)”) including a group manifesting a polar group by the action of an acid (hereinafter, also referred to as “acid-dissociable group”). In addition, the composition may further include, as a polymer component other than the above polymer component, a second polymer (hereinafter, also referred to as “polymer (B)”) not having the structural unit (I).

The polymer (A) or polymer (B) may further have a structure unit containing a fluorine atom (hereinafter, also referred to as “structural unit (H)”), a structural unit (III) including a phenolic hydroxyl group, and a structural unit (IV) including a lactone structure, a cyclic carbonate structure, a sultone structure, or a combination thereof, and may further have other structural units other than the structural units (I) to (IV).

### (Polymer (A) and Polymer (B))

The polymer (A) is a polymer having the structural unit (I). The polymer (A) may further have the structural units (II) to (IV) or other structural units. The polymer (B) is a polymer different from the polymer (A). The polymer (B) may have the structural unit (II), and may have the structural units (III) and (IV), or other structural units other than the structural units (III) and (IV).

### (Structural Unit (I))

The structural unit (I) is a structural unit having an acid-dissociable group. The polymer (A) can further improve the sensitivity and lithographic performance of the respective resist composition by having the structural unit (I). Example of the structural unit (I) may include a structural unit represented by the following chemical formula (1) (hereinafter, also referred to as “structural unit (I-1)”), and a structural unit represented by the following chemical formula (2) (hereinafter, also referred to as “structural unit (I-2)”). In the following chemical formulas (1) and (2), groups represented by —CR^{A2}R^{A3}R^{A4} and —CR^{A6}R^{A7}R^{A8} are acid-dissociable groups.

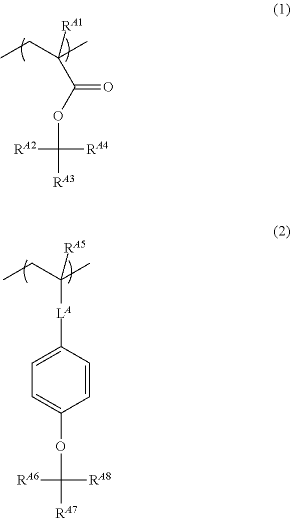

In the above chemical formula (1), R^{A1} represents a hydrogen atom, a fluorine atom, a methyl group, or a trifluoromethyl group. R^{A2} is a monovalent hydrocarbon group of 1 to 20 carbon atoms. R^{A3} and R^{A4} each independently represent a monovalent hydrocarbon group of 1 to 20 carbon atoms, or a cyclic structure of 3 to 20 ring atoms which is configured of R^{A3} and R^{A4} joined to each other, together with a carbon atom to which they are bound.

In the above chemical formula (2), R^{A5} is a hydrogen atom, a fluorine atom, a methyl group, or a trifluoromethyl group. R^{A6} represents a hydrogen atom, a monovalent hydrocarbon group of 1 to 20 carbon atoms, or a monovalent oxy hydrocarbon group of 1 to 20 carbon atoms. R^{A7} and R^{A8} each independently represent a monovalent hydrocarbon group of 1 to 20 carbon atoms or a monovalent oxy hydrocarbon group of 1 to 20 carbon atoms. L^{A} represents a single bond, —O—, —COO—, or —CONH—.

Examples of the monovalent hydrocarbon group of 1 to 20 carbon atoms represented by R_{A2}, R^{A6}, R^{A7}, and R^{A8} may include a monovalent chain hydrocarbon group of 1 to 30 carbon atoms, a monovalent alicyclic hydrocarbon of 3 to 30 carbon atoms, and a monovalent aromatic hydrocarbon group of 6 to 30 carbon atoms.

Examples of the monovalent chain hydrocarbon group of 1 to 30 carbon atoms may include: alkyl groups, such as a methyl group, an ethyl group, an n-propyl group, and an i-propyl group; alkenyl groups, such as an ethenyl group, a propenyl group, and a butenyl group; and alkynyl groups, such as an ethynyl group, a propynyl group, and butynyl group.

Examples of the monovalent alicyclic hydrocarbon group of 3 to 30 carbon atoms may include: saturated monocyclic hydrocarbon groups, such as a cyclopropyl group, a cyclobutyl group, a cyclopentyl group, a cyclohexyl group, a cyclooctyl group, a cyclodecyl group, and a cyclododecyl group; unsaturated monocyclic hydrocarbon groups, such as a cyclopropenyl group, a cyclobutenyl group, a cyclopentenyl group, a cyclohexenyl group, a cyclooctenyl group, and a cyclodecenyl group; saturated polycyclic hydrocarbon groups, such as a bicyclo[2.2.11]heptanyl group, a bicyclo[2.2.2]octanyl group, and a tricyclo[3.3.1.13,7]decanyl group; and unsaturated polycyclic hydrocarbon groups, such as a bicyclo[2.2.1]heptenyl group and a bicyclo[2.2.2]octenyl group.

Examples of the monovalent aromatic hydrocarbon group of 6 to 30 carbon atoms may include: aryl groups, such as a phenyl group, a tolyl group, a xylyl group, a mesityl group, a naphthyl group, a methylnaphthyl group, an anthryl group, and a methylanthryl group; and aralkyl groups, such as a benzyl group, a phenethyl group, a naphthylmethyl group, and an anthrylmethyl group.

R^{A2} may be a chain hydrocarbon group and a cycloalkyl group, specifically an alkyl group and a cycloalkyl group, more specifically a methyl group, an ethyl group, a propyl group, a cyclopentyl group, a cyclohexyl group, a cyclooctyl group, and an adamantyl group.

Examples of the monovalent chain hydrocarbon group of 1 to 20 carbon atoms and the monovalent alicyclic hydrocarbon group of 3 to 20 carbon atoms, each of which is represented by R^{A3} and R^{A4}, may include the same groups as exemplified in connection with R^{A2}, R^{A6}, R^{A7}, and R^{A8}.

Examples of the alicyclic structure of 3 to 20 ring atoms which is configured of R^{A3} and R^{A4} groups joined to each other together with a carbon atom to which they are bound, may include: monocyclic cycloalkane structures, such as a cyclopropane structure, a cyclobutane structure, a cyclopentane structure, a cyclopentene structure, a cyclopentadiene structure, a cyclohexane structure, a cyclooctane structure, and a cyclodecane structure; and polycyclic cycloalkane structures, such as a norbornane structure, an adamantane structure, a tricyclodecane structure, and a tetracyclododecane structure.

R^{A3} and R^{A4} may be an alkyl group, a monocyclic cycloalkane structure which is configured of R^{A3} and R^{A4} groups joined to each other, a norbornane structure, and an adamantane structure, more specifically a methyl group, an ethyl group, a cyclopentane structure, a cyclohexane structure, and an adamantane structure.

Examples of the monovalent oxy hydrocarbon group of 1 to 20 carbon atoms represented by R^{A6}, R^{A7}, and R^{A8} may include groups including an oxygen atom between carbon-carbon in those exemplified as the monovalent hydrocarbon group of 1 to 20 carbon atoms represented by R^{A2}, R^{A6}, R^{A7}, and R^{A8}.

R^{A6}, R^{A7}, and R^{A8} may be a chain hydrocarbon group, and an alicyclic hydrocarbon group including an oxygen atom.

L^{A} may be a single bond and —COO—, more specifically a single bond.

R^{A1} may be a hydrogen atom and a methyl group, more specifically a methyl group, in view of the copolymerization of monomers to give the structural unit (I).

R^{A5} may be a hydrogen atom and a methyl group, more specifically a hydrogen atom, in view of the copolymerization of monomers to give the structural unit (I).

Examples of the structural unit (I-1) may include structural units represented by the following chemical formulas (1-1) to (1-4) (hereinafter, also referred to as “structural units (I-1-a) to (I-1-d)”). Examples of the structural unit (I-2) may include a structural unit represented by the following chemical formula (2-1) (hereinafter, also referred to as “structural units (I-2-a)”).

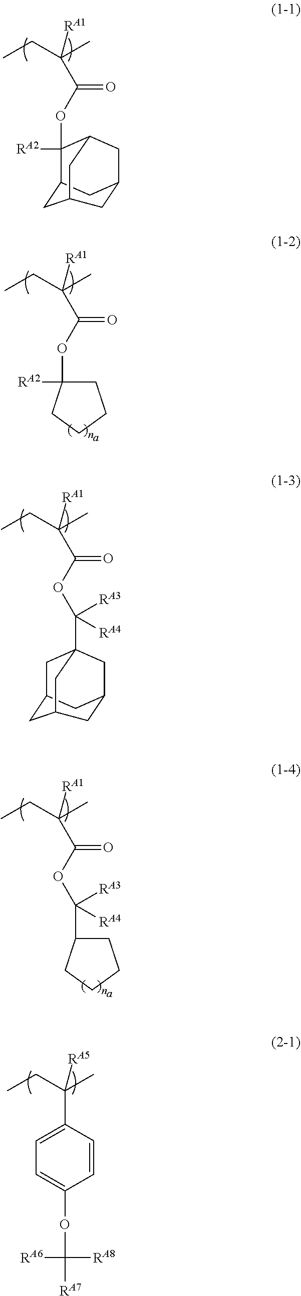

R^{A1} to R^{A4} in the above chemical formulas (1-1) to (1-4) are synonymous with the terms in the above chemical formula (1). nₐ represents an integer of 1 to 4. R^{A5} to R^{A8} in the above chemical formula (2-1) are synonymous with the terms in the above chemical formula (2).

nₐ may be 1, 2, and 4, specifically 1.

Examples of the structural units (I-1-a) to (I-1-d) may include structural units represented by the following chemical formulas (1-5) and (1-6).

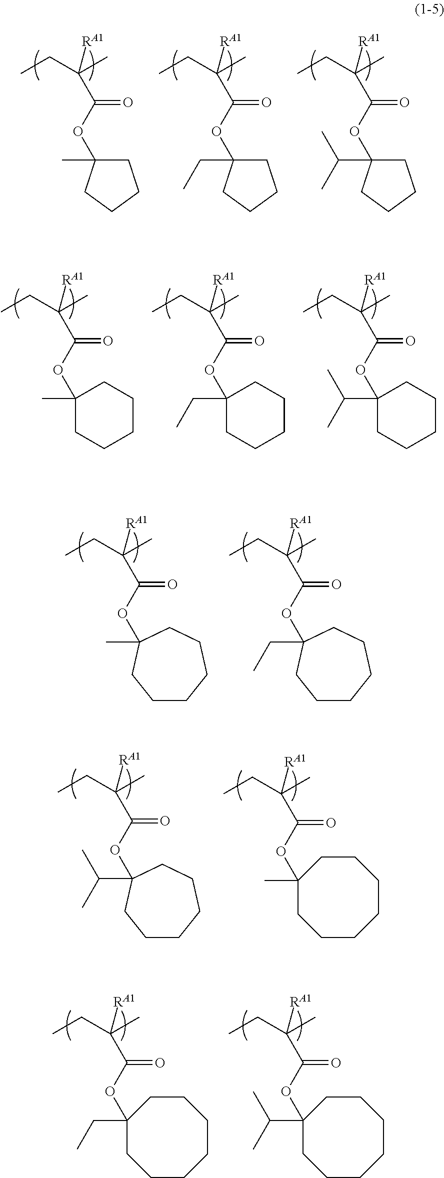

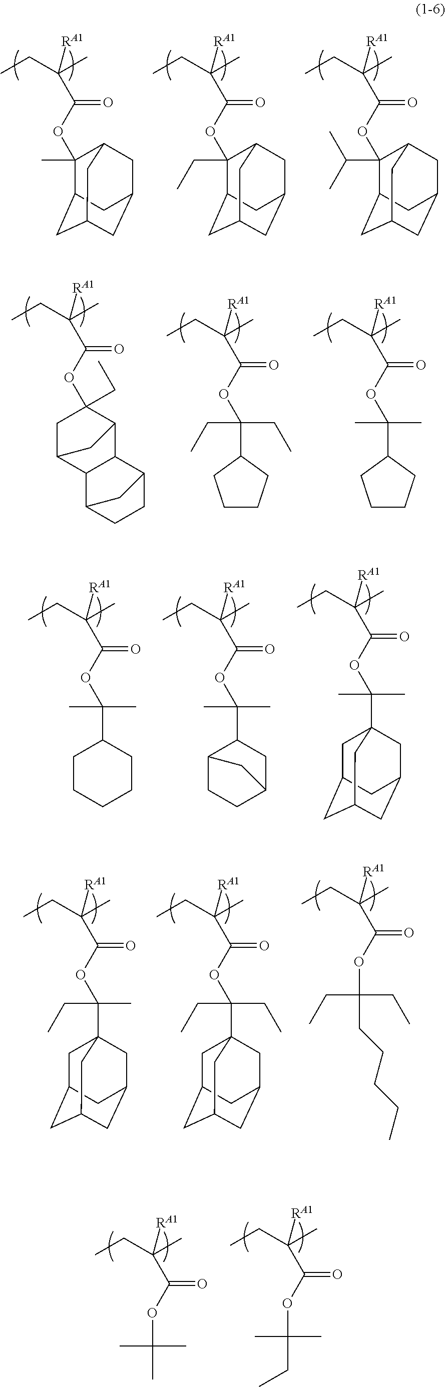

In the above chemical formulas, R^{A1} is synonymous with the term in the above chemical formula (1).

Examples of the structural unit (I-2-a) may include structural units represented by the following chemical formula (2-2).

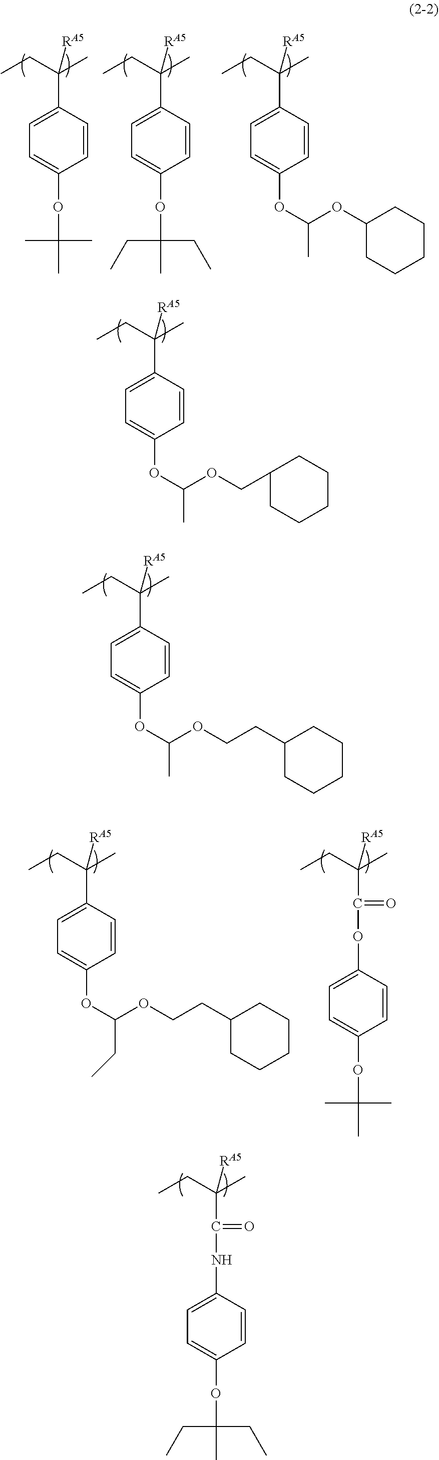

R^{A5} in the above chemical formula is synonymous with the term in the following chemical formula (2).

The structural unit (I) may be the structural units (I-1-a) to (I-1-d), more specifically a structural unit derived from 2-methyl-2-adamanthyl(meth)acrylate, a structural unit derived from 2-ipropyl-2-adamantyl(meth)acrylate, a structural unit derived from 1-methyl-1-cyclopenthyl(meth)acrylate, a structural unit derived from 1-ethyl-1-cyclohexyl(meth)acrylate, a structural unit derived from 1-ipropyl-1-cyclopenthyl(meth)acrylate, a structural unit derived from 2-cyclohexylpropan-2-yl(meth)acrylate, and a structural unit derived from 2-(adamantan-1-yl)propan-2-yl(meth)acrylate.

The lower limit of the proportion of the structural unit (I) relative to the total structural units constituting the polymer (A) may be 10 mol %, specifically 20 mol %, more specifically 25 mol %, most specifically 30 mol %. The upper limit of the proportion may be 80 mol %, specifically 70 mol %, more specifically 65 mol %, most specifically 60 mol %. By setting the proportion to the above ranges, a sufficient dissolution contrast between a pattern-exposed portion and an unexposed portion of a resist composition film formed of the respective resist composition can be ensured, leading to improved resolution.

### (Structural Unit (II))

The structural unit (II) is a structural unit having a fluorine atom (excluding the structural units corresponding to the structural unit (I)). The structural unit (II) does not include an ordinary salt structure.

In a case where the polymer (A) has the structural unit (II), the lower limit of the proportion of the structural unit (II) relative to the total structure units constituting the polymer (A) may be 3 mol %, specifically 5 mol %, more specifically 10 mol %. The upper limit of the proportion may be 40 mol %, specifically 35 mol %, more specifically 30 mol %. By setting the proportion to the above ranges, the sensitivity can be further improved when EUV or the like is used as a light for pattern exposure. Meanwhile, if the proportion exceeds the upper limit, the rectangularity of the cross-sectional shape of the resist pattern may be degraded.

In a case where the polymer component includes the polymer (B) and the polymer (B) has the structural unit (II), the lower limit of the proportion of the structural unit (II) relative to the total structure units constituting the polymer (B) may be 3 mol %, specifically 5 mol %, more specifically 10 mol %. The upper limit of the proportion may be 40 mol %, specifically 35 mol %, more specifically 30 mol %. By setting the proportion to the above ranges, the sensitivity can be further improved when EUV or the like is used as a light for pattern exposure. Meanwhile, if the proportion of the structural unit (II) exceeds the upper limit, the rectangularity of the cross-sectional shape of the resist pattern may be degraded.

### (Structural Unit (III))

The structural unit (III) is a structural unit having a phenolic hydroxy group (excluding the structural units corresponding to the structural units (I) and (II)). Since the polymer (A) or polymer (B) has the structural unit (III), the sensitivity can be further improved when KrF excimer laser light, extreme ultraviolet (EUV), an electron beam, or the like is irradiated in the pattern exposure step to be described later.

A part or all of hydrogen atoms included in an aromatic ring including the phenolic hydroxyl group may be substituted with a substituent. Examples of the substituent may include the same groups as exemplified in connection with R^{A5} and R^{A8}.

Examples of the structural unit (III) may include structural units represented by the following chemical formulas (3) to (8) (hereinafter, also referred to as “structural units (III-1) to (III-6)”).

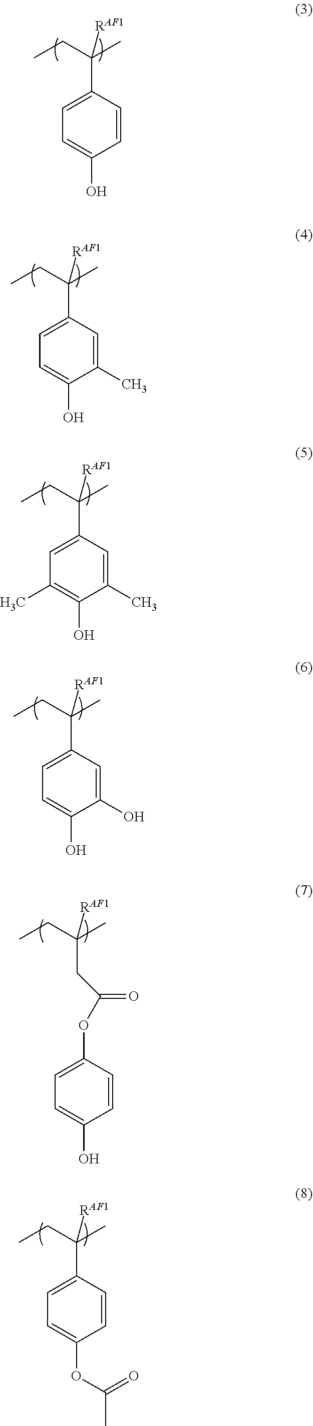

In the above chemical formulas (3) to (8), R^{AF1} is a hydrogen atom or a methyl group.

R^{AF1} may be a hydrogen atom.

The structural unit (III) may be the structural unit (III-1) and the structural unit (III-2), specifically the structural unit (III-1).

In a case where the polymer (A) has the structural unit (III), the lower limit of the proportion of the structural unit (III) relative to the total structure units constituting the polymer (A) may be 1 mol %, specifically 30 mol %, more specifically 50 mol %. The upper limit of the proportion may be 90 mol %, specifically 80 mol %, more specifically 75 mol %. By setting the proportion of the structural unit (III) to the above ranges, the sensitivity of the respective resist composition can be further improved.

In a case where the polymer component includes the polymer (B) and the polymer (B) has the structural unit (III), the lower limit of the proportion of the structural unit (III) relative to the total structure units constituting the polymer (B) may be 1 mol %, specifically 30 mol %, more specifically 50 mol %. The upper limit of the proportion may be 90 mol %, specifically 80 mol %, more specifically 75 mol %. By setting the proportion of the structural unit (III) to the above ranges, the sensitivity of the respective resist composition can be further improved.

In addition, the structural unit (III) may be formed by polymerizing a monomer, in which the hydrogen atom of the —OH group of the aromatic ring including a phenolic hydroxyl group is substituted with an acetyl group, and then subjecting the obtained polymer to a hydrolysis reaction in the presence of an amine.

### (Structural Unit (IV))

The structural unit (IV) is a structural unit having a lactone structure, a cyclic carbonate structure, a sultone structure, or a combination thereof (excluding the structural units corresponding to the structural units (I) to (III)). Since the polymers (A) and (B) further have the structural unit (IV), the solubility of the polymers in a developer can be adjusted more suitably. As a result, the lithographic performance of the respective resist composition can be further improved. Furthermore, the adhesion between a resist composition film formed of the respective resist composition and a substrate can be enhanced. Herein, the lactone structure refers to a structure having one ring (lactone ring) including a group represented by —O—C(O)—. The cyclic carbonate structure refers to a structure having one ring (cyclic carbonate ring) including a group represented by —O—C(O)—O—. The sultone structure refers to a structure having one ring (sultone ring) including a group represented by —O—S(O)₂—.

The structural unit (IV) may be a structural unit including a norbornene lactone structure, a structural unit including an oxanorbornane lactone structure, a structural unit including a γ-butyrolactone structure, a structure unit including an ethylene carbonate structure, and a structure unit including a norbornene sultone structure. More specifically, the structural unit (IV) may be a structural unit derived from norbornane lactone-yl(meth)acrylate, a structural unit derived from oxanorbornane lactone-yl(meth)acrylate, a structural unit derived from cyano-substituted norbornane lactone-yl(meth)acrylate, a structural unit derived from norbornane lactone-yloxycarbonylmethyl(meth)acrylate, a structural unit derived from butyrolacton-3-yl(meth)acrylate, a structural unit derived from butyrolacton-4-yl(meth)acrylate, a structural unit derived from 3,5-dimethylbutyrolacton-3-yl(meth)acrylate, a structural unit derived from 4,5-dimethylbutyrolacton-4-yl(meth)acrylate, a structural unit derived from 1-(butyrolacton-3-yl)cyclohexan-1-yl(meth)acrylate, a structural unit derived from ethylene carbonate-ylmethyl(meth)acrylate, a structural unit derived from cyclohexene carbonate-ylmethyl (meth) acrylate, a structural unit derived from norbornane sultone-yl(meth)acrylate, and a structural unit derived from norbornane sultone-yloxycarbonylmethyl(meth)acrylate.

In a case where the polymer (A) has the structural unit (IV), the lower limit of the proportion of the structural unit (IV) relative to the total structure units constituting the polymer (A) may be 1 mol %, specifically 10 mol %, more specifically 20 mol %, most specifically 20 mol %. The upper limit of the proportion may be 70 mol %, specifically 65 mol %, more specifically 60 mol %, most specifically 55 mol %. By setting the proportion to the above ranges, the adhesion between a resist film formed of the respective resist composition and a substrate can be further enhanced.

In a case where the polymer component includes the polymer (B) and the polymer (B) has the structural unit (IV), the lower limit of the proportion of the structural unit (IV) relative to the total structure units constituting the polymer (B) may be 1 mol %, specifically 10 mol %, more specifically 20 mol %, most specifically 25 mol %. The upper limit of the proportion may be 70 mol %, specifically 65 mol %, more specifically 60 mol %, most specifically 55 mol %. By setting the proportion to the above ranges, the adhesion between a resist film formed of the respective resist composition and a substrate can be further enhanced.

### [Other Structural Units]

The polymers (A) and (B) may have other structural units other than the structural units (I) to (IV). Examples of various structural units may include a structural unit including a polar group and a structural unit including a non-dissociable hydrocarbon group. Examples of the polar group may include an alcoholic hydroxyl group, a carboxy group, a cyano group, a nitro group, and a sulfone amide group. Examples of the non-dissociable hydrocarbon group may include a linear alkyl group. The upper limit of the proportion of the other structural units relative to the total structural units constituting the polymer (A) may be 20 mol %, specifically 10 mol %.

The lower unit of the total content of the polymers (A) and (B) may be 70 mass %, specifically 75 mass %, more specifically 80 mass % in the total solid content of the respective resist composition. The “total solid content” refers to components other than a solvent of the respective resist composition.

A polystyrene equivalent weight average molecular weight (Mw) of the polymer (A) as determined by gel permeation chromatography (GPC) is not particularly limited, but the lower limit thereof may be 1,000, specifically 2,000, more specifically 3,000, most specifically 5,000. The upper limit of the Mw of the polymer (A) may be 50,000, specifically 30,000, more specifically 20,000, most specifically 15,000. By setting the Mw of the polymer (A) to the above ranges, the applicability and the development defect inhibitory ability of the respective resist composition can be improved. If the Mw of the polymer (A) is smaller than the lower limit, a resist film having sufficient heat resistance may not be obtained. On the other hand, if the Mw of the polymer (A) is larger than the upper limit, the developability of a resin film may be degraded.

A ratio (Mw/Mn) of the Mw to the polystyrene equivalent number average molecular weight (Mn) of the polymer (A) as determined by GPC is ordinarily 1. The upper limit of the ratio is usually 5, but may be 3, specifically 2.

The polystyrene equivalent weight average molecular weight (Mw) of the polymer (B) as determined by the gel permeation chromatography (GPC) is not particularly limited, but the lower limit thereof may be 1,000, specifically 2,000, more specifically 2,500, most specifically 3,000. The upper limit of the Mw of the polymer (B) may be 50,000, specifically 30,000, more specifically 20,000, most specifically 15,000. By setting the Mw of the polymer (B) to the above ranges, the applicability and the development defect inhibitory ability of the respective resist composition can be improved. If the Mw of the polymer (B) is smaller than the lower limit, a resist film having sufficient heat resistance may not be obtained. On the contrary, if the Mw of the polymer (B) is larger than the upper limit, the developability of a resin film may be degraded.

The lower limit of the ratio (Mw/Mn) of the Mw to the polystyrene equivalent number average molecular weight (Mn) of the polymer (B) as determined by GPC may be 1. The upper limit of the ratio may be 5, specifically 3, more specifically 2.

Herein, the Mw and Mn of the polymer are determined using the gel permeation chromatography (GPC) under the following conditions.

GPC columns: G2000HXL x2, G3000HXL x1, G4000HXL x1 (manufactured by Tosoh Corporation)

Column temperature: 40 degrees C.

Elution solvent: tetrahydrofuran

Flow velocity: 1.0 mL/min

Sample concentration: 1.0 mass %

Amount of sample injected: 100 μL

Detector: differential refractometer

Standard substance: mono-dispersed polystyrene

The polymers (A) and (B) may contain a low-molecular-weight component having a molecular weight of 1,000 or less. The upper limit of the content of the low-molecular-weight component in the polymer (A) may be 1.0 mass %, specifically 0.5 mass %, more specifically 0.3 mass %. Examples of the lower limit of the content may include 0.01 mass %. By setting the content of the low-molecular-weight component in the polymers (A) and (B) to the above ranges, the lithographic performance of the respective resist composition can be further improved.

As used herein, the content of the low-molecular-weight component in the polymer corresponds to a value measured using high-performance liquid chromatography (HPLC) under the following conditions.

Column: “Inertsil ODA-25 μm column” (4.6 mmφ×250 mm) manufactured by GL Science corporation

Eluent: acrylonitrile/ 0.1 mass % phosphate aqueous solution

Flow rate: 1.0 mL/min

Sample concentration: 1.0 mass %

Amount of sample injected: 100 μL

Detector: differential refractometer

The lower limit of the proportion of fluorine atoms in the polymers (A) and (B) may be 1 mass %, specifically 2 mass %, more specifically 4 mass %, most specifically 7 mass %. The upper limit of the proportion may be 60 mass %, specifically 40 mass %, more specifically 30 mass %. The proportion (mass %) of fluorine atoms of the polymer can be calculated from the structure of the polymer, determined by 13C-NMR spectrum measurement.

### (Synthetic Method of Polymers (A) and (B))

The polymers (A) and (B) may be prepared by, for example, polymerizing the monomers corresponding to the respective structural units in an appropriate polymerization reaction solvent through the use of a polymerization initiator, such as a radical polymerization initiator. Specific examples of the synthetic method may include: a method of dropping a solution containing monomers and a radical polymerization initiator in a polymerization reaction solvent or a solution containing a monomer to cause a polymerization reaction; a method of dropping a solution containing monomers and a solution containing a radical polymerization initiator in a polymerization reaction solvent or a solution containing a monomer to cause a polymerization reaction; and a method of separately dropping plural kinds of solutions containing respective monomers and a solution containing a radical polymerization initiator in a polymerization reaction solvent or a solution containing a monomer to cause a polymerization reaction.

Examples of the radical polymerization initiator may include azo-based radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), and dimethyl 2,2′-azobisisobutyrate; and peroxide-based radical initiators, such as benzoyl peroxide, t-butyl hydroperoxide, and cumene hydroperoxide. Of these, the AIBN and the dimethyl 2,2′-azobisisobutyrate are preferable, and the AIBN is more preferable, as the radical polymerization initiator. These radical initiators may be used either alone, or as a mixture of two or more thereof.

Examples of the solvent for use in the polymerization include the same solvent that may be contained in the respective resist composition to be described later.

The lower limit of a reaction temperature in the polymerization may be 40 degrees C., specifically 50 degrees C. The upper limit of the reaction temperature may be 150 degrees C., specifically 120 degrees C. The lower limit of a reaction time in the polymerization may be 1 hour. The upper limit of the reaction time may be 48 hours, specifically 24 hours. The polymers (A) and (B) may be recovered by a reprecipitation technique. That is, after the completion of the reaction, a target polymer is recovered as a powder by adding a reaction solution to a reprecipitation solvent. As the reprecipitation solvent, alcohols or alkanes may be used either alone or as a mixture of two or more thereof. The polymer may be recovered by removing a low-molecular component, such as a monomer or an oligomer, through a separation manipulation, column manipulation, ultrafiltration, or the like, besides the reprecipitation technique.

### [Acid-Generating Agent]

In the resist composition of the present embodiment, the acid-generating agent is a component that generates an acid by exposure. Herein, the meaning that an acid is generated by exposure represents that an acid is generated by irradiating the acid-generating agent with radiation (active energy radiation), such as light or electron rays. The acid generated from the acid-generating agent can act on the above-described polymer component so that the respective polymer component is soluble or insoluble in a developer.

In the present embodiment, when the acid-generating agent is irradiated with a first radiation having a wavelength of 300 nm or less and not irradiated with a second radiation having a wavelength of more than 300 nm, the acid-generating agent has a light absorption wavelength, which can be shifted so as to absorb the second radiation.

Herein, the first radiation is energy radiation having a wavelength of 300 nm or less (e.g., extreme ultraviolet (EUV), etc.) The wavelength range of the first radiation is not particularly limited as long as the wavelength range of the first radiation is 300 nm or less, but the wavelength range of the first radiation may be 250 nm or less, specifically 200 nm or less.

The second radiation is energy radiation having a wavelength of 300 nm or less (e.g., ultraviolet (UV) excluding extreme ultraviolet (EUV), etc.) The wavelength range of the second radiation is not particularly limited as long as the wavelength of the second radiation exceeds 300 nm, but the wavelength range of the second radiation may be 500 nm or less, specifically 400 nm or less.

Herein, the meaning of the case of being irradiated with the first radiation and not irradiated with the second radiation represents a case of being irradiated with only the first radiation but not the second radiation. The meaning that the light absorption wavelength is shifted so as to absorb the second radiation represents that the maximum absorption wavelength with respect to a radiation is transited (or shifted) from a wavelength region of the first radiation to a wavelength region of the second radiation.

In addition, the acid-generating agent is decomposed when irradiated with the first radiation and then irradiated with the second radiation, and is not decomposed when not irradiated with the first radiation and irradiated with the second radiation. The meaning of a case of not being irradiated with the first radiation and irradiated with the second radiation represents a case of being irradiated with only the second radiation but not the first radiation. In addition, the meaning of a case of being irradiated with the first radiation and then irradiated with the second radiation represents a case of being irradiated with only the first radiation and then only the second radiation. The meaning that the acid-generating agent is decomposed represents that the acid-generating agent is transformed into two or more kinds of different components while generating an acid.

In the resist composition according to the present embodiment, the polarity of the acid- generating agent can be increased by the action of an acid. The meaning that the polarity is increased represents that the leaning of charges increases, resulting in an increase in hydrophilicity. Due to the increased polarity, the acid-generating agent is highly soluble in a hydrophilic developer, such as an organic alkaline solution but low soluble in a hydrophobic developer, such as an organic solvent.

In the resist composition according to the present embodiment, the acid-generating agent generates an acid when irradiated with the first radiation. In addition, the acid-generating agent does not generate an acid when not irradiated with the first radiation and irradiated with the second radiation.

That is, the acid-generating agent can generate an acid when irradiated with only the first radiation. In addition, the acid-generating agent can generate an acid when irradiated with only the first radiation and then irradiated with only the second radiation. In addition, the acid-generating agent cannot generate an acid when not irradiated with the first radiation and irradiated with only the second radiation.

That is, the acid-generating agent can generate an acid by irradiation with the first radiation before the light absorption wavelength of the acid-generating agent is shifted so as to absorb the second radiation. Meanwhile, the acid-generating agent can generate an acid by irradiation with the second radiation, after the light absorption wavelength of the acid-generating agent is shifted so as to absorb the second radiation.

In the resist composition according to the present embodiment, the acid-generating agent contains an onium compound, which is transformed into a carbonyl compound when irradiated with the first radiation. That is, the acid-generating agent contains an onium compound and is irradiated with only the first radiation, so that the respective onium compound can be transformed into a carbonyl compound. In addition, the carbonyl compound may be an onium compound, or a compound other than the onium compound.

In the resist compound according to the present embodiment, the onium compound contained in the acid-generating agent may include, but is not limited to, a compound represented by any one selected from the following chemical formulas (9), (10), (11), and (12).

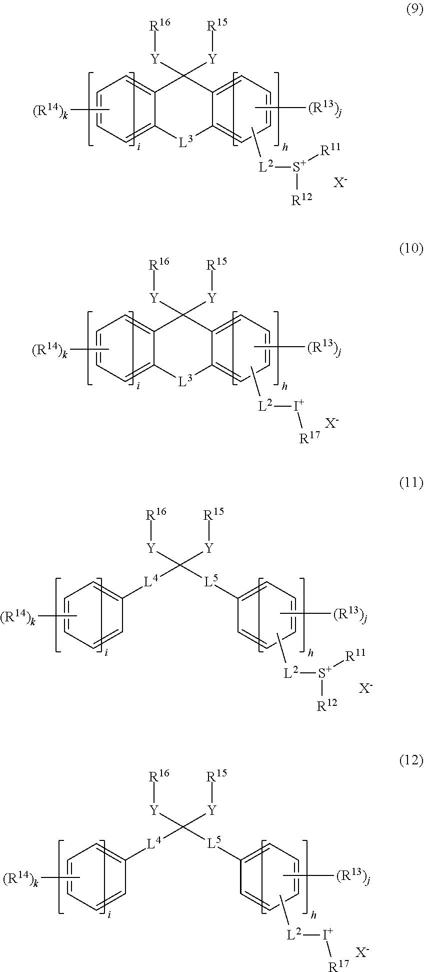

In the above chemical formula (9), R¹¹ and R¹² may be each independently any one selected from the group consisting of: a linear, branched, or cyclic alkyl group of 1 to 12 carbon atoms which may have a substituent; a linear, branched, or cyclic alkenyl group of 1 to 12 carbon atoms which may have a substituent; an aryl group of 6 to 14 carbon atoms which may have a substituent; and a heteroaryl group of 4 to 12 carbon atoms which may have a substituent.

Specific examples of the linear, branched, or cyclic alkyl group of 1 to 12 carbon atoms represented by R¹¹ and R¹² may include alkyl groups, such as a methyl group, an ethyl group, an n-propyl group, an n-butyl group, an isoprolyl group, a t-butyl group, a cyclopropyl group, a cyclobutyl group, a cyclopentyl group, a cyclohexyl group, an adamantan-1-yl group, an adamantan-2-yl group, a norbornan-1-yl group, and a norbornan-1-yl group.

In the alkyl group represented by each of R¹¹ and R¹², one divalent heteroatom-containing group selected from the group consisting of —O—, —CO—, —COO—, —COO—, —O—CO—O—, —NHCO—, —CONH—, —NH—CO—O—, —O—CO—NH—, —NH—, —N(R)—, —N(Ar)—, —S—, —SO—, and —SO₂—, instead of at least one methylene group, may be contained in skeleton. However, the sulfur atom (S⁺) of the sulfonium group may be bound to the divalent hydrocarbon group but not directly bound to the heteroatom-containing group. R and Ar will be described later.

The alkenyl group represented by R¹¹ and R¹² may be one in which at least one carbon- carbon single bond in the alkyl group is substituted with a carbon-carbon double bond.

Specific examples of the aryl group of 6 to 14 carbon atoms which may have a substituent, represented by R¹¹ and R¹², may include a monocyclic aromatic hydrocarbon group, and a condensed polycyclic aromatic hydrocarbon group in which at least two monocyclic aromatic hydrocarbons are condensed with each other. These aryl groups may have a substituent.

Examples of the monocyclic aromatic hydrocarbon group may include a group having a skeleton, such as benzene. Examples of the condensed polycyclic aromatic hydrocarbon group may include groups having skeletons, such as indene, naphthalene, azulene, anthracene, and penanthrene.

Examples of the heteroaryl group of 4 to 12 carbon atoms which may have a substituent, represented by R¹¹ and R¹², may be one which includes, in the skeleton thereof, instead of at least one carbon atom of the aryl group, at least one selected from an oxygen atom, a nitrogen atom, and a sulfur atom.

Examples of the heteroaryl group may include: a monocyclic aromatic heterocyclic group, or a condensed polycyclic aromatic heterocyclic group in which at least one monocyclic aromatic heterocyclic group is condensed with the aromatic hydrocarbon group or the aliphatic heterocyclic group. These aromatic heterocyclic groups may have a substituent.

Examples of the monocyclic aromatic heterocyclic group may include groups having skeletons, such as furan, pyrrole, imidazole, pyran, pyridine, pyrimidine, and pyrazine. Examples of the condensed polycyclic aromatic heterocyclic group may include groups having skeletons, such as indole, purine, quinoline, isoquinoline, chromene, phenoxazine, xanthene, acridine, phenazine, and carbazole.

Examples of the substituent which may be included in R¹¹ and R¹² (hereinafter, also referred to as “first substituent”) may include a hydroxy group, a cyano group, a mercapto group, a carboxy group, a carbonyl group, an alkoxy group (—OR), an acyl group (—COR), an alkoxycarbonyl group (—COOR), an aryl group (—Ar), an aryloxy group (—OAr), an amino group, an alkylamino group (—NHR), a dialkylamino group (—N(R)₂), an arylamino group (—NHAr), a diarylamino group (—N(Ar)₂), an N-alkyl-N-arylamino group (—NRAr), a phosphino group, a silyl group , a halogen atom, a trialkylsilyl group (—Si—(R)₃), a silyl group in which at least one alkyl group of the respective trialkylsilyl group is substituted with Ar, an alkylsulfanyl group (—SR), and an arylsulfanyl group (—SAr), but are not limited thereto. R and Ar will be described later.

In addition, the first substituent may be a group having a polymerizable group, such as a (meth)acryloyl group.

At least two of R¹¹, R¹², and an aryl group to which a sulfonium group is bound may be directly joined to each other by a single bond or may be joined to each other via any one selected from the group consisting of an oxygen atom, a sulfur atom, a nitrogen atom-containing group and a methylene group to thereby form a cyclic structure, together with a sulfur atom (S⁺) of the sulfonium group to which they are bound. However, the sulfur atom (S⁺) of the sulfonium group may be bound to the divalent hydrocarbon group but not directly bound to the heteroatom- containing group.

Examples of the “nitrogen-containing group” may include divalent groups containing a nitrogen atom, such as an aminodiyl group (—NH—), an alkylaminodiyl group (—NR—), or an arylaminodiyl group (—NAr—). R and Ar will be described later.

In the above chemical formula (9), the aryl group to which the sulfonium group is bound is a portion indicated by an arrow in the following chemical formula (9-1).

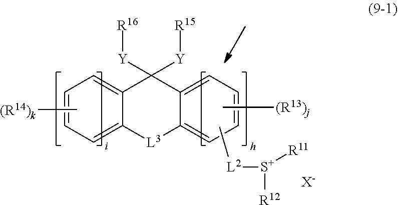

In the first substituent or the like, R may be an alkyl group of one or more carbon atoms. In addition, the number of carbon atoms may be 20 or less. Specific examples of the alkyl group of one or more carbon atoms may include: linear alkyl groups, such as a methyl group, an ethyl group, an n-propyl group, an n-butyl group, an n-pentyl group, an n-hexyl group, an n-octyl group, and an n-decyl group; branched alkyl groups, such as an isopropyl group, an isobutyl group, a tert-butyl group, an isopentyl group, a tert-pentyl group, and a 2-ethylexyl group; alicyclic alkyl groups, such as a cyclopropyl group, a cyclobutyl group, a cyclopentyl group, a cyclohexyl group, an adamantan-1-yl group, an adamantan-2-yl group, a norbornan-1-yl group, and a norbornan-2-yl group; silyl-substituted alkyl groups in which one hydrogen atom of these groups is substituted with a trialkylsilyl group, such as a trimethylsilyl group, a triethylsilyl group and a dimethylethyl silyl group; and alkyl groups in which at least one hydrogen atom of these groups is substituted with a cyano group or a fluoro group.

In the first substituent or the like, Ar may be an aryl group or a heteroaryl group. The heteroaryl group is an aryl group which contains at least one hetero atom in the cyclic structure. Specific examples of Ar may include ones having 20 or less of carbon atoms, such as a phenyl group, a biphenyl group, a terphenyl group, a quarter-phenyl group, a naphthyl group, an anthryl group, a phenanthrenyl group, a pentalenyl group, an indenyl group, an indasenyl group, an acenaphthyl group, a fluorenyl group, a heptalenyl group, a naphthacenyl group, a pyrenyl group, a chrysenyl group, a tetrasenyl group, a furanyl group, a thienyl group, a pyranyl group, a sulfanyl pyranyl group, a pyrrolyl group, an imidazolyl group, an oxazolyl group, a thiazolyl group, a pyrazoyl group, a pyridyl group, an isobenzofuranyl group, a benzofuranyl group, an isochromenyl group, a chromenyl group, an indolyl group, an isoindolyl group, a benzoimidazoyl group, a xanthenyl group, an aquadinyl group, and a carbazoyl group.

In a case where R¹¹ and R¹² have the first substituent and the onium salt is a low-molecular compound, the number of carbon atoms in R¹¹ and R¹², including carbon atoms of the first substituent, may be 1 to 20.

In an aspect of the present disclosure, the onium salt, as one unit of the resin, that is, as a unit including an onium salt structure, may be a polymer component, which binds to a portion of the polymer, or a polymer component included as a unit of the polymer. When the onium salt is a polymer component, the first substituent may be the main chain of the polymer. When the first substituent of R¹¹ and R¹² is the main chain of the polymer, the number of carbon atoms in the main chain of the polymer is excluded from the number of carbon atoms in R¹¹ and R¹². In one aspect of the present disclosure, when the onium salt is a polymer component, the weight average molecular weight of the total polymer components may be adjusted to 2,000 to 200,000. The low-molecular compound has a weight average molecular weight of less than 2,000. The polymer component has a weight average molecular weight of 2,000 or more.

R¹¹ and R¹² may be an aryl group in view of the improvement of stability.

R¹³ and R¹⁴ may be each independently any one selected from the group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom. In a case where each of R¹³ and R¹⁴ has carbon, each of R¹³ and R¹⁴ may have 1 to 12 carbon atoms and may have a substituent (hereinafter, also referred to as “second substituent”).

The alkyl group represented by R¹³ and R¹⁴ may be a linear, branched, or cyclic group. Specifically, the alkyl group may be the same as the alkyl group represented by R in the first substituent. The aryl group and heteroaryl group represented by R¹³ and R¹⁴ may be the same as the aryl group and heteroaryl group represented by Ar in the first substituent of R¹¹ and R¹².

The alkoxy group represented by R¹³ and R¹⁴ may be the same as the alkoxy group (—OR) in the first substituent. Examples of the hydroxy(poly)alkyleneoxy group represented by R¹³ and R¹⁴ may include a polyethyleneoxy group and a polypropyleneoxy group. Examples of the halogen atom represented by R¹³ and R¹⁴ may be a fluorine atom, a chlorine atom, and an iodine atom.

In the alkyl group represented by R¹³ and R¹⁴, the same group as the heteroatom-containing group in R¹¹ and R¹², instead of at least one methylene group, may be included in the skeleton. However, the alkyl group preferably does not have a consecutive connection of heteroatoms, such as —O—O—, —S—S—, and —O—S—.

The second substituent, which may be included in R¹³ and R¹⁴, may be the same as the first substituent. In a case where R¹³ and R¹⁴ have the second substituent and the onium salt is a low-molecular compound, the number of carbon atoms in R¹³ and R¹⁴, including carbon atoms of the second substituent, may be 1 to 12. In a case where the second substituent of R¹³ and R¹⁴ is the main chain of the polymer, the number of carbon atoms in the main chain of the polymer is excluded from the number of carbon atoms in R¹³ and R¹⁴.

R¹⁴ may be an alkyl group. Also, R¹⁴ may include electron-donating groups, such as an aryl group, an alkoxy group, an alkylsulfanyl group, an aryloxy group, an arylsulfanyl group, an amino group, and an alkylamino group, when these groups are located at the ortho- or para-position of the quaternary carbon binding to Y and the arylene having R¹⁴. These groups are preferable in view of improving the absorptivity at 365 nm.

R¹⁵ and R¹⁶ may be any one selected from the group consisting of: a linear, branched, or cyclic alkyl group of 1 to 12 carbon atoms which may have a substituent; a linear, branched, or cyclic alkenyl group of 1 to 12 carbon atoms which may have a substituent; an aryl group of 6 to 14 carbon atoms which may have a substituent; and a heteroaryl group of 4 to 12 carbon atoms which may have a substituent. These groups are selected from the same options as in R¹¹ and R¹². In addition, the substituent in R¹⁵ and R¹⁶ (hereinafter, also referred to as “third substituent”) may be the same as the first substituent.

R¹⁵ and R¹⁶ may be directly joined to each other by a single bond, or may be joined to each other via any one selected from the group consisting of an oxygen atom, a sulfur atom, and an alkylene group, thereby forming a cyclic structure. In view of synthesis, R¹⁵ and R¹⁶ may be identical to each other.

The quaternary carbon atom to which two Y's are directly bound and the two aryl groups (Ar^{a} and Ar^{b} indicated by arrows in the following chemical formula (9-2)) directly bound to the quaternary carbon atom form a five-membered ring structure by a direct bond between two aryl groups directly bound to the quaternary carbon atom or a six-membered ring structure by the bond via one atom. L³ is selected from the group consisting of a direct bond, a methylene group, a sulfur atom, a nitrogen atom-containing group, and an oxygen atom. The nitrogen atom-containing group represented by L³ may be a divalent nitrogen atom-containing group.

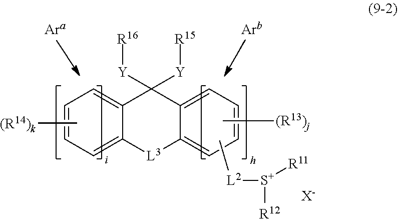

In a case of forming the five-membered ring structure by a direct bond between aryl groups, the onium salt has a structure represented by the following chemical formula (9-3).

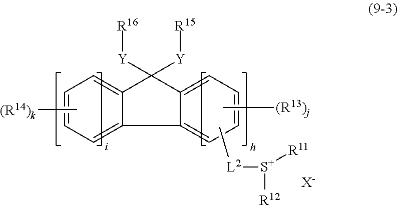

In a case of forming the six-membered ring structure by the bond between aryl groups via one atom, examples of the onium salt may have structures represented by the following chemical formula (9-4).

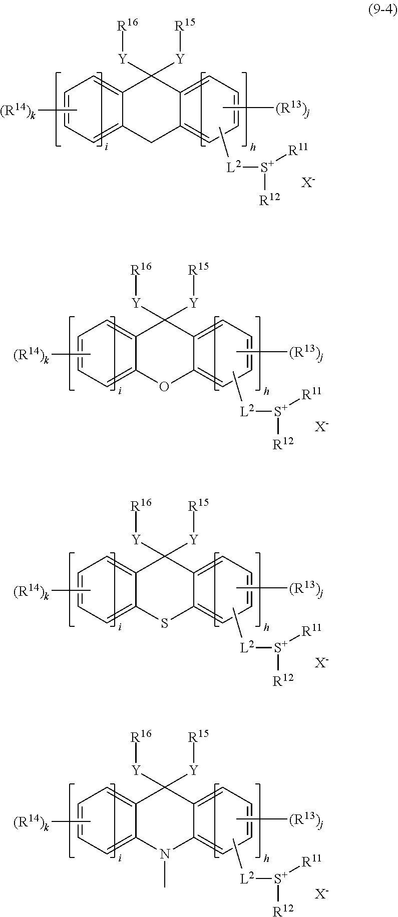

L² may be any one selected from the group consisting of: a direct bond; a linear, branched, or cyclic alkylene group of 1 to 12 carbon atoms; an alkenylene group of 1 to 12 carbon atoms; an arylene group of 6 to 12 carbon atoms; a heteroarylene group of 4 to 12 carbon atoms; and a group to which the above groups are bound via an oxygen atom, a sulfur atom, or a nitrogen atom-containing group. The alkylene group, alkenylene group, arylene group, and heteroarylene group represented by L² may include ones in which the alkyl group, alkenyl group, aryl group, and heteroaryl group represented by R¹¹ are divalent. The nitrogen atom-containing group represented by L² may be the same as the nitrogen atom-containing group represented by R¹¹.

In the above chemical formula (9), k and j may be each independently 0 to 3, specifically 0 to 2, in view of ease of synthesis.

R¹³ to R¹⁶, X⁻Y, L², L³, and h to k in the above chemical formula (10) are each independently selected from the same options as in R¹³ to R¹⁶, X⁻, Y, L², L³, Y, and h to k in the above chemical formula (9), respectively.

R¹⁷ may be an aryl group of 6 to 12 carbon atoms which may have a substituent, and a heteroaryl group of 4 to 12 carbon atoms which may have a substituent. R¹⁷ and the aryl group to which the iodonium group is bound may be joined to each other to thereby form a cyclic structure, together with an iodine atom to which they are bound. The aryl group and heteroaryl group represented by R¹⁷ are selected from the same options as in the aryl group and heteroaryl group represented by R¹¹, respectively. The substituent in R¹⁷ may be the same as the first substituent.

In the above chemical formula (10), the aryl group to which the iodonium group is bound represents a portion indicated by an arrow in the following chemical formula (10-1).

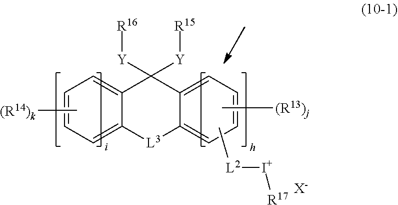

The quaternary carbon atom to which two Y's are directly bound and the two aryl groups directly bound to the quaternary carbon atom form a five-membered ring structure by a direct bond between two aryl groups directly bound to the quaternary carbon atom or a six-membered ring structure by the bond via L³.

R¹¹ to R¹⁶, L², Y, h to k, and X⁻ in the above chemical formula (11) are each independently selected from the same options as in R¹¹ to R¹⁶, L², Y, h to k, and X⁻ in the above chemical formula (9), respectively.

L⁴ and L⁵ each independently represent any one selected from the group consisting of a direct bond, an alkenylene group of 2 carbon atoms, an alkynylene group of 2 carbon atoms, and a carbonyl group. That is, the quaternary carbon atom to which two Y's are directly bound and two aryl groups may directly bind to each other, or may bind to each other via an alkenylene group of 2 carbon atoms or an alkynylene group of 2 carbon atoms, but have a structure including at least one bond via an alkenylene group of 2 carbon atoms or an alkynylene group of 2 carbon atoms.

In the above chemical formula (11), the aryl group to which the sulfonium group is bound represents a portion indicated by an arrow in the following chemical formula (11-1).

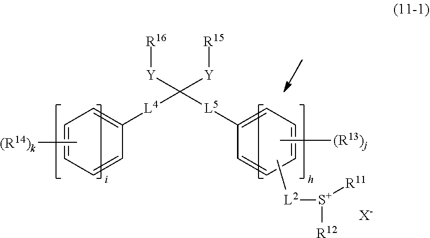

In the above chemical formula (12), R¹³ to R¹⁷, L², Y, h to k, and X⁻ are each independently selected from the same options as in R¹³ to R¹⁷, L², Y, h to k, and X⁻ in the above chemical formula (10).

L⁴ and L⁵ are each independently any one selected from the group consisting of a direct bond, an alkenylene group of 2 carbon atoms, an alkynylene group of 2 carbon atoms, and a carbonyl group. That is, the quaternary carbon atom to which two Y's are directly bound and two aryl groups may directly bind to each other, or may bind to each other via an alkenylene group of 2 carbon atoms or an alkynylene group of 2 carbon atoms, but have a structure including at least one bond via an alkenylene group of 2 carbon atoms or an alkynylene group of 2 carbon atoms.

In the above chemical formula (12), the aryl group to which the iodonium group is bound represents a portion indicated by an arrow in the following chemical formula (12-1).

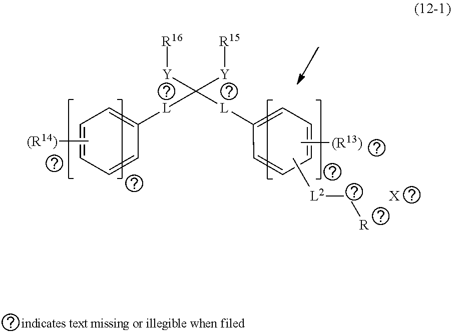

In the above chemical formulas (9), (10), (11), or (12), Y is an oxygen atom or a sulfur atom. h and i are each independently an integer of 1 to 3. j is an integer of 0 to 4 when h is 1, an integer of 0 to 6 when h is 2, or an integer of 0 to 8 when h is 3. k is an integer of 0 to 5 when i is 1, an integer of 0 to 7 when h is 2, or an integer of 0 to 9 when h is 3. In addition, for example, when i and/or h are 2 in the above chemical formula (9) or (10), the onium salt has a naphthalene ring. This naphthalene ring may bind to the quaternary carbon, to which Y's are bound, at any position from the 1st to 8th positions.

For example, when i and/or h are 3 in the above chemical formula (9), (10), (11), or (12), the onium salt has at least one of an anthracene ring, a phenanthrene ring, and a naphthacene ring. Even in such a case, the naphthalene ring and the naphthacene ring may bind to the quaternary carbon, to which Y's are bound, at any position from the 1st to 10th positions.

In several aspects of the present disclosure, the onium salt may be exemplified to have a sulfonium cation and an iodonium cation shown in the following chemical formulas (9-5) to (9-9). However, several aspects of the present disclosure are not limited thereto.

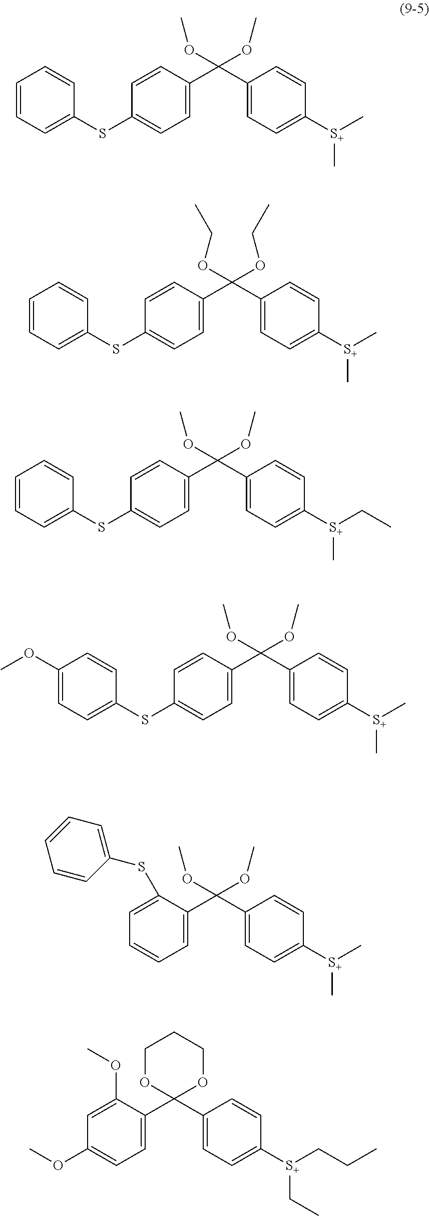

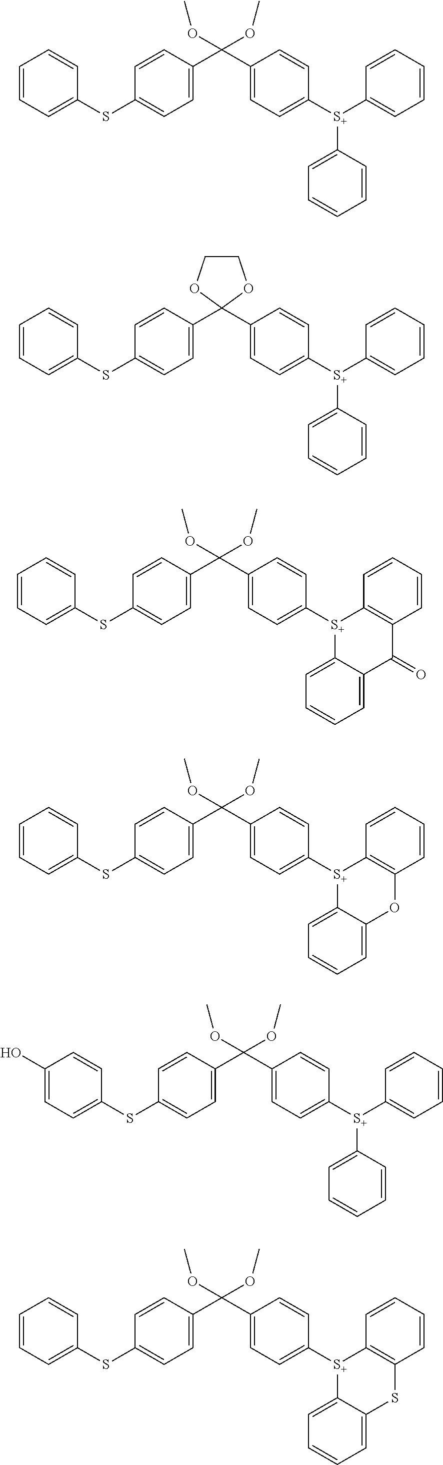 [SMILES: COC(OC)(c1ccc(Sc2ccccc2)cc1)c1ccc([S+](c2ccccc2)c2ccccc2)cc1 ; c1ccc(Sc2ccc(C3(c4ccc([S+](c5ccccc5)c5ccccc5)cc4)OCCO3)cc2)cc1 ; COC(OC)(c1ccc(Sc2ccccc2)cc1)c1ccc(-[s+]2c3ccccc3c(=O)c3ccccc32)cc1 ; COC(OC)(c1ccc(Sc2ccccc2)cc1)c1ccc([S+]2c3ccccc3Oc3ccccc32)cc1 ; COC(OC)(c1ccc(Sc2ccc(O)cc2)cc1)c1ccc([S+](c2ccccc2)c2ccccc2)cc1 ; COC(OC)(c1ccc(Sc2ccccc2)cc1)c1ccc([S+]2c3ccccc3Sc3ccccc32)cc1]

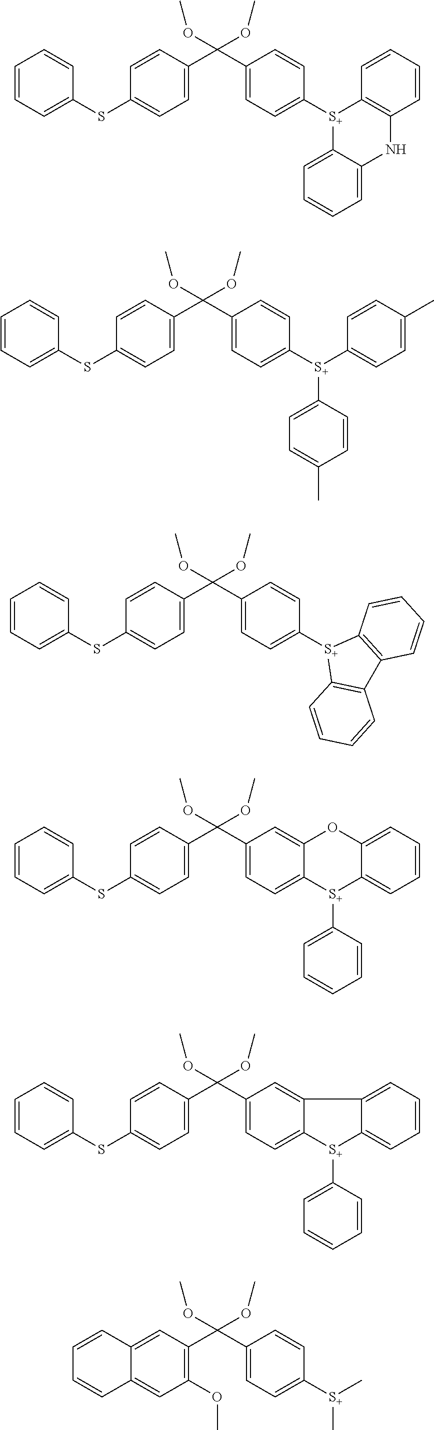 [SMILES: COC(OC)(c1ccc(Sc2ccccc2)cc1)c1ccc([S+]2c3ccccc3Nc3ccccc32)cc1 ; COC(OC)(c1ccc(Sc2ccccc2)cc1)c1ccc([S+](c2ccc(C)cc2)c2ccc(C)cc2)cc1 ; COC(OC)(c1ccc(Sc2ccccc2)cc1)c1ccc(-[s+]2c3ccccc3c3ccccc32)cc1 ; COC(OC)(c1ccc(Sc2ccccc2)cc1)c1ccc2c(c1)Oc1ccccc1[S+]2c1ccccc1 ; COC(OC)(c1ccc(Sc2ccccc2)cc1)c1ccc2c(c1)c1ccccc1[s+]2-c1ccccc1 ; COc1cc2ccccc2cc1C(OC)(OC)c1ccc([S+](C)C)cc1]

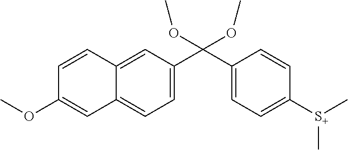

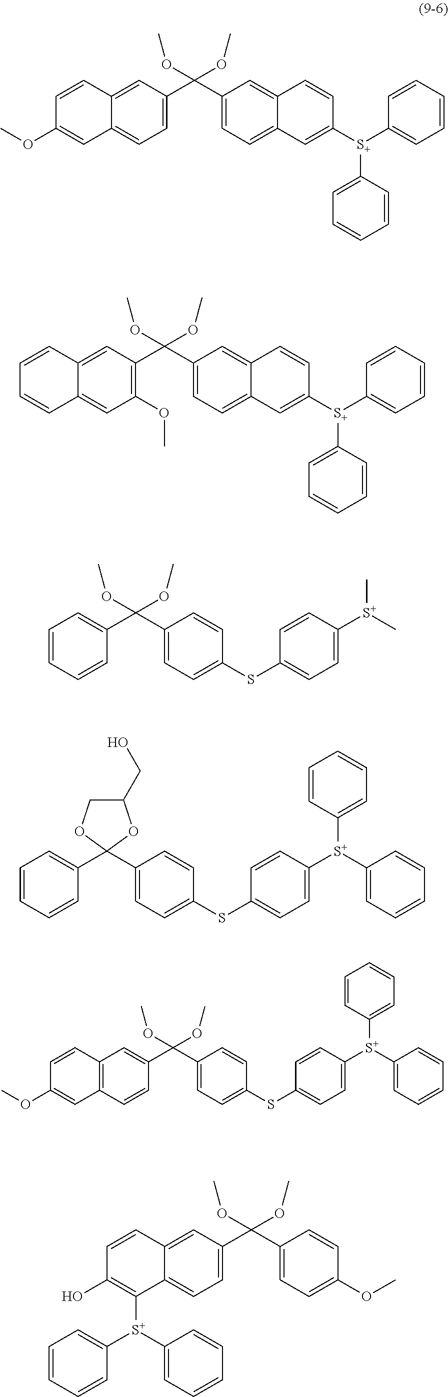

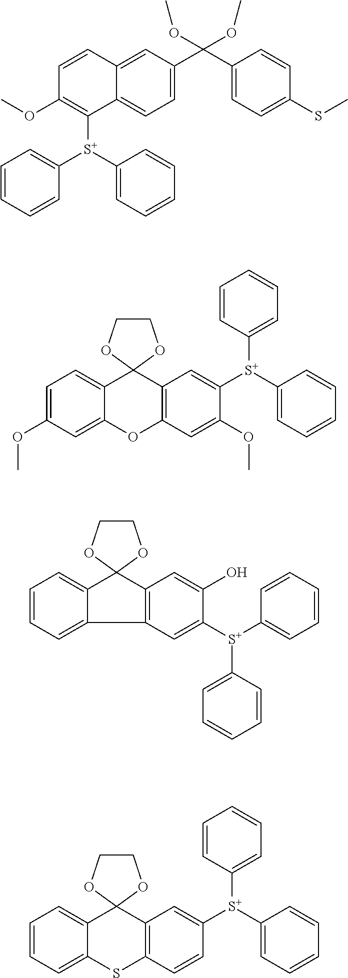 [SMILES: COc1ccc2cc(C(OC)(OC)c3ccc(SC)cc3)ccc2c1[S+](c1ccccc1)c1ccccc1 ; COc1ccc2c(c1)Oc1cc(OC)c([S+](c3ccccc3)c3ccccc3)cc1C21OCCO1 ; Oc1cc2c(cc1[S+](c1ccccc1)c1ccccc1)-c1ccccc1C21OCCO1 ; c1ccc([S+](c2ccccc2)c2ccc3c(c2)C2(OCCO2)c2ccccc2S3)cc1]

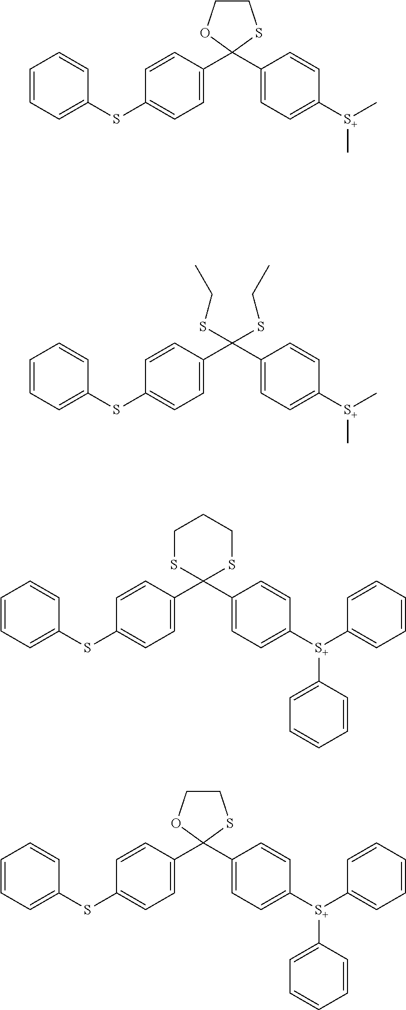 [SMILES: C[S+](C)c1ccc(C2(c3ccc(Sc4ccccc4)cc3)OCCS2)cc1 ; CCSC(SCC)(c1ccc(Sc2ccccc2)cc1)c1ccc([S+](C)C)cc1 ; c1ccc(Sc2ccc(C3(c4ccc([S+](c5ccccc5)c5ccccc5)cc4)SCCCS3)cc2)cc1 ; c1ccc(Sc2ccc(C3(c4ccc([S+](c5ccccc5)c5ccccc5)cc4)OCCS3)cc2)cc1]

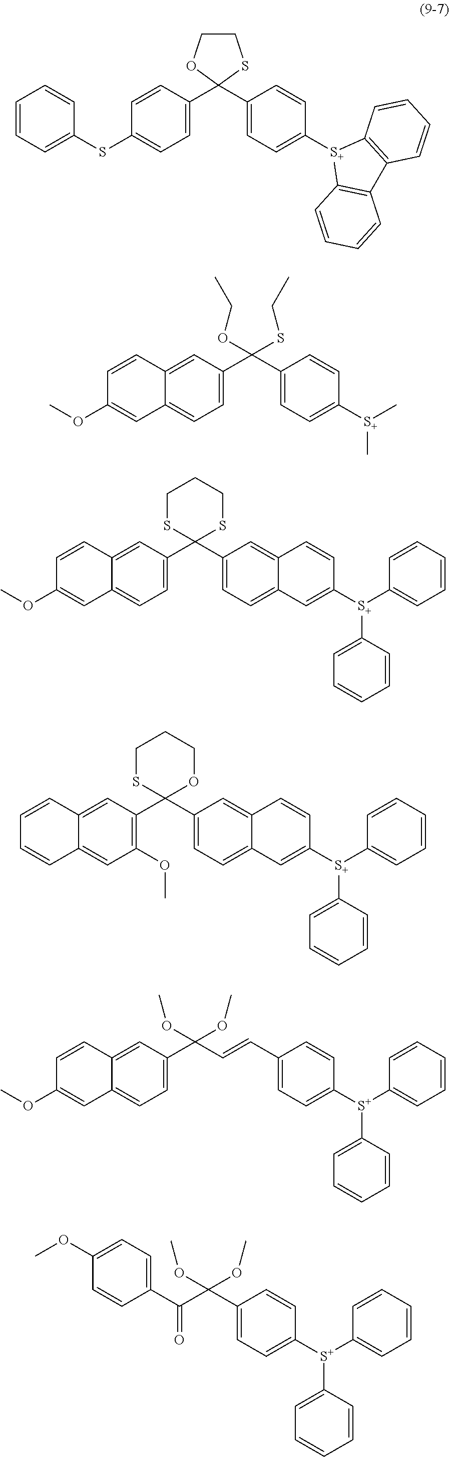

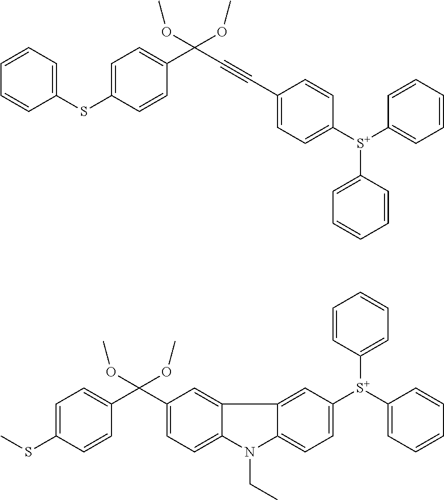 [SMILES: COC(C#Cc1ccc([S+](c2ccccc2)c2ccccc2)cc1)(OC)c1ccc(Sc2ccccc2)cc1 ; CCn1c2ccc([S+](c3ccccc3)c3ccccc3)cc2c2cc(C(OC)(OC)c3ccc(SC)cc3)ccc21]

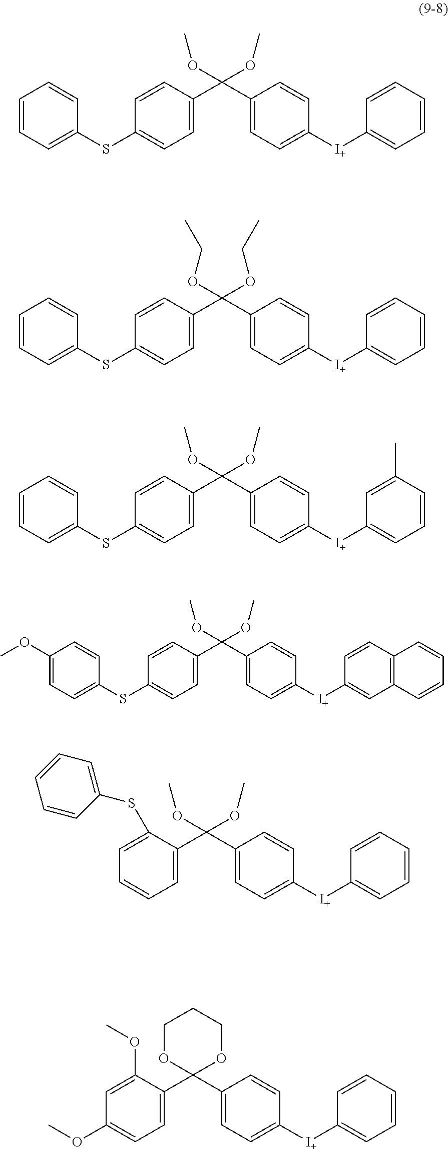 [SMILES: COC(OC)(c1ccc(Sc2ccccc2)cc1)c1ccc([I+]c2ccccc2)cc1 ; CCOC(OCC)(c1ccc(Sc2ccccc2)cc1)c1ccc([I+]c2ccccc2)cc1 ; COC(OC)(c1ccc(Sc2ccccc2)cc1)c1ccc([I+]c2cccc(C)c2)cc1 ; COc1ccc(Sc2ccc(C(OC)(OC)c3ccc([I+]c4ccc5ccccc5c4)cc3)cc2)cc1 ; COC(OC)(c1ccc([I+]c2ccccc2)cc1)c1ccccc1Sc1ccccc1 ; COc1ccc(C2(c3ccc([I+]c4ccccc4)cc3)OCCCO2)c(OC)c1]

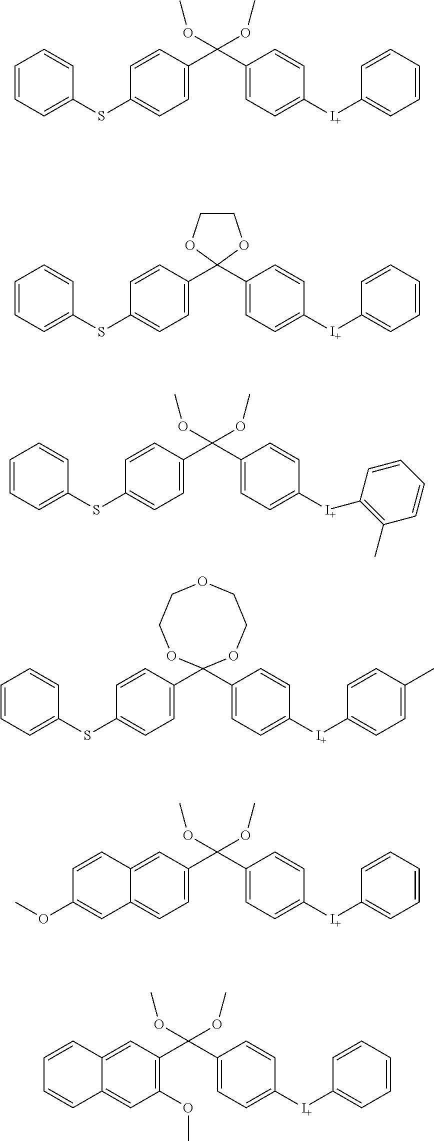

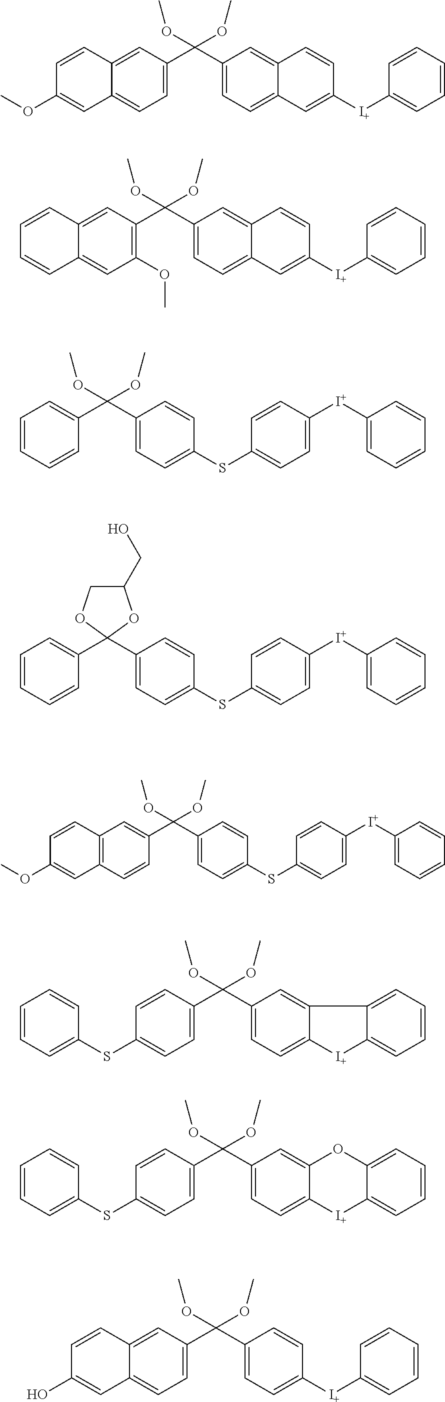

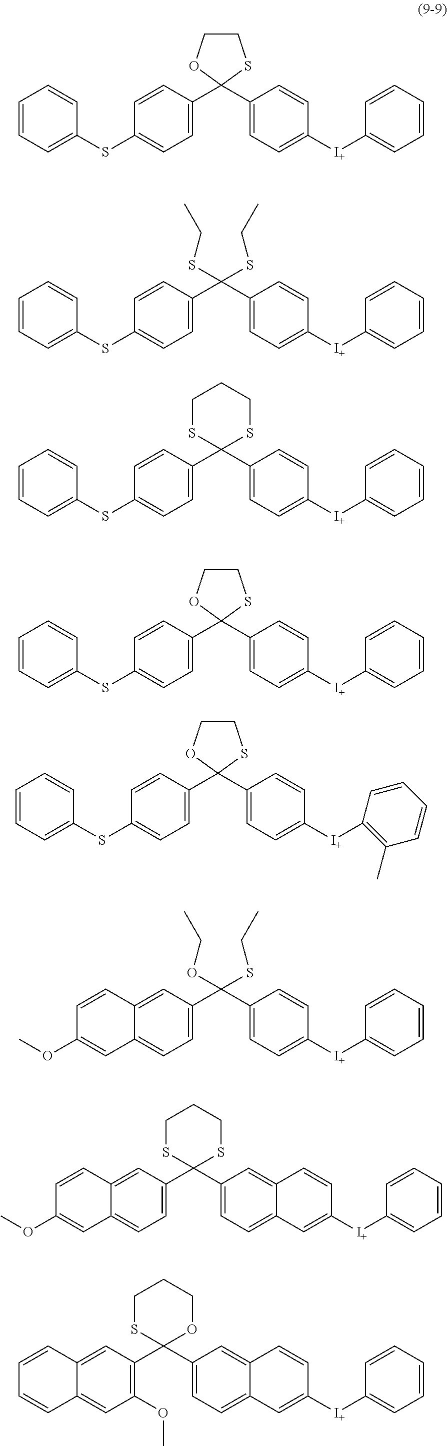

One aspect of the present disclosure, a sulfonium salt represented by the following chemical formula (13) is preferable.

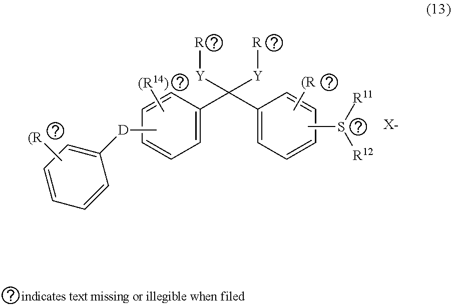

R¹¹ to R¹⁶, X⁻, and Y in the following chemical formula (13) are each independently selected from the same options as in R¹¹ to R¹⁶, X⁻, and Y in the above chemical formula (9), respectively.

R¹⁸ may be any one selected from the group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom. In a case where R¹⁸ has carbon, R¹⁸ may have 1 to 12 carbon atoms, and the groups may have a substituent.

In addition, e represents an integer of 0 to 4, f represents an integer of 0 to 4, and g represents an integer of 0 to 5.

X—represents an anion. The anion is not particularly limited, and examples thereof may include anions, such as a sulfonate anion, a carboxylate anion, an imide anion, a methide anion, a carbon anion, a borate anion, a halogen anion, a phosphate anion, an antimonate anion, or an arsenate anion.

More specifically, examples of the anion may include an anion represented by ZA^{a-}, (Rf)_{b}PF_{(6-b)}⁻, R¹⁹_{c}BA_{(4-c)}⁻, R¹⁹_{c}GaA_{(4-c)}⁻, R²⁰SO₂⁻, (R²⁰SO₂)₃C⁻, or (R²⁰SO₂)₂N⁻. When the numbers of Rf, R¹⁹, and R²⁰ are 2 or greater, two Rf's, two R¹⁹'s, and two R²⁰'s may bind to each other to form rings, respectively.

Z represents a phosphorous atom, a boron atom, or an antimony atom. A represents a halogen atom (preferably, a fluorine atom). P represents a phosphorus atom, F represents a fluorine atom, B represents a boron atom, and Ga represents a gallium atom. S represents a sulfur atom, O represents an oxygen atom, C represents a carbon atom, and N represents a nitrogen atom.

Rf may be an alkyl group in which 80 mol % or more of hydrogen atoms are substituted with fluorine atoms. The alkyl group may be an alkyl group of 1 to 8 carbon atoms. Examples of the alkyl group having fluorine substitution represented by Rf may include linear alkyl groups (methyl, ethyl, propyl, butyl, pentyl, octyl, etc), branched alkyl groups (isopropyl, isobutyl, sec-butyl, tert-butyl, etc.), and cycloalkyl groups (cyclopropyl, cyclobutyl, cyclopentyl, cyclohexyl, etc). As for Rf, the proportion of hydrogen atoms substituted with fluorine atoms in these alkyl groups may be 80 mol % or more, specifically 90% or more, more specifically 100%, on the basis of the mole number of hydrogen atoms in the original alkyl group.

More specific examples of Rf may include CF₃⁻, CF₃CF2⁻, (CF₃)₂CF⁻, CF₃CF₂CF₂⁻, CF₃CF₂CF₂CF₂⁻, (CF₃)₂CFCF₂⁻, CF₃CF₂(CF₃)CF⁻, and (CF₃)₃C⁻. The b Rf's are each independent from each other, and therefore may be identical to or different from each other.

R¹⁹ represents a phenyl group in which a portion of hydrogen atoms are substituted with at least one halogen atom or electron attractive group. Examples of the halogen atom may include a fluorine atom, a chlorine atom, and a bromine atom. Examples of the electron attractive group may include a trifluoromethyl group, a nitro group, and a cyano group. Of these, a phenyl group in which one hydrogen atom is substituted with a fluorine atom or a trifluoromethyl group is preferable. The c Rf's are each independent from each other, and therefore may be identical to or different from each other.

R²⁰ represents an alkyl group of 1 to 20 carbon atoms in which a part or all of hydrogen atoms may be substituted with a fluorine atom, or an aryl group of 6 to 20 carbon atoms. The alkyl group may be any of a linear, branched, or cyclic form, and the aryl group may be unsubstituted or may have a substituent.

In addition, a represents an integer of 4 to 6. b represents an integer of 1 to 5, specifically 2 to 4, more specifically 2 or 3. c represents an integer of 1 to 4, specifically 4. Examples of the anion represented by ZAₐ⁻ may include anions represented by SbF₆⁻, PF₆⁻ and BF₄⁻.

Examples of the anion represented by (Rf)_{b}PF_{(6-b)}⁻ may include anions, such as (CF₃CF₂)₂PF₄⁻, (CF₃CF₂)₃PF₃⁻, ((CF₃)₂CF)₂PF₄⁻, ((CF₃)₂CF)₃PF₃⁻, (CF₃CF₂CF₂)₂PF₄⁻, (CF₃CF₂CF₂)₃PF₃⁻, ((CF₃)₂CFCF₂)₂PF₄⁻, ((CF₃)₂CFCF₂)₃PF₃⁻, (CF₃CF₂CF₂CF₂)₂PF₄⁻, and (CF₃CF₂CF₂CF₂)₃PF₃⁻. Of these, anions such as (CF₃CF₂)₃PF₃⁻, (CF₃CF₂CF₂)₃PF₃⁻, ((CF₃)₂CF)₃PF₃⁻, ((CF₃)₂CF)₂PF₄⁻, ((CF₃)₂CFCF₂)₃PF₃⁻, and ((CF₃)₂CFCF₂)₂PF₄⁻, may be preferable.

Examples of the anion represented by R¹⁹_{c}BA_{(4-c)}⁻ may include anions, such as (C₆F₅)₄B⁻, ((CF₃)₂C₆H₃)₄B⁻, (CF₃C₆H₄)₄B⁻, (C₆F₅)₂BF₂⁻, C₆F₅BF₃⁻, and (C₆H₃F₂)₄B⁻. Of these, anions, such as (C₆F₅)₄B⁻ and ((CF₃)₂C₆H₃)₄B⁻, are preferable.

Examples of the anion represented by R¹⁹_{c}GaA_{(4-c)}⁻ may include anions, such as (C₆F₅)₄Ga⁻, ((CF₃)₂C₆H₃)₄Ga⁻, (CF₃C₆H₄)₄Ga⁻, (C₆F₅)₂GaF₂⁻, C₆F₅GaF₃⁻, and (C₆H₃F₂)₄Ga⁻. Of these, anions, such as (C₆F₅)₄Ga⁻ and ((CF₃)₂C₆H₃)₄Ga⁻, are preferable.

Examples of the anion represented by R²⁰SO₃⁻ may include a trifluoromethanesulfonate anion, a pentafluoroethanesulfonate anion, a heptafluoropropanesulfonate anion, a nonafluorobutanesulfonate anion, a pentafluorophenylsulfonate anion, a p-toluenesulfonate anion, a benzenesulfonate anion, a camphorsulfonate anion, a methanesulfonate anion, an ethanesulfonate anion, a propanesulfonate anion, and a butanesulfonate anion. Of these, the trifluoromethanesulfonate anion, the nonafluorobutanesulfonate anion, the methanesulfonate anion, the butanesulfonate anion, the benzenesulfonate anion, and the p-toluenesulfonate anion are preferable.

Examples of the anion represented by (R²⁰SO₂)₃C⁻ may include anions, such as (CF₃SO₂)₃C⁻, (C₂F₅SO₂)₃C⁻, (C₃F₇SO₂)₃C⁻, and (C₄F₉SO₂)₃C⁻.

Examples of the anion represented by (R²⁰SO₂)₂N⁻ may include anions, such as (CF₃SO₂)₂N⁻, (C₂F₅ SO₂)₂N⁻, (C₃F₇SO₂)₂N⁻, and (C₄F₉SO₂)₂N⁻. In addition, a cyclic imide in which portions corresponding to two (R²⁰SO₂)'s are joined to each other to form a cyclic structure may also be an example of the anion represented by (R²⁰SO₂)₂N⁻.

In addition to the above anions, perhalogenate ions (ClO₄⁻, BrO₄⁻, etc), halogenated sulfuonate ions (FSO₃⁻, ClSO₃⁻, etc), sulfonate ions (CH₃SO₄⁻, CF₃SO₄⁻, HSO₄⁻, etc), carbonate ions (HCO₃⁻, CH₃CO₃⁻, etc), aluminate ions (AlCl₄⁻, AlF₄⁻, etc), hexafluoro bismuthate ion (BiF6⁻), carboxylate ions (CH₃COO⁻, CF₃COO⁻, C₆H₅COO⁻, CH₃C₆H₄COO⁻, C₆F₅COO⁻, CF₃C₆H₄COO⁻, etc), aryl borate ions (B(C₆H₅)₄⁻, CH₃CH₂CH₂CH₂B(C₆H₅)₃⁻, etc), thiocyanate ion (SCN⁻), and nitrate ion (NO₃⁻) may be used as a monovalent anion.

These anions may have a substituent. Examples of the substituent may include an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom. Among these anions, a sulfonate anion, a carboxylate anion, and the like may be preferable.

An onium salt according to an aspect of the present disclosure is an aspect of a photo acid-generating agent (A), and may be an acid-generating agent unit-containing resin, of which an anion part is bound to a portion of the polymer. Examples of such an onium salt may include resins in which X⁻ in the above chemical formulas (9), (10), (11), and (12) has a unit represented by the following chemical formula (14). The onium salt is contained as one unit of the acid-generating agent unit-containing resin in the composition, thereby suppressing the diffusion of an acid generated upon the exposure and thus inhibiting LWR.

In addition, the unit represented by the following chemical formula (14) may be contained in the resin (B) or may be contained in a resin different from the resin (B).

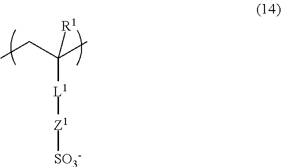

In the above chemical formula (14), R¹ may be any one selected from the group consisting of: a hydrogen atom, an alkyl group and a halogenated alkyl group. L¹ may be any one selected from the group consisting of: a direct bond; a linear, branched, or cyclic alkylene carbonyloxy group which may have a carbonyloxy group, a carbonylamino group and a substituent; and an alkylene carbonylamino group.

Z¹ is a linear or branched alkyl group of 1 to 12 carbon atoms, a linear or branched alkenyl group of 1 to 12 carbon atoms, and a linear or branched aryl group of 6 to 14 carbon atoms. In addition, a part or all of hydrogen atoms of these alkyl, alkenyl and aryl groups may be substituted with a fluorine atom. Of these groups, at least one methylene group may be substituted with a divalent heteroatom-containing group.

Examples of the anion part represented by the above chemical formula (14) may be exemplified as shown in the following chemical formulas (14-1) and 914-2). However, the present disclosure is not limited thereto.

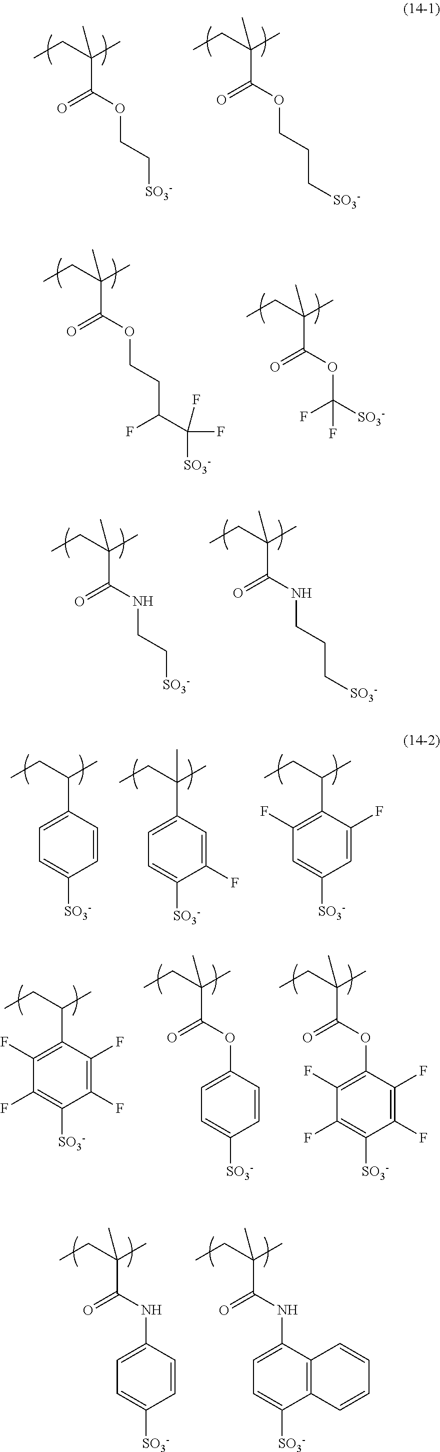

An onium salt according to several aspects of the present disclosure may have a molar absorption coefficient of less than 1.0×10⁵ cm²/mol, specifically less than 1.0×10⁴cm²/mol, at a wavelength of 365 nm.

In the above chemical formulas (9) to (12), the atom groups composed of R¹⁵, R¹⁶, and respective Y's may be each independently acetal or thioacetal, but particularly limited thereto.

Specifically, in a case where the onium compound contained in the acid-generating agent is the above-described onium salt, a ketone derivative in which acetal or thioacetal of the respective onium salt is deprotected may have a molar absorption coefficient of 1.0×10⁵ cm²/mol or more, specifically 1.0×10⁶ cm²/mol or more, at a wavelength of 365 nm.

The molar absorption coefficient of the ketone derivative at 365 nm may be 5 times or more, specifically 10 times or more, more specifically 20 times the molar absorption coefficient at 365 nm of the onium salt according to several aspects of the present disclosure.

For the above characteristics, the onium salt represented by the above chemical formula (9), (10), (11), or (12) is preferable. In addition, the onium compound contained in the photo acid-generating agent is not limited to the above-described onium salts. That is, in a case where an onium salt is used as the onium compound contained in the photoacid-generating agent, an iodonium salt may be used without limitation to the above-described sulfonium salt.

The synthesis method for the onium salt is not particularly limited, but for example, the synthesis methods for onium salts (sulfonium salt and iodonium salt) disclosed in PCT Publication No. WO2018/074382 may be applied thereto.

The content of the acid-generating agent in the resist composition according to the present embodiment may be 1 to 40 parts by mass, specifically 2 to 30 parts by mass, more specifically 3 to 15 parts by mass, relative to 100 parts by mass of the resist composition excluding the respective acid-generating agent.

In the calculation of the content of the acid-generating agent, an organic solvent is not contained in 100 parts by mass of the resist composition. In a case where the acid-generating agent is contained as one unit in the resin, that is, in a case where the acid-generating agent is a polymer component, the calculation of the content is based on the mass excluding the main chain of the polymer.

In the resist composition according to the present embodiment, a polymer component and a low-molecular-weight component may be used alone or in combination of two or more thereof or may be used in combination with other acid-generating agents, as the acid-generating agent. In the resist composition, the acid-generating agent may be substituted as a part of the polymer component.

Examples of the other acid-generating agents besides the acid-generating agent containing the onium salt may include a universal ionic acid-generating agent and a non-ionic acid-generating agent. Examples of the ionic acid-generating agent may include onium compounds, such as the aforementioned other iodonium and sulfonium salts. Examples of the non-ionic acid-generating agent may include an N-sulfonyloxyimide compound, an oxime sulfonate compound, an organic halogen compound, and a sulfonyl diazomethane compound. In a case where the resist composition includes an acid-generating agent besides the acid-generating agent containing the onium salt, the content thereof may be 0.1 to 50 parts by mass, relative to 100 parts by mass of the resist composition excluding the total amount of the acid-generating agent.

### [Quencher]

In the resist composition of the present embodiment, the quencher is a component having basicity for acid. Herein, the quencher has a function of inhibiting an acid generated from the acid-generating agent by the action with the acid (for example, neutralization). The basicity indicates acting as a base relative to acid. Therefore, examples of a substance having basicity may include, but are not limited to one having alkalinity, a weak acid salt that may become a base for acid.

In the present embodiment, the quencher loses basicity for acid when irradiated with the first radiation. In addition, the quencher maintains basicity for acid when not irradiated with the first radiation and irradiated with the second radiation.

That is, the quencher loses basicity for acid when irradiated with only the first radiation. In addition, the quencher loses basicity for acid even when irradiated with only the first radiation and then irradiated with only the second radiation. In addition, the quencher maintains (does not lose) basicity for acid when not irradiated with the first radiation and irradiated with only the second radiation.

That is, the quencher loses basicity for acid by irradiation with the first radiation, before the light absorption wavelength of the quencher is shifted so as to absorb the second radiation. Meanwhile, the quencher loses basicity for acid by irradiation with the second radiation, after the light absorption wavelength of the quencher is shifted to absorb the second radiation.

In the resist composition according to the present embodiment, the quencher contains an onium compound, which is transformed into a carbonyl compound when irradiated with the first radiation. That is, the quencher contains an onium compound and is irradiated with only the first radiation, so that the respective onium compound can be transformed into a carbonyl compound. The carbonyl compound may be an onium compound, or a compound other than the onium compound.

In the resist compound of the present embodiment, the onium compound contained in the quencher may include, but is not limited to, a compound represented by any one selected from the following chemical formulas (15), (16), (17), and (18).

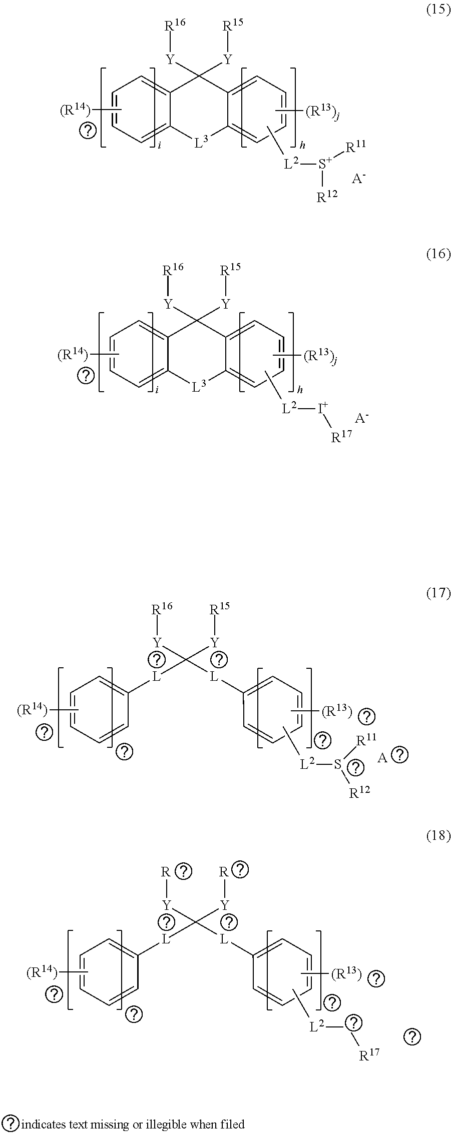

In the above chemical formula (15), R¹¹ and R¹² may be each independently any one selected from the group consisting of: a linear, branched, or cyclic alkyl group of 1 to 12 carbon atoms which may have a substituent; a linear, branched, or cyclic alkenyl group of 1 to 12 carbon atoms which may have a substituent; an aryl group of 6 to 14 carbon atoms which may have a substituent; and a heteroaryl group of 4 to 12 carbon atoms which may have a substituent.

Specific examples of the linear, branched, or cyclic alkyl group of 1 to 12 carbon atoms represented by R¹¹ and R¹² may include alkyl groups, such as a methyl group, an ethyl group, an n-propyl group, an n-butyl group, an isoprolyl group, a t-butyl group, a cyclopropyl group, a cyclobutyl group, a cyclopentyl group, a cyclohexyl group, an adamantan-1-yl group, an adamantan-2-yl group, a norbornan-1-yl group, and a norbornan-1-yl group.

In the alkyl group represented by R¹¹ and R¹², one divalent heteroatom-containing group selected from the group consisting of —O—, —CO—, —COO—, —COO—, —O—CO—O—, —NHCO—, —CONH—, —NH—CO—O—, —O—CO—NH—, —NH—, —N(R)—, —N(Ar)—, —S—, —SO—, and —SO₂—, instead of at least one methylene group, may be contained in the skeleton. However, the sulfur atom (S⁺) of the sulfonium group may be bound to the divalent hydrocarbon group but not directly bound to the heteroatom-containing group. R and Ar will be described later.

The alkenyl group represented by R¹¹ and R¹² may be one in which at least one carbon- carbon single bond in the alkyl group is substituted with a carbon-carbon double bond.

Specific examples of the aryl group of 6 to 14 carbon atoms which may have a substituent, represented by R¹¹ and R¹², may include a monocyclic aromatic hydrocarbon group, and a condensed polycyclic aromatic hydrocarbon group in which at least two monocyclic aromatic hydrocarbons are condensed with each other. These aryl groups may have a substituent.

Examples of the monocyclic aromatic hydrocarbon group may include a group having a skeleton, such as benzene. Examples of the condensed polycyclic aromatic hydrocarbon group may include groups having skeletons, such as indene, naphthalene, azulene, anthracene, and penanthrene.

Examples of the heteroaryl group of 4 to 12 carbon atoms which may have a substituent, represented by R¹¹ and R¹², may be one which includes, in the skeleton thereof, instead of at least one carbon atom of the aryl group, at least one selected from an oxygen atom, a nitrogen atom, and a sulfur atom.

Examples of the heteroaryl group may include: a monocyclic aromatic heterocyclic group, or a condensed polycyclic aromatic heterocyclic group in which at least one monocyclic aromatic heterocyclic is condensed with the aromatic hydrocarbon group or the aliphatic heterocyclic group. These aromatic heterocyclic groups may have a substituent.

Examples of the monocyclic aromatic heterocyclic group may include groups having skeletons, such as furan, pyrrole, imidazole, pyran, pyridine, pyrimidine, and pyrazine. Examples of the condensed polycyclic aromatic heterocyclic group may include groups having skeletons, such as indole, purine, quinoline, isoquinoline, chromene, phenoxazine, xanthene, acridine, phenazine, and carbazole.

Examples of the substituent which may be included in R¹¹ and R¹² (hereinafter, also referred to as “first substituent”), may include a hydroxy group, a cyano group, a mercapto group, a carboxyl group, a carbonyl group, an alkoxy group (—OR), an acyl group (—COR), an alkoxycarbonyl group (—COOR), an aryl group (—Ar), an aryloxy group (—OAr), an amino group, an alkylamino group (—NHR), a dialkylamino group (—N(R)₂), an arylamino group (—NHAr), a diarylamino group (—N(Ar)₂), an N-alkyl-N-arylamino group (—NRAr), a phosphino group, a silyl group , a halogen atom, a trialkylsilyl group (—Si—(R)₃), a silyl group in which at least one alkyl group of the respective trialkylsilyl group is substituted with Ar, an alkylsulfanyl group (—SR), and an arylsulfanyl group (—SAr), but are not limited thereto. R and Ar will be described later.

In addition, the first substituent may be a group having a polymerizable group, such as a (meth)acryloyl group.

At least two of R¹¹, R¹², and the aryl group to which a sulfonium group is bound may be directly joined to each other by a single bond, or may be joined to each other via any one selected from the group consisting of an oxygen atom, a sulfur atom, a nitrogen atom-containing group and a methylene group to thereby form a cyclic structure, together with a sulfur atom (S⁺) of the sulfonium group to which they are bound. However, the sulfur atom (S⁺) of the sulfonium group may be bound to the divalent hydrocarbon group but not directly bound to the heteroatom-containing group.

Examples of the “nitrogen-containing group” may include divalent groups containing a nitrogen atom, such as an aminodiyl group (—NH—), an alkylaminodiyl group (—NR—), or an arylaminodiyl group (—NAr—). R and Ar will be described later.

In the above chemical formula (15), the aryl group to which the sulfonium group is bound is a portion indicated by an arrow in the following chemical formula (15-1).

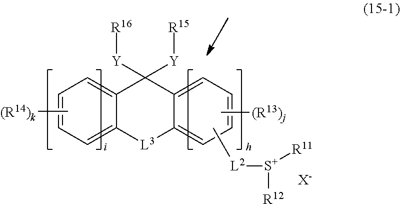

In the first substituent or the like, R may be an alkyl group of one or more carbon atoms. In addition, the number of carbon atoms may be 20 or less. Specific examples of the alkyl group of one or more carbon atoms may include: linear alkyl groups, such as a methyl group, an ethyl group, an n-propyl group, an n-butyl group, an n-pentyl group, an n-hexyl group, an n-octyl group, and an n-decyl group; branched alkyl groups, such as an isopropyl group, an isobutyl group, a tert-butyl group, an isopentyl group, a tert-pentyl group, and a 2-ethylexyl group; alicyclic alkyl groups, such as a cyclopropyl group, a cyclobutyl group, a cyclopentyl group, a cyclohexyl group, an adamantan-1-yl group, an adamantan-2-yl group, a norboman-1-yl group, and a norbornan-2-yl group; silyl-substituted alkyl groups in which one hydrogen atom of these groups is substituted with a trialkylsilyl group, such as a trimethylsilyl group, a triethylsilyl group, and a dimethylethylsilyl group; and alkyl groups in which at least one hydrogen atom of these groups is substituted with a cyano group or a fluoro group.

In the first substituent or the like, Ar may be an aryl group or a heteroaryl group. The heteroaryl group is an aryl group which contains at least one heteroatom in the cyclic structure. Specific examples of Ar may include ones having 20 or less of carbon atoms, such as a phenyl group, a biphenyl group, a terphenyl group, a quarter-phenyl group, a naphthyl group, an anthryl group, a phenanthrenyl group, a pentalenyl group, an indenyl group, an indasenyl group, an acenaphthyl group, a fluorenyl group, a heptalenyl group, a naphthacenyl group, a pyrenyl group, a chrysenyl group, a tetrasenyl group, a furanyl group, a thienyl group, a pyranyl group, a sulfanylpyranyl group, a pyrrolyl group, an imidazolyl group, an oxazolyl group, a thiazolyl group, a pyrazoyl group, a pyridyl group, an isobenzofuranyl group, a benzofuranyl group, an isochromenyl group, a chromenyl group, an indolyl group, an isoindolyl group, a benzoimidazoyl group, a xanthenyl group, an aquadinyl group, and a carbazoyl group.

In a case where R¹¹ and R¹² have the first substituent and the onium salt is a low-molecular compound, the number of carbon atoms in R¹¹ and R¹², including carbon atoms of the first substituent, may be 1 to 20.

In an aspect of the present disclosure, the onium salt, as one unit of the resin, namely as a unit including an onium salt structure, may be a polymer component, which binds to a portion of the polymer, or a polymer component included as a unit of the polymer. When the onium salt is a polymer component, the first substituent may be the main chain of the polymer. When the first substituent of R¹¹ and R¹² is the main chain of the polymer, the number of carbon atoms in the main chain of the polymer is excluded from the number of carbon atoms in R¹¹ and R¹². In one aspect of the present disclosure, when the onium salt is a polymer component, the weight average molecular weight of the total polymer components may be adjusted to 2,000 to 200,000. The low-molecular compound has a weight average molecular weight of less than 2,000, and the polymer component has a weight average molecular weight of 2,000 or more.

R¹¹ and R¹² may be an aryl group in view of the improvement of stability.

R¹³ and R¹⁴ may be each independently at least one selected from the group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom. When each of R¹³ and R¹⁴ has carbon, each of R¹³ and R¹⁴ may have 1 to 12 carbon atoms and may have a substituent (hereinafter, also referred to as “second substituent”).

The alkyl group represented by R¹³ and R¹⁴ may be a linear, branched, or cyclic group. Specifically, the alkyl group represented by R¹³ and R¹⁴ may be the same as the alkyl group represented by R in the first substituent. The aryl group and heteroaryl group represented by R¹³ and R¹⁴ may be the same as the aryl group and heteroaryl group represented by Ar in the first substituent of R¹¹ and R¹².

The alkoxy group represented by R¹³ and R¹⁴ may be the same as the alkoxy group (—OR) in the first substituent. Examples of the hydroxy(poly)alkyleneoxy group represented by R¹³ and R¹⁴ may include a polyethyleneoxy group and a polypropyleneoxy group. Examples of the halogen atom represented by R¹³ and R¹⁴ may be a fluorine atom, a chlorine atom, and an iodine atom.

In the alkyl group represented by R¹³ and R¹⁴, the same group as the heteroatom- containing group in R¹¹ and R¹², instead of at least one methylene group, may be included in the skeleton. However, the alkyl group preferably does not have a consecutive connection of heteroatoms, such as —O—O—, —S—S—, and —O—S—.

The second substituent which may be included in R¹³ and R¹⁴, may be the same as the first substituent. In a case where R¹³ and R¹⁴ have the second substituent and the onium salt is a low-molecular compound, the number of carbon atoms in R¹³ and R¹⁴, including carbon atoms of the second substituent, may be 1 to 12. In a case where the second substituent of R¹³ and R¹⁴ is the main chain of the polymer, the number of carbon atoms in the main chain of the polymer is excluded from the number of carbon atoms in R¹³ and R¹⁴.

R¹⁴ may be an alkyl group. Also, R¹⁴ may include electron-donating groups, such as an aryl group, an alkoxy group, an alkylsulfanyl group, an aryloxy group, an arylsulfanyl group, an amino group, and an alkylamino group, when these groups are located at the ortho- or para-position of the quaternary carbon binding to Y and the arylene having R¹⁴. These groups are preferable in view of improving the absorptivity at 365 nm.

R¹⁵ and R¹⁶ may be each independently any one selected from the group consisting of: a linear, branched, or cyclic alkyl group of 1 to 12 carbon atoms which may have a substituent; a linear, branched, or cyclic alkenyl group of 1 to 12 carbon atoms which may have a substituent; an aryl group of 6 to 14 carbon atoms which may have a substituent; and a heteroaryl group of 4 to 12 carbon atoms which may have a substituent. These groups are selected from the same options as in R¹¹ and R¹². In addition, the substituent in R¹⁵ and R¹⁶ (hereinafter, also referred to as “third substituent”) may be the same as the first substituent.

R¹⁵ and R¹⁶ may be directly joined to each other by a single bond, or may be joined to each other via any one selected from the group consisting of an oxygen atom, a sulfur atom, and an alkylene group to thereby form a cyclic structure. In view of synthesis, R¹⁵ and R¹⁶ may be identical to each other.

The quaternary carbon atom to which two Y's are directly bound and the two aryl groups (Ar^{a} and Ar^{b} indicated by arrows in the following chemical formula (19)) directly bound to the quaternary carbon atom form a five-membered ring structure by a direct bond between two aryl groups directly bound to the quaternary carbon atom or a six-membered ring structure by the bond via one atom. L³ is selected from the group consisting of a direct bond, a methylene group, a sulfur atom, a nitrogen atom-containing group, and an oxygen atom. The nitrogen atom-containing group represented by L³ may be the same as the divalent nitrogen atom-containing group.

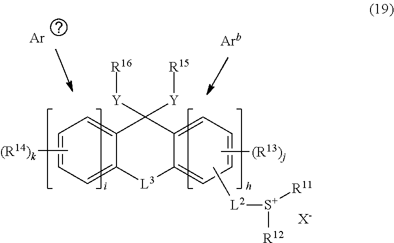

In a case of forming the five-membered ring structure by a direct bond between two aryl groups, the onium salt has a structure represented by the following chemical formula (19-1).

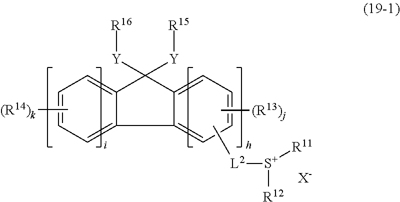

In a case of forming the six-membered ring structure by the bond between aryl groups via one atom, the onium salt may have exemplary structures represented by the following chemical formula (19-2).

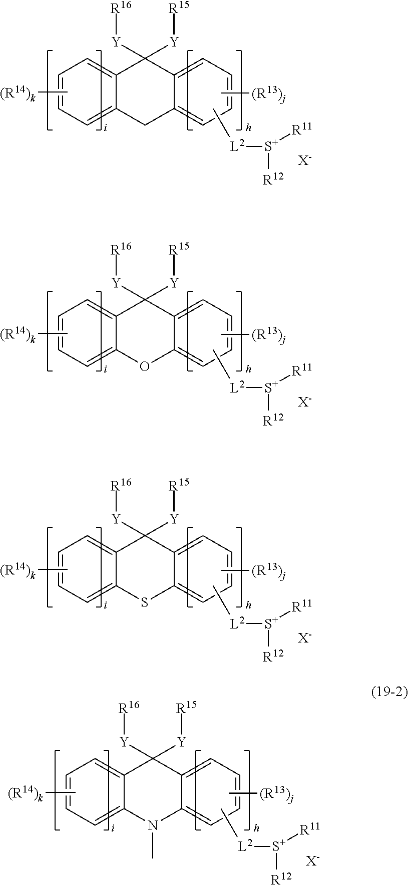

L² may be any one selected from the group consisting of: a linear, branched, or cyclic alkylene group of 1 to 12 carbon atoms; an alkenylene group of 1 to 12 carbon atoms; an arylene group of 6 to 12 carbon atoms; a heteroarylene group of 4 to 12 carbon atoms; and groups to which the above groups are bound via an oxygen atom, a sulfur atom, or a nitrogen atom-containing group. The alkylene group, alkenylene group, arylene group, and heteroarylene group represented by L² may include ones in which the alkyl group, alkenyl group, aryl group, and heteroaryl group represented by R¹¹ are divalent. The nitrogen atom-containing group represented by L² may be the same as the nitrogen atom-containing group represented by R¹¹.

In the above chemical formula (15), k and j may be each independently 0 to 3, specifically 0 to 2, in view of ease of synthesis.

R¹³ to R¹⁶, A⁻, Y, L², L³, and h to k in the above chemical formula (16) are each independently selected from the same options as in R¹³ to R¹⁶, A⁻, Y, L², L³, and h to k in the above chemical formula (15), respectively.

R¹⁷ may be an aryl group of 6 to 12 carbon atoms which may have a substituent, and a heteroaryl group of 4 to 12 carbon atoms which may have a substituent. R¹⁷ and the aryl group to which the iodonium group is bound may be joined to each other to thereby form a cyclic structure, together with an iodine atom to which they are bound. The aryl group and heteroaryl group represented by R¹⁷ are selected from the same options as in the aryl group and heteroaryl group represented by R¹¹, respectively. The substituent in R¹⁷ may be the same as the first substituent.

In the above chemical formula (16), the aryl group to which the iodonium group is bound represents a portion indicated by an arrow in the following chemical formula (16-1).

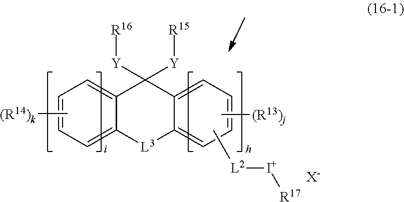

The quaternary carbon atom to which two Y's are directly bound and the two aryl groups directly bound to the quaternary carbon atom form a five-membered ring structure by a direct bond between two aryl groups directly bound to the quaternary carbon atom, or a six-membered ring structure by the bond via L³.

R¹¹ to R¹⁶, L², Y, h to k, and A⁻ in the above chemical formula (17) are each independently selected from the same options as in R¹¹ to R¹⁶, L², Y, h to k, and A⁻ in the above chemical formula (15), respectively.

L⁴ and L⁵ are each independently any one selected from the group consisting of a direct bond, an alkenylene group of 2 carbon atoms, an alkynylene group of 2 carbon atoms, and a carbonyl group. That is, the quaternary carbon atom to which two Y's are directly bound and two aryl groups may directly bind to each other, or may bind to each other via the alkenylene group of 2 carbon atoms or the alkynylene group of 2 carbon atoms, but have a structure including at least one bond via the alkenylene group of 2 carbon atoms or the alkynylene group of 2 carbon atoms.

In the above chemical formula (17), the aryl group to which the sulfonium group is bound represents a portion indicated by an arrow in the following chemical formula (17-1).

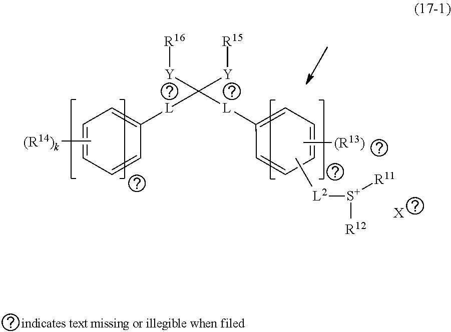

In the above chemical formula (18), R¹³ to R¹⁷, L², Y, h to k, and A⁻ are each independently selected from the same options as in R¹³ to R′⁷, L², Y, h to k, and A⁻ in the above chemical formula (16).

L⁴ and L⁵ are each independently any one selected from the group consisting of a direct bond, an alkenylene group of 2 carbon atoms, an alkynylene group of 2 carbon atoms, and a carbonyl group. That is, the quaternary carbon atom to which two Y's are directly bound and two aryl groups may directly bind to each other, or may bind to each other via the alkenylene group of 2 carbon atoms or the alkynylene group of 2 carbon atoms, but have a structure including at least one bond via the alkenylene group of 2 carbon atoms or the alkynylene group of 2 carbon atoms.

In the above chemical formula (18), the aryl group to which the iodonium group is bound represents a portion indicated by an arrow in the following chemical formula (18-1).

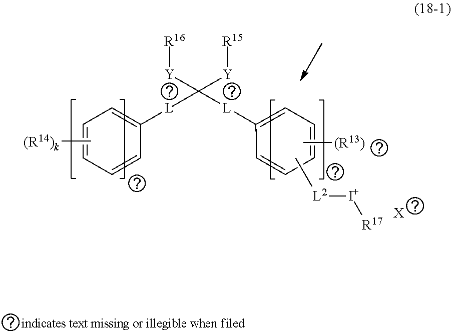

In the above chemical formulas (15), (16), (17), or (18), Y is an oxygen atom or a sulfur atom. h and i are each independently an integer of 1 to 3. j is an integer of 0 to 4 when h is 1, an integer of 0 to 6 when h is 2, or an integer of 0 to 8 when h is 3. k is an integer of 0 to 5 when i is 1, an integer of 0 to 7 when h is 2, or an integer of 0 to 9 when h is 3. In addition, for example, when i and/or h are 2 in the above chemical formula (15) or (16), the onium salt has a naphthalene ring. The naphthalene ring may bind to the quaternary carbon, to which Y's are bound, at any position from the 1st to 8th positions.

For example, when i and/or h are 3 in the above chemical formula (15), (16), (17), or (18), the onium salt has at least one of an anthracene ring, a phenanthrene ring, and a naphthacene ring. Even in such a case, the phenanthrene ring and the naphthacene ring may bind to the quaternary carbon, to which Y's are bound, at any position from the 1st to 10th positions.

In several aspects of the present disclosure, it may be exemplified that the onium salt has a sulfonium cation and an iodonium cation as shown in the following chemical formulas (20) to (24). However, several aspects of the present disclosure are not limited thereto.

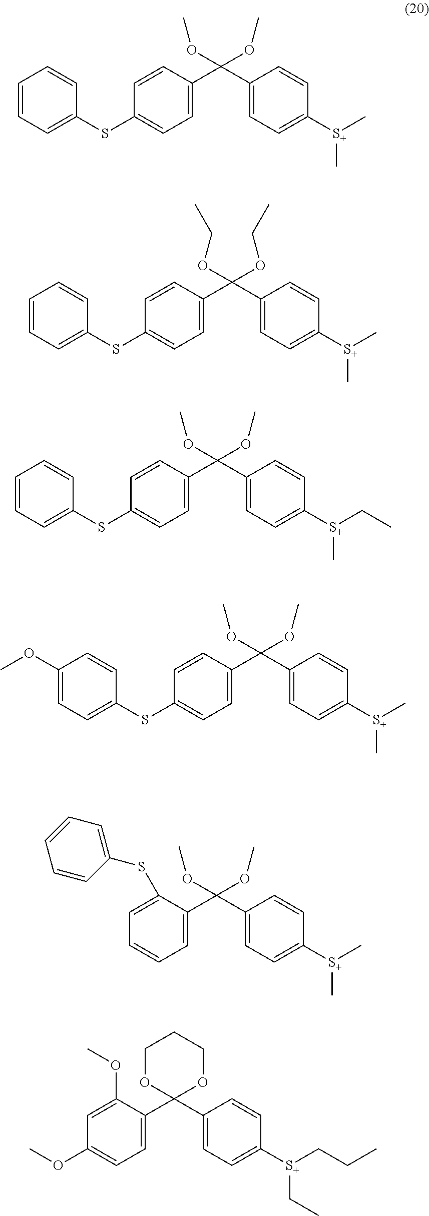

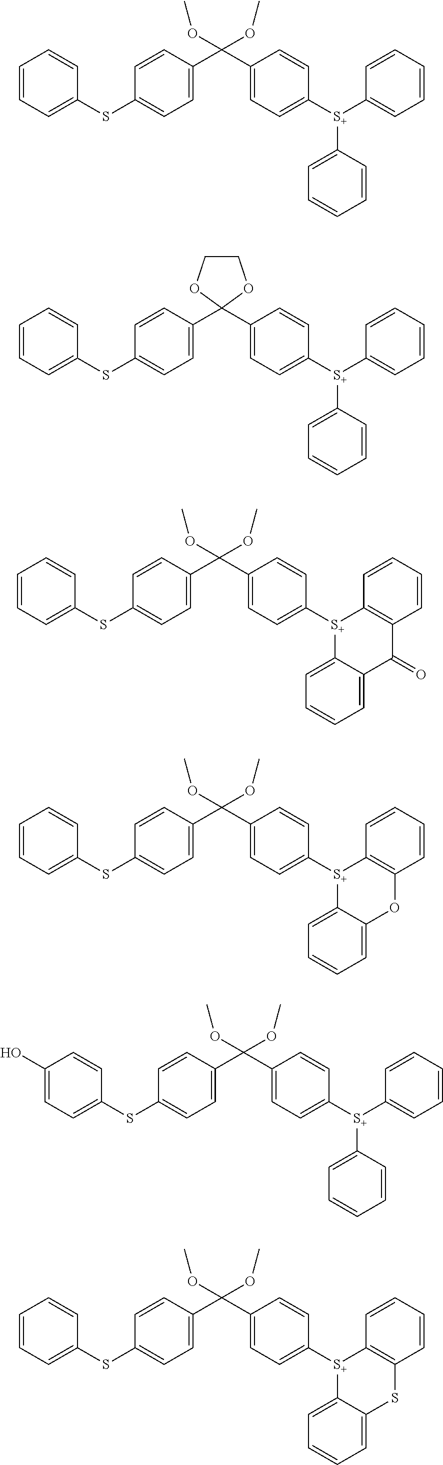 [SMILES: COC(OC)(c1ccc(Sc2ccccc2)cc1)c1ccc([S+](c2ccccc2)c2ccccc2)cc1 ; c1ccc(Sc2ccc(C3(c4ccc([S+](c5ccccc5)c5ccccc5)cc4)OCCO3)cc2)cc1 ; COC(OC)(c1ccc(Sc2ccccc2)cc1)c1ccc(-[s+]2c3ccccc3c(=O)c3ccccc32)cc1 ; COC(OC)(c1ccc(Sc2ccccc2)cc1)c1ccc([S+]2c3ccccc3Oc3ccccc32)cc1 ; COC(OC)(c1ccc(Sc2ccc(O)cc2)cc1)c1ccc([S+](c2ccccc2)c2ccccc2)cc1 ; COC(OC)(c1ccc(Sc2ccccc2)cc1)c1ccc([S+]2c3ccccc3Sc3ccccc32)cc1]

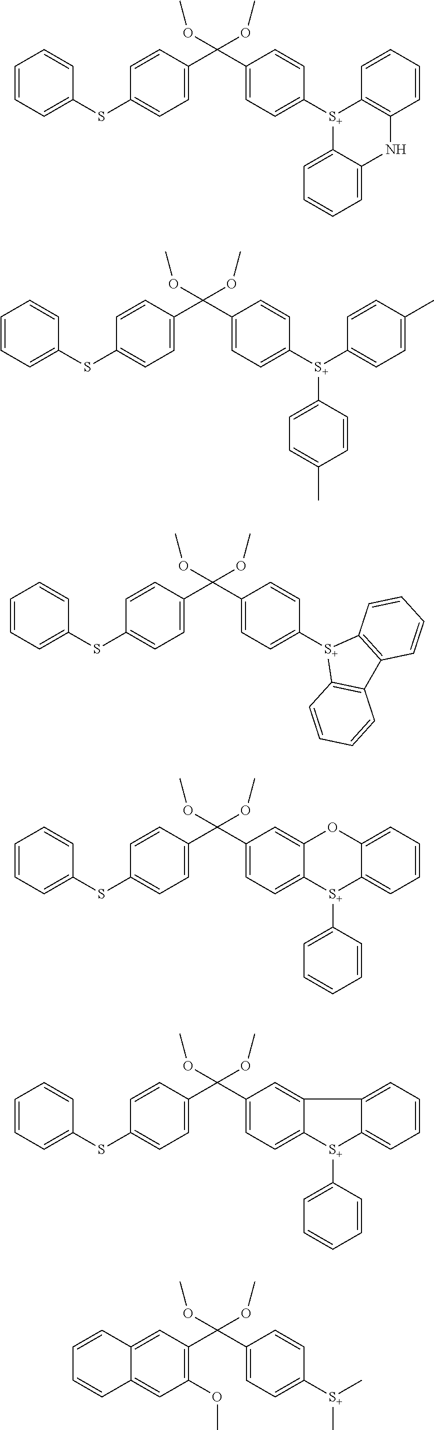 [SMILES: COC(OC)(c1ccc(Sc2ccccc2)cc1)c1ccc([S+]2c3ccccc3Nc3ccccc32)cc1 ; COC(OC)(c1ccc(Sc2ccccc2)cc1)c1ccc([S+](c2ccc(C)cc2)c2ccc(C)cc2)cc1 ; COC(OC)(c1ccc(Sc2ccccc2)cc1)c1ccc(-[s+]2c3ccccc3c3ccccc32)cc1 ; COC(OC)(c1ccc(Sc2ccccc2)cc1)c1ccc2c(c1)Oc1ccccc1[S+]2c1ccccc1 ; COC(OC)(c1ccc(Sc2ccccc2)cc1)c1ccc2c(c1)c1ccccc1[s+]2-c1ccccc1 ; COc1cc2ccccc2cc1C(OC)(OC)c1ccc([S+](C)C)cc1]

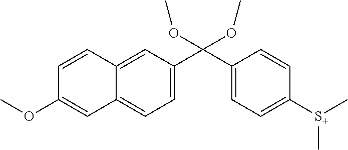

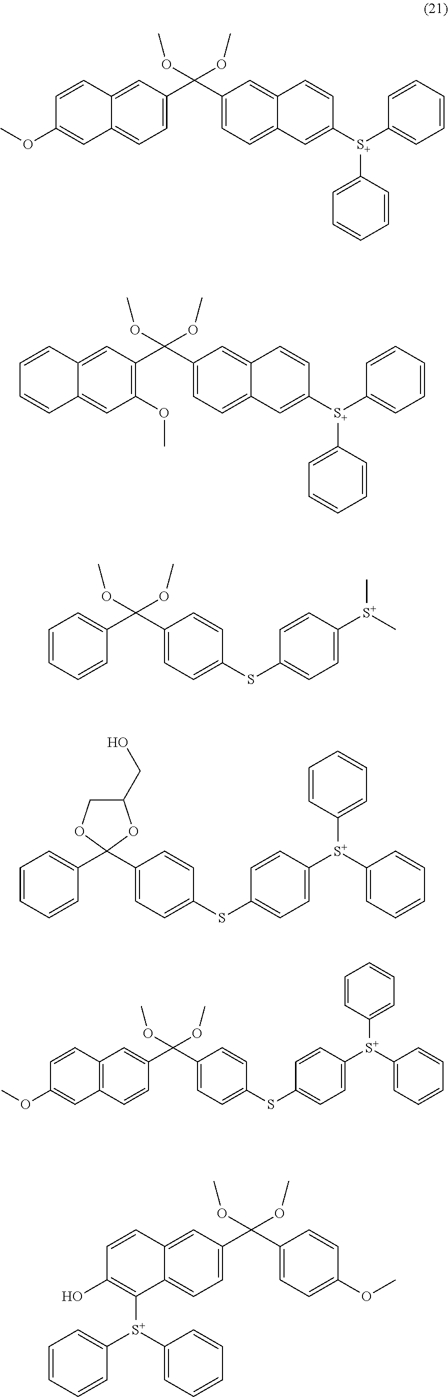

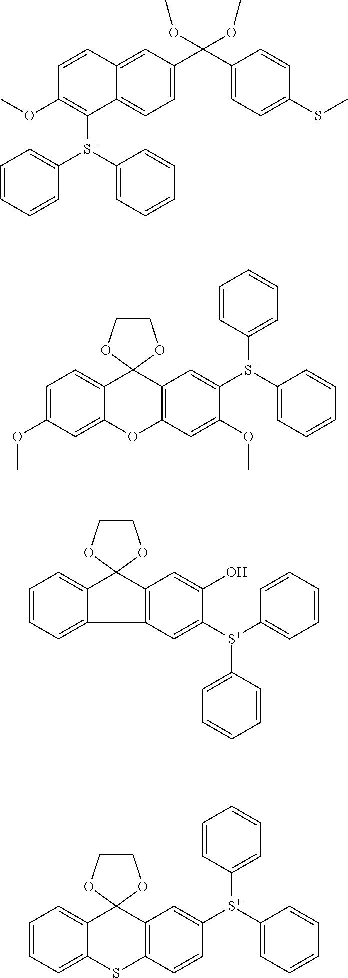 [SMILES: COc1ccc2cc(C(OC)(OC)c3ccc(SC)cc3)ccc2c1[S+](c1ccccc1)c1ccccc1 ; COc1ccc2c(c1)Oc1cc(OC)c([S+](c3ccccc3)c3ccccc3)cc1C21OCCO1 ; Oc1cc2c(cc1[S+](c1ccccc1)c1ccccc1)-c1ccccc1C21OCCO1 ; c1ccc([S+](c2ccccc2)c2ccc3c(c2)C2(OCCO2)c2ccccc2S3)cc1]

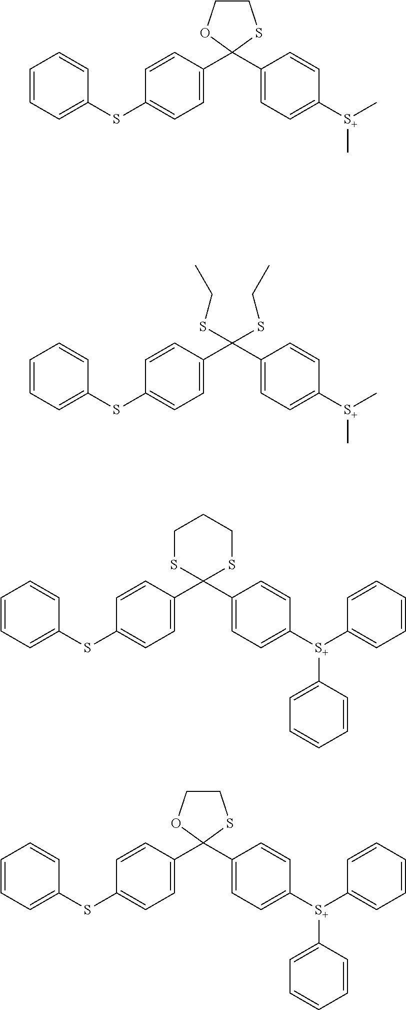 [SMILES: C[S+](C)c1ccc(C2(c3ccc(Sc4ccccc4)cc3)OCCS2)cc1 ; CCSC(SCC)(c1ccc(Sc2ccccc2)cc1)c1ccc([S+](C)C)cc1 ; c1ccc(Sc2ccc(C3(c4ccc([S+](c5ccccc5)c5ccccc5)cc4)SCCCS3)cc2)cc1 ; c1ccc(Sc2ccc(C3(c4ccc([S+](c5ccccc5)c5ccccc5)cc4)OCCS3)cc2)cc1]

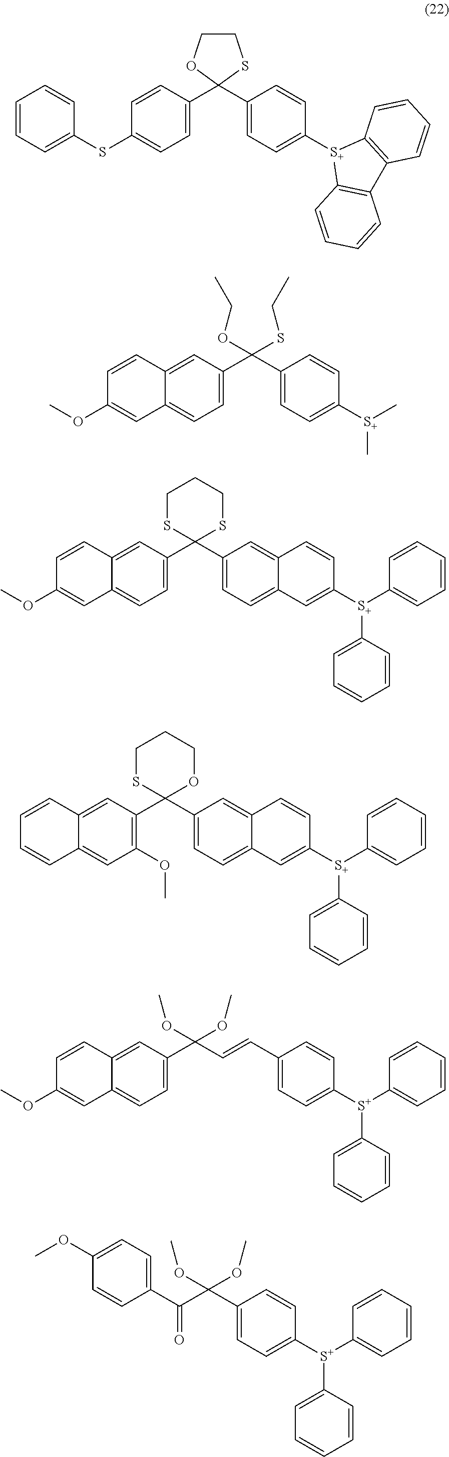

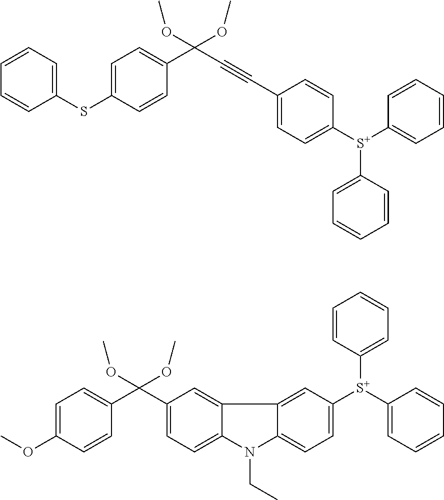 [SMILES: COC(C#Cc1ccc([S+](c2ccccc2)c2ccccc2)cc1)(OC)c1ccc(Sc2ccccc2)cc1 ; CCn1c2ccc([S+](c3ccccc3)c3ccccc3)cc2c2cc(C(OC)(OC)c3ccc(OC)cc3)ccc21]

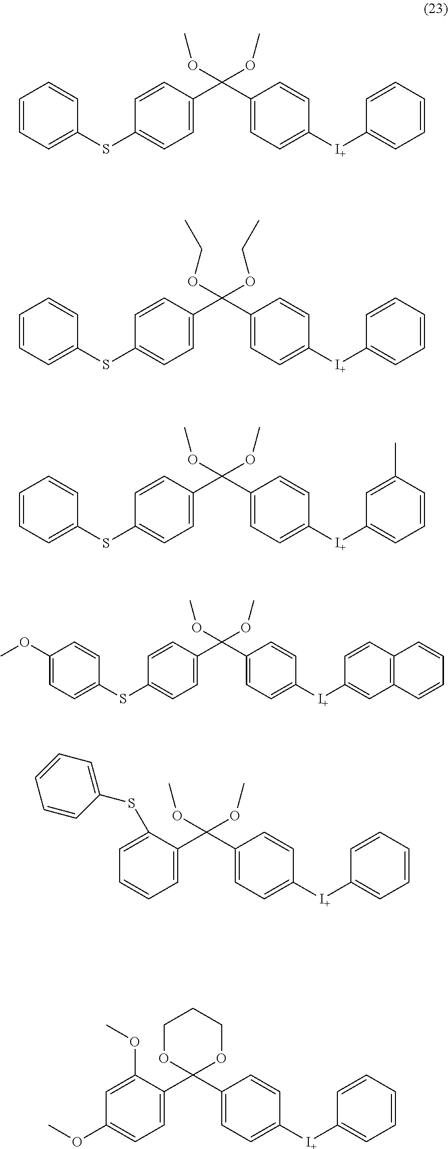 [SMILES: COC(OC)(c1ccc(Sc2ccccc2)cc1)c1ccc([I+]c2ccccc2)cc1 ; CCOC(OCC)(c1ccc(Sc2ccccc2)cc1)c1ccc([I+]c2ccccc2)cc1 ; COC(OC)(c1ccc(Sc2ccccc2)cc1)c1ccc([I+]c2cccc(C)c2)cc1 ; COc1ccc(Sc2ccc(C(OC)(OC)c3ccc([I+]c4ccc5ccccc5c4)cc3)cc2)cc1 ; COC(OC)(c1ccc([I+]c2ccccc2)cc1)c1ccccc1Sc1ccccc1 ; COc1ccc(C2(c3ccc([I+]c4ccccc4)cc3)OCCCO2)c(OC)c1]

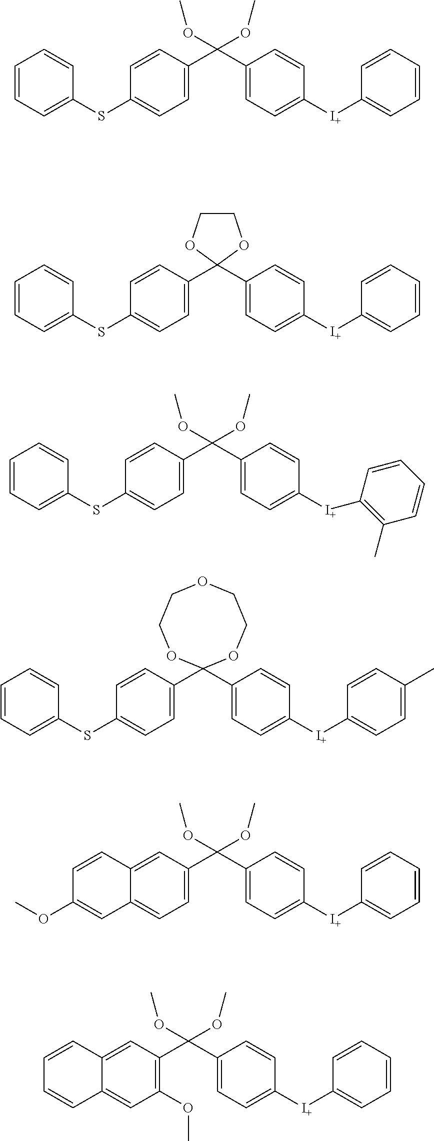

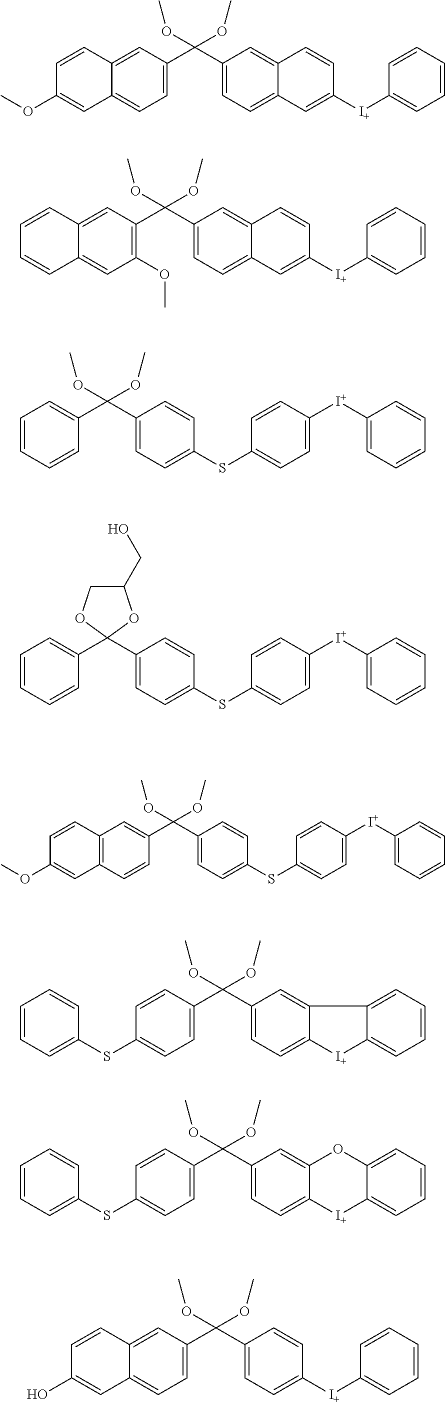

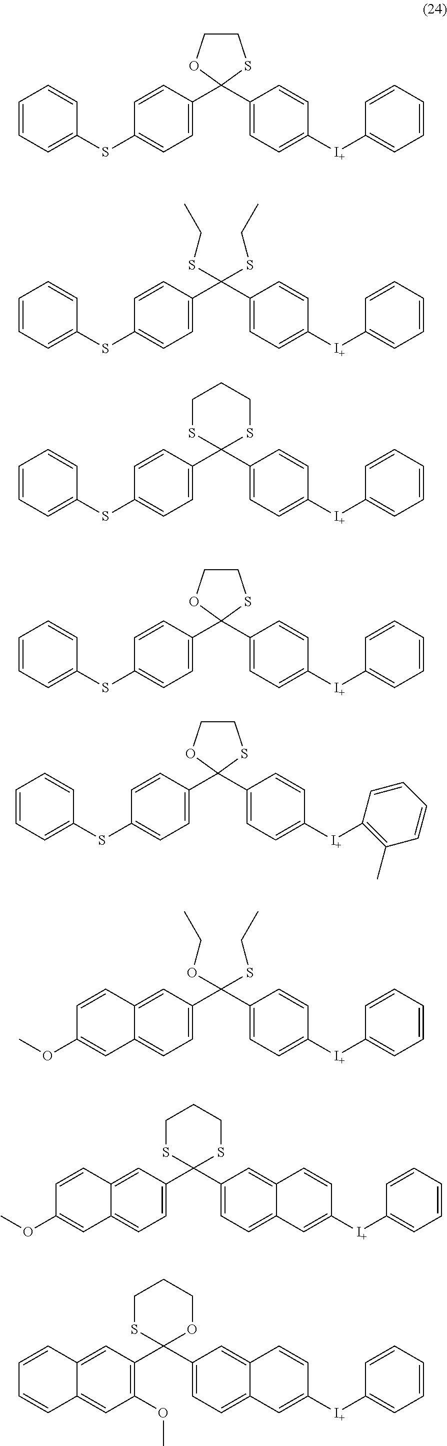

An aspect of the present disclosure, a sulfonium salt represented by the following chemical formula (25) is preferable.

PGPubs, use the Gap Bulletin per PTO.

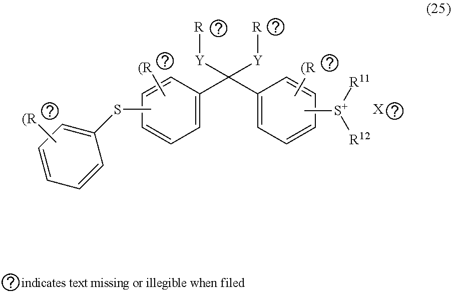

R¹¹ to R¹⁶, A⁻, and Y in the above chemical formula (25) are each independently selected from the same options as in R¹¹ to R¹⁶, A⁻, and Y in the above chemical formula (15), respectively.

R¹⁸ may be any one selected from the group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom, wherein when R¹⁸ has carbon, R¹⁸ may have 1 to 12 carbon atoms and may have a substituent.

In addition, e is an integer of 0 to 4, f is an integer of 0 to 4, and g is an integer of 0 to 5.

A⁻ is a monovalent counter anion excluding X⁻ in the above chemical formulas (9) to (12). The anion is not particularly limited, and examples thereof may include anions, such as a sulfonate anion, a carboxylate anion, an imide anion, a methide anion, a carbon anion, a borate anion, a halogen anion, a phosphate anion, an antimonate anion, or an arsenate anion.

More specifically, examples of the anion may include an anion represented by ZA^{a-}, (Rf)_{b}PF_{(6-b)}⁻, R¹⁹_{c}BA_{(4-c)}⁻, R¹⁹_{c}GaA_{(4-c)}⁻, R²⁰SO₃⁻, (R²⁰SO₂)₃C⁻, or (R²⁰SO₂)₂N⁻. When the numbers of Rf, R¹⁹, and R²⁰ are 2 or greater, two Rf's, two R¹⁹'s, and two R²⁰'s may bind to each other to form rings, respectively.

Z represents a phosphorous atom, a boron atom, or an antimony atom. A represents a halogen atom (preferably, a fluorine atom). P represents a phosphorus atom, F represents a fluorine atom, B represents a boron atom, and Ga represents a gallium atom. S represents a sulfur atom, O represents an oxygen atom, C represents a carbon atom, and N represents a nitrogen atom.

Rf may be an alkyl group in which 80 mol % or more of hydrogen atoms are substituted with fluorine atoms. The alkyl group may be an alkyl group of 1 to 8 carbon atoms. Examples of the alkyl group having fluorine substitution represented by Rf may include linear alkyl groups (methyl, ethyl, propyl, butyl, pentyl, octyl, etc), branched alkyl groups (isopropyl, isobutyl, sec-butyl, tert-butyl, etc.), and cycloalkyl groups (cyclopropyl, cyclobutyl, cyclopentyl, cyclohexyl, etc). As for Rf, the proportion of hydrogen atoms substituted with fluorine atoms in these alkyl groups may be 80 mol % or more, specifically 90% or more, more specifically 100%, on the basis of the mole number of hydrogen atoms in the original alkyl group.

Specific examples of Rf may include CF₃⁻, CF₃CF2⁻, (CF₃)₂CF⁻, CF₃CF₂CF₂⁻, CF₃CF₂CF₂CF₂⁻, (CF₃)₂CFCF₂⁻, CF₃CF₂(CF₃)CF⁻, and (CF₃)₃C⁻. The b Rf's are each independent from each other, and therefore may be identical to or different from each other.

R¹⁹ represents a phenyl group in which a part of hydrogen atoms are substituted with at least one halogen atom or electron attractive group. Examples of the halogen atom may include a fluorine atom, a chlorine atom, and a bromine atom. Examples of the electron attractive group include a trifluoromethyl group, a nitro group, and a cyano group. Of these, a phenyl group in which one hydrogen atom is substituted with the fluorine atom or the trifluoromethyl group is preferable. The c Rf's are each independent from each other, and therefore may be identical to or different from each other.

R²° represents an alkyl group of 1 to 20 carbon atoms in which a part or all of hydrogen atoms may be substituted with a fluorine atom, or an aryl group of 6 to 20 carbon atoms. The alkyl group may be any of a linear, branched, or cyclic form. The aryl group may be unsubstituted or may have a substituent.

In addition, a represents an integer of 4 to 6. b represents an integer of 1 to 5, specifically 2 to 4, more specifically 2 or 3. c represents an integer of 1 to 4, specifically 4. Examples of the anion represented by ZA; may include anions, such as SbF6, PF6 and BF₄⁻.

Examples of the anion represented by (Rf)_{b}PF_{(6-b)}⁻ may include anions, such as (CF₃CF₂)₂PF₄⁻, (CF₃CF₂)₃PF₃⁻, ((CF₃)₂CF)₂PF₄⁻, ((CF₃)₂CF)₃PF₃⁻, (CF₃CF₂CF₂)₂PF₄⁻, (CF₃CF₂CF₂)₃PF₃⁻, ((CF₃)₂CFCF₂)₂PF₄⁻, ((CF₃)₂CFCF₂)₃PF₃⁻, (CF₃CF₂CF₂CF₂)₂PF₄⁻, and (CF₃CF₂CF₂CF₂)₃PF₃⁻. Of these, anions such as (CF₃CF₂)₃PF₃⁻, (CF₃CF₂CF₂)₃PF₃⁻, ((CF₃)₂CF)₃PF₃⁻, ((CF₃)₂CF)₂PF₄⁻, ((CF₃)₂CFCF₂)₃PF₃⁻, and ((CF₃)₂CFCF₂)₂PF₄⁻, are preferable.

Examples of the anion represented by R¹⁹_{c}BA_{(4-c)}⁻ may include anions, such as (C₆F₅)₄B⁻, ((CF₃)₂C₆H₃)₄B⁻, (CF₃C₆H₄)₄B⁻, (C₆F₅)₂BF₂⁻, C₆F₅BF₃⁻, and (C₆H₃F₂)₄B⁻. Of these, anions, such as (C₆F₅)₄B⁻ and ((CF₃)₂C₆H₃)₄B⁻, are preferable.

Examples of the anion represented by R¹⁹_{c}GaA_{(4-c)}⁻ may include anions, such as (C₆F₅)₄Ga⁻, ((CF₃)₂C₆H₃)₄Ga⁻, (CF₃C₆H₄)₄Ga⁻, (C₆F₅)₂GaF₂⁻, C₆F₅GaF₃⁻, and (C₆H₃F₂)₄Ga⁻. Of these, anions, such as (C₆F₅)₄Ga⁻ and ((CF₃)₂C₆H₃)₄Ga⁻, are preferable.

Examples of the anion represented by R²⁰SO₃⁻ may include a trifluoromethanesulfonate anion, a pentafluoroethanesulfonate anion, a heptafluoropropanesulfonate anion, a nonafluorobutanesulfonate anion, a pentafluorophenylsulfonate anion, a p-toluenesulfonate anion, a benzenesulfonate anion, a camphorsulfonate anion, a methanesulfonate anion, an ethanesulfonate anion, a propanesulfonate anion, and a butanesulfonate anion. Of these, the trifluoromethanesulfonate anion, the nonafluorobutanesulfonate anion, the methanesulfonate anion, the butanesulfonate anion, the benzenesulfonate anion, and the p-toluenesulfonate anion are preferable.

Examples of the anion represented by (R²⁰SO₂)₃C⁻ may include anions, such as (CF₃SO₂)₃C⁻, (C₂F₅SO₂)₃C⁻, (C₃F₇SO₂)₃C⁻, and (C₄F₉SO₂)₃C⁻.

Examples of the anion represented by (R²⁰SO₂)₂N⁻ may include anions, such as (CF₃SO₂)₂N⁻, (C₂F₅ SO₂)₂N⁻, (C₃F₇SO₂)₂N⁻, and (C₄F₉SO₂)₂N⁻. In addition, a cyclic imide in which portions corresponding to two (R²⁰SO₂)'s are joined to each other to form a cyclic structure may also be an example of the anion represented by (R²⁰SO₂)₂N⁻.

In addition to the above anions, perhalogenate ions (ClO₄⁻, BrO₄⁻, etc), halogenated sulfuonate ions (FSO₃⁻, ClSO₃⁻, etc), sulfonate ions (CH₃SO₄⁻, CF₃SO₄⁻, HSO₄⁻, etc), carbonate ions (HCO₃⁻, CH₃CO₃⁻, etc), aluminate ions (AlCl₄⁻, AlF₄⁻, etc), hexafluoro bismuthate ion (BiF6⁻), carboxylate ions (CH₃COO⁻, CF₃COO⁻, C₆H₅COO⁻, CH₃C₆H₄COO⁻, C₆F₅COO⁻, CF₃C₆H₄COO⁻, etc), aryl borate ions (B(C₆H₅)₄⁻, CH₃CH₂CH₂CH₂B(C₆H₅)₃⁻, etc), thiocyanate ion (SCN⁻), and nitrate ion (NO₃⁻) may be used as a monovalent anion.

These anions may have a substituent. Examples of the substituent may include an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom. Of these, the sulfonate anion, the carboxylate anion, and the like are preferable.

An onium salt according to an aspect of the present disclosure is an aspect of the quencher, and may be a quencher unit-containing resin, of which an anion part is bound to a portion of the polymer. Examples of such an onium salt may include resins in which A⁻ in the above chemical formulas (15), (16), (17), and (18) has a unit represented by the following chemical formula (26). The onium salt is contained as one unit of the quencher unit-containing resin in the composition, thereby suppressing the diffusion of an acid generated upon the exposure and thus inhibiting LWR.

In addition, the unit represented by the following chemical formula (26) may be contained in the resin (B) or may be contained in a resin different from the resin (B).

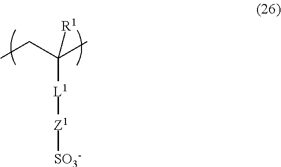

In the above chemical formula (26), R¹ may be any one selected from the group consisting of: a hydrogen atom, an alkyl group and a halogenated alkyl group. L¹ may be any one selected from the group consisting of: a direct bond; a linear, branched, or cyclic alkylene carbonyloxy group which may have a carbonyloxy group, a carbonylamino group and a substituent; and an alkylene carbonylamino group.

Z¹ is a linear or branched alkyl group of 1 to 12 carbon atoms, a linear or branched alkenyl group of 1 to 12 carbon atoms, and a linear or branched aryl group of 6 to 14 carbon atoms. In addition, a part or all of hydrogen atoms of these alkyl, alkenyl group, and aryl groups may be substituted with a fluorine atom. Of these groups, at least one methylene group may be substituted with a divalent heteroatom-containing group.

Examples of the anion part represented by the above chemical formula (26) may be shown in the following chemical formulas (26-1) and (26-2). However, the present disclosure is not limited thereto.

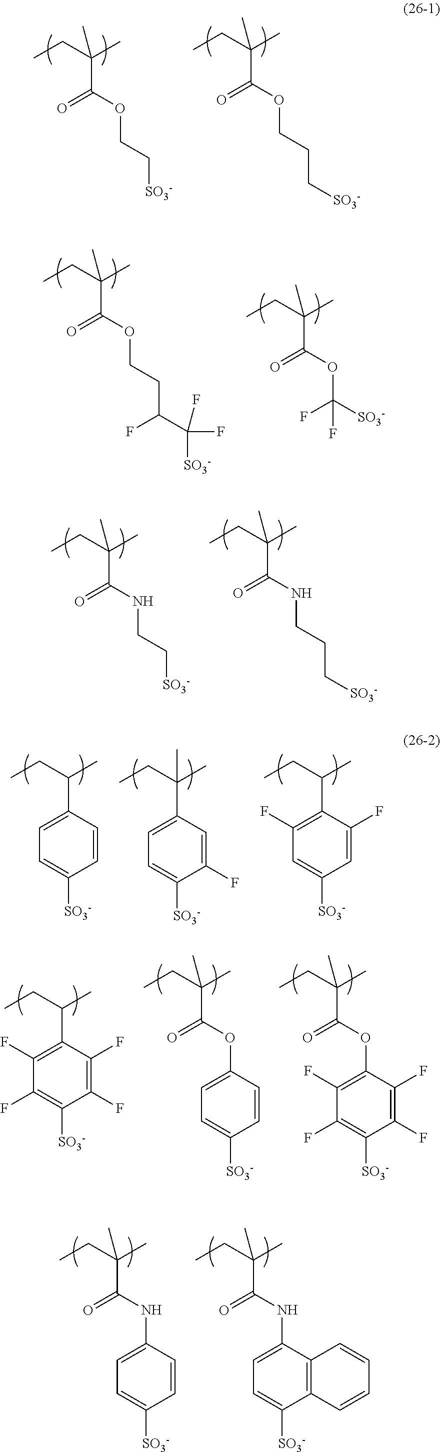

An onium salt according to several aspects of the present disclosure may have a molar absorption coefficient of less than 1.0×10⁵ cm²/mol, specifically less than 1.0×10⁴cm²/mol, at a wavelength of 365 nm.

In the above chemical formulas (15) to (18), the atom groups composed of R¹⁵, R¹⁶ and respective Y's may be each independently acetal or thioacetal, but particularly limited thereto.

Specifically, in a case where the onium compound contained in the quencher is the above-described onium salt, a ketone derivative in which acetal or thioacetal of the respective onium salt is deprotected may have a molar absorption coefficient nm of 1.0×10⁵ cm²/mol or more, specifically 1.0×10⁶ cm²/mol or more, at a wavelength of 365 nm.

The molar absorption coefficient of the ketone derivative at 365 nm may be 5 times or more, specifically 10 times or more, more specifically 20 times, the molar absorption coefficient of the onium salt according to several aspects of the present disclosure.

For the above characteristics, the onium salt represented by the above chemical formula (15), (16), (17), or (18) is preferable. In addition, the onium compound contained in the quencher is not limited to the above-described onium salts. That is, in a case where an onium salt is used as the onium compound contained in the quencher, an iodonium salt may be used without limitation to the above-described sulfonium salt.

The synthesis method for the onium salt is not particularly limited, but for example, the synthesis method for onium salts (sulfonium salt and iodonium salt) disclosed in PCT Publication No. WO2018/074382 may be applied thereto.

The content of the quencher in the resist composition according to the present embodiment may be 1 to 40 parts by mass, specifically 2 to 30 parts by mass, more specifically 3 to 15 parts by mass, relative to 100 parts by mass of the resist composition excluding the respective quencher.

In the calculation of the content of the quencher, an organic solvent (solvating media) is not contained in 100 parts by mass of the resist composition. In a case where the quencher is contained as one unit in the resin. That is, in a case where the quencher is a polymer component, the calculation of the content is based on the mass excluding the main chain of the polymer.

In the resist composition according to the present embodiment, a polymer component and a low-molecular-weight component may be used alone or in combination of two or more thereof or may be used in combination with other quenchers, as the quencher. In the resist composition, the quencher may be substituted as a part of the polymer component.

Examples of the other quenchers besides the quencher containing the onium salt may include a universal ionic quencher and a non-ionic quencher. Examples of the ionic quencher may include onium compounds, such as the aforementioned other iodonium and sulfonium salts. Examples of the non-ionic quencher may include an N-sulfonyloxyimide compound, an oxime sulfonate compound, an organic halogen compound, and a sulfonyl diazomethane compound.

In a case where the resist composition includes a quencher besides the quencher containing the onium salt, the content thereof may be 0.1 to 50 parts by mass relative to 100 parts by mass of the resist composition excluding the total amount of the quencher.

In addition, the resist composition according to the present embodiment includes a typical solvent (organic solvent, etc), in addition to the polymer component, the acid-generating agent, and the quencher. The resist composition may further include a radiation-sensitive sensitizing agent, a radical trapping agent, a cross-linking agent, a surface-activating agent, a stabilizing agent, a pigment, other additive agents, and the like.

In the resist composition according to the present embodiment, as described above, when at least one of the acid-generating agent and the quencher is irradiated with the first radiation and not irradiated with the second radiation, the light absorption wavelength thereof is shifted so as to absorb the second radiation. In addition, the at least one of the acid-generating agent and the quencher is decomposed when irradiated with the first radiation and then irradiated with the second radiation. In addition, the at least one of the acid-generating agent and the quencher is not decomposed when not irradiated with the first radiation and then irradiated with the second radiation.

Therefore, the resist composition according to the present embodiment is exposed to the first radiation (EUV, etc) and thus can form a latent image of a resist pattern with high resolution and favorable roughness (excellent lithographic performance). In addition, an exposed portion by the first radiation is exposed to the second radiation with a higher output, thereby increasing exposure efficiency, which makes it possible to shorten the exposure time. Therefore, according to the present embodiment, a resist pattern can be developed while suppressing the resolution of the latent image and the roughness from being degraded. Thus, high sensitivity and excellent lithographic performance are obtained.

In the resist composition according to the present embodiment, as described above, at least one of the acid-generating agent and the quencher has increased polarity by the action of an acid, and thus has increased solubility in a hydrophilic developer, such as an organic alkali solution, and decreased solubility in a hydrophobic developer, such as an organic solvent. Therefore, higher sensitivity and superior lithographic performance are obtained by either positive or negative developer.

In the resist composition according to the present embodiment, the acid-generating agent generates an acid when irradiated with the first radiation, and does not generate an acid when not irradiated with the first radiation and irradiated with the second radiation. Therefore, the acid-generating agent can be surely decomposed when irradiated with the first radiation and then irradiated with the second radiation, and is not surely decomposed when irradiated with the first radiation and not irradiated with the second radiation. Therefore, according to the present embodiment, a resist pattern can be developed while the degradation of latent image resolution and roughness is suppressed.

In the resist composition according to the present embodiment, as described above, the acid-generating agent contains an onium compound, which is transformed into a carbonyl compound when irradiated with the first radiation, so that the respective onium compound can be transformed into a carbonyl compound when the acid-generating agent is irradiated with only the first radiation. Therefore, the acid-generating agent surely has increased polarity, and thus surely has increased solubility in a hydrophilic developer, such as an organic alkali solution, and decreased solubility in a hydrophobic developer, such as an organic solvent.

In the resist composition according to the present embodiment, the onium compound contained in the acid-generating agent includes a compound represented by any one selected from the above chemical formulas (9), (10), (11), and (12), so that the onium compound can be surely transformed into a carbonyl compound when the acid-generating agent is irradiated with only the first radiation. Therefore, the polarity of the acid-generating agent can be surely increased in the resist composition according to the present embodiment.

In the compounds of the above chemical formulas (9) to (12), as described above, in a case wherein the atom groups composed of R¹⁵, R¹⁶, and respective Y's are each independently acetal or thioacetal, the acetal or thioacetal can be transformed into ketone when the acid- generating agent is irradiated with only the first radiation. Due to that, in the resist composition according to the present embodiment, the polarity of the acid-generating agent can be more surely increased.

In addition, in the resist composition according to the present embodiment, the quencher loses basicity for acid when irradiated with the first radiation, and maintains basicity for acid when not irradiated with the first radiation and irradiated with the second radiation. Therefore, according to the present embodiment, a resist pattern can be developed while the degradation of latent image resolution and roughness is suppressed.

In the resist composition according to the present embodiment, as described above, the quencher contains an onium compound, which is transformed into a carbonyl compound when irradiated with the first radiation, so that the respective onium compound can be transformed into a carbonyl compound when the quencher is irradiated with only the first radiation. Therefore, the quencher surely has increased polarity, and thus surely has increased solubility in a hydrophilic developer, such as an organic alkali solution, and decreased solubility in a hydrophobic developer, such as an organic solvent.

In the resist composition according to the present embodiment, the onium compound contained in the quencher includes a compound represented by any one selected from the above chemical formulas (15), (16), (17), and (18), so that the onium compound can be surely transformed into a carbonyl compound when the quencher is irradiated with only the first radiation. Therefore, the polarity of the quencher can be surely increased in the resist composition according to the present embodiment.

In the above chemical formulas (15) to (18), in a case wherein the atom groups composed of R¹⁵, R¹⁶, and respective Y's are each independently acetal or thioacetal, the acetal or thioacetal can be transformed into ketone when the acid-generating agent is irradiated with only the first radiation. Thus, in the resist composition according to the present embodiment, the polarity of the quencher can be surely increased.

### <Resist Pattern Forming Method>

The aforementioned resist composition is suitably used for a two-stage exposure lithography process. That is, a lithography process (resist pattern forming method) accoridng to the present embodiment includes: a film formation step of forming a resist film obtained by using the resist composition on a substrate; a pattern exposure step of irradiating the resist film with the first radiation via a mask; a one-shot exposure step of irradiating the resist film after the pattern exposure step with the second radiation; a baking step of heating the resist film after the one-shot exposure step; and a developing step of bringing the resist film after the baking step into contact with a developer.

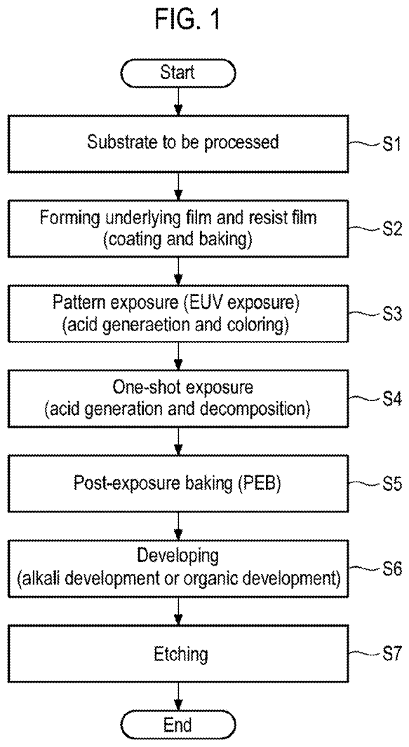

FIG. 1 is a flowchart showing the lithography process according to the present embodiment.

As shown in FIG. 1, the lithography process according to the present embodiment includes the following steps:

Step S1: Step of preparing a substrate to be processed

Step S2: Step of forming an underlying film and a resist film (film formation step)

Step S3: Step of generating an acid in an exposed portion by pattern exposure (pattern exposure step)

Step S4: Step of increasing the acid only in the pattern-exposed portion by one-shot exposure (one-shot exposure step).

Step S5: Step of inducing a polarity change reaction by an acid catalyst in the pattern-exposed portion by post-exposure baking (baking step)

Step S6: Step of forming a resist pattern by development treatment (developing step)

Step S7: Step of transferring the pattern by etching (etching step)

### (Step S1)

In the following steps, the substrate as a workpiece (substrate to be processed) may be composed of semiconductor wafers, such as a silicon substrate, a silicon dioxide substrate, a glass substrate, and an ITO substrate. An insulating layer may be formed on the semiconductor wafer.

### (Step S2: Film Formation Step)

The resist film is formed using the resist material of the present embodiment. Examples of the method of forming the resist film may include a method of coating a liquid resist material through spin coating or the like, and a method of laminating a film-like (solid) resist material. In the case of coating the liquid resist material, the liquid resist material may be heated (pre-baked) after coating, thereby volatilizing the solvent in the resist material. The conditions for forming the resist film may be appropriately selected according to the properties of the resist material, the thickness of the resist film to be obtained, and the like. The average thickness of the resist film may be 1 to 5,000 nm, specifically 10 to 1,000 nm, more specifically 30 to 200 nm.

Before the resist film is formed on the substrate, an underlying film (an antireflection film, a film for resist adhesion enhancement, a film for resist shape improvement, etc) may be formed on the substrate. The formation of the antireflection film can suppress the occurrence of standing waves which results from the reflection of radiation from the substrate or the like during the pattern exposure step. The formation of the film for resist adhesion enhancement can enhance the adhesion between the substrate and the resist film. The formation of the film for resist shape improvement can further improve the shape of resist after development. That is, the formation of the film for resist shape improvement can reduce a slack or contractile shape of the resist.

In order to prevent deterioration in resist shape due to the occurrence of standing waves of the radiation for one-shot exposure, the thickness of the underlying film may be designed to also suppress the reflection of the radiation for one-shot exposure. The underlying film may be a film that does not absorb the radiation for one-shot exposure. For example, in a case where the underlying film absorbs the radiation for one-shot exposure, a radiation sensitization reaction occurs in the resist film by energy transfer or electromigration from the underlying film, and thus an acid may be generated in a pattern-unexposed portion. Therefore, a buffer layer that does not transmit the radiation sensitization reaction may be disposed between the resist film and the underlying film, thereby preventing the sensitization from the underlying film absorbing the radiation.

A protective film may be further formed on the resist film. The formation of the protective film can inhibit the deactivation of acids and reaction intermediates thereof generated in the pattern exposure step S3, thereby improving the process stability. In order to prevent an acid generation reaction in the unexposed portion in the one-shot exposure step, the protective film may be an absorption film which absorbs at least a portion of the wavelength of the non-ionizing radiation directly absorbed by the polymer component or the acid-generating agent. The use of the absorption film inhibits the entrance of an out-of-band light (OOB light) into the resist film, thereby preventing the decomposition of a radiation-sensitive acid-generating agent or a radiation-sensitive acid-generating group in the pattern-unexposed portion, wherein the OOB light is the radiation of the ultraviolet region generated at the time of EUV exposure. In the case where the absorption film is formed directly on the resist film, in order to inhibit the generation of an acid in the resist film, which is caused by the radiation sensitization reaction in the pattern-unexposed portion, no radiation sensitization reaction may be induced from the protective film by the wavelength of the second radiation during the one-shot exposure step. By forming the absorption film on the resist film after the pattern exposure step S3 before the one-shot exposure step S4, it is possible to further inhibit an acid from being directly generated from the radiation-sensitive acid-generating agent or the radiation-sensitive acid-generating group remaining in the resist film after the pattern exposing step S3 by the irradiation of the second radiation in the one-shot exposure step S4.

### (Step S3: Pattern Exposure Step)

In the pattern exposure step S3, a light-shielding mask with a predetermined pattern is disposed on the resist film formed in the film formation step S2. Thereafter, the resist film is irradiated (pattern-exposed) with the first radiation, via the mask, from an exposure apparatus (radiation irradiating module) having a projector lens, an electro-optical system mirror, or a reflection mirror.

The first radiation used in the pattern exposure is an ionizing radiation or a non-ionizing radiation having a wavelength of 250 nm or less. The upper limit of the wavelength of the non-ionizing radiation is 250 nm, specifically 200 nm. The lower limit of the wavelength of the non-ionizing radiation may be 150 nm, specifically 190 nm.

In addition, the ionizing radiation is a radiation having sufficient energy to ionize an atom or molecule. On the other hand, the non-ionizing radiation is a radiation that does not have sufficient energy to ionize an atom or molecule. Examples of the ionizing radiation may include gamma ray, X-ray, alpha ray, a heavy particle beam, a proton beam, beta ray, an ion beam, an electron beam, and EUV. The ionizing radiation used in the pattern exposure may be an electron beam, EUV, and an ion beam, more specifically the electron beam and the EUV. Examples of the non-ionizing radiation may include non-ionizing radiations having a wavelength of 250 nm or less, such as KrF excimer laser light and ArF excimer laser light.

As a light source for the pattern exposure, for example, an electron beam of 1 to 200 keV, EUV having a wavelength of 13.5 nm, 139-nm excimer laser light (ArF excimer laser light), or 248-nm excimer laser light (KrF excimer laser light) may be frequently used. The exposure amount in the pattern exposure may be smaller than that in a case of one-shot exposure using a chemically-amplified resist of the present embodiment. The acid-generating agent in the resist film is decomposed by the pattern exposure, thereby generating an acid.

For exposure, a step-and-scan exposure apparatus called “scanner” is widely used. In this method, a pattern of each shot is formed by performing scan-exposure on the mask and the substrate in synchronization. This exposure induces a selective reaction in exposed sites in the resist.

Before the one-shot exposure step S4 below is performed, an absorption film, which absorbs at least a portion of the wavelength of the non-ionizing radiation directly absorbed by the radiation-sensitive acid-generating agent among the acid-generating agents, may be formed on the resist film in the pattern exposure step S3. The formation of the absorption film can further inhibit the direct generation of the acid from the radiation-sensitive acid-generating agent or the radiation-sensitive acid-generating group remaining in the resist film after the pattern exposure step S3, through the irradiation of the second radiation in the one-shot exposure step S4 below.

The resist pattern forming method of the present embodiment may further include a step of transferring the substrate from the exposure apparatus performing the pattern exposure step S3 to an exposure apparatus for performing the one-shot exposure step S4 below, after the pattern exposure step S3 and before the one-shot exposure step S4 below. In addition, the one-shot exposure may be carried out in coating-developing apparatuses connected to each other in an in-line manner or in a module corresponding to an interface with an exposure device.

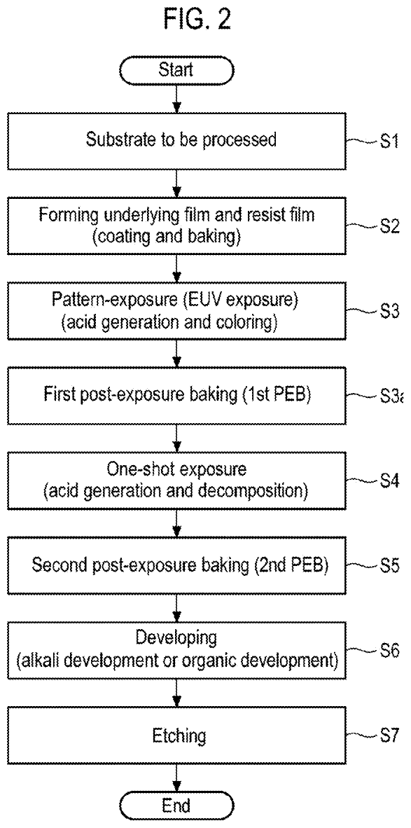

In a case where the acid-generating agent contains a ketal compound, an acetal compound, or an ortho-ester compound, the resist pattern forming method of the present embodiment may include a baking step S3 a (also referred to as post-pattern exposure baking (PPEB or PEB)) after the pattern exposure step S3 and before the one-shot exposure step S4 (see FIG. 2). A heating temperature in the baking step may be 30 to 150 degrees C., specifically 50 to 120 degrees C., more specifically 60 to 100 degrees C. A heating time in the baking step may be 5 seconds to 3 minutes, specifically 10 to 60 seconds. In addition, the baking may be performed under a humidity-controlled environment.

### (Step S4: One-shot Exposure Step)

In the one-shot exposure step S4, the entire surface (entire surface encompassing the pattern-exposed portion and the pattern-unexposed portion) of the resist film after the pattern exposure step S3 is irradiated with the second radiation (one-shot exposure) from a high-sensitivity module (also referred to as an exposure apparatus or a radiation-irradiating module) having a projector lens (or a light source). As for the one-shot exposure, the whole wafer surface may be exposed at once, by a combination of local exposures, or by overlapping exposure. As a light source for the one-shot exposure, a general light source may be used, and not only ultraviolet radiation from a mercury lamp, a xenon lamp, or the like, which are controlled to have a desired wavelength by passing through a band pass filter or a cutoff filter, but also narrowband ultraviolet radiation from an LED light source, a laser diode, a laser light source, or the like may be also favorable. In the one-shot exposure, only the acid-generating agent, of which the light absorption wavelength is shifted so as to absorb the second radiation in the pattern-exposed portion of the resist film, absorbs radiation. Therefore, in the one-shot exposure, selective absorption of radiation occurs in the pattern-exposed portion. Accordingly, during the one-shot exposure, an acid can be continuously generated only in the pattern-exposed portion, and thus the sensitivity can be significantly improved. On the other hand, no acid is generated in the pattern-unexposed portion, and thus the sensitivity can be improved while the chemical contrast in the resist film is maintained.

The second radiation used in the one-shot exposure is a non-ionizing radiation, which has a longer wavelength than that of the non-ionizing radiation in the first radiation and has a wavelength exceeding 250 nm. The second radiation may be a near-infrared radiation (having a wavelength of 250 to 450 nm).

In the one-shot exposure step S4, a radiation having a wavelength longer than that of the radiation which can be absorbed by the acid-generating agent, needs to be exposed to inhibit an acid generation reaction in the pattern-unexposed portion. Considering these facts, the lower limit of the wavelength of the non-ionizing radiation in the one-shot exposure may be 280 nm, specifically 320 nm. In a case of an acid-generating agent that can absorb radiation with a longer wavelength, the wavelength of the non-ionizing radiation may be 350 nm or more. However, when the wavelength of the non-ionizing radiation is too long, the efficiency of the radiation sensitization reaction is reduced, and therefore, a non-ionizing radiation having a wavelength as short as possible absorbable by the acid-generating agent while avoiding the wavelength absorbable by the acid-generating agent may be used. In this respect, the upper limit of the wavelength of the non-ionizing radiation may be 450 nm, specifically 400 nm.

The pattern exposure step S3 and/or the one-shot exposure step S4 may be performed by immersion lithography (immersion exposure) or dry lithography (dry exposure). The immersion lithography refers to an exposure performed in a state where a liquid is interposed between a resist film and a projector lens. In contrast, the dry lithography refers to an exposure performed in a state where a gas is interposed between a resist film and a projector lens, under a reduced pressure, or in a vacuum.

In addition, the immersion lithography in the pattern exposure step S3 and/or the one-shot exposure step S4 may be performed in a state where a liquid having a refractive index of 1.0 or greater is interposed between the projector lens and the resist film or the protective film formed in the film formation step S2. The protective film may be used in preventing reflection or improving reaction stability. The protective film may prevent the infiltration of a liquid, increase water repellency on the film surface, thus preventing defects resulting from a liquid in the immersion exposure.

In the immersion lithography in the one-shot exposure step S4, the liquid may absorb at least a portion of the wavelength of the second radiation directly absorbed by the acid-generating agent. The use of the liquid in the immersion lithography can further inhibit the direct generation of an acid from the acid-generating agent remaining in the resist film after the pattern exposure step S3, through the irradiation of the second radiation in the one-shot exposure step S4.

In a case where the pattern exposure step S3 and/or the one-shot exposure step S4 are performed by the dry lithography, the dry lithography may be performed either under a reduced- pressure atmosphere or under an inert atmosphere, in the air. Specifically, the dry lithography may be performed under a reduced-pressure atmosphere or under an inert atmosphere containing nitrogen or argon. Furthermore, the upper limit of the basic compound in an atmosphere when the dry lithography may be 20 ppb, specifically 5ppb, more specifically 1 ppb.

### (Step S5: Baking Step)

In the baking step S5, the resist film after the one-shot exposure step S4 is heated (hereinafter, also referred to as “post-flood exposure baking (PFEB)” or “post-exposure baking (PEB)”). In some cases, when the resist pattern forming method of the present embodiment includes the baking step S3a after the pattern exposure step S3 and before the one-shot exposure step S4, the baking step S3a will be referred to as a first post-exposure baking step (1st PEB step) and the baking step S5 will be referred to as a second post-exposure baking step (2nd PEB step) (see FIG. 2).

Heating conditions used in the baking step S5 may be 50 to 200 degrees C., 10 to 300 seconds under an atmosphere of an inert gas, such as nitrogen or argon, in the air. By setting the heating conditions to the above ranges, the diffusion of an acid can be controlled and the processing rate of the semiconductor wafer can also be ensured. In the baking step S5, a cross-linking reaction and a polarity change reaction, such as a deprotection reaction of the polymer component, occurs by the acid generated in the pattern exposure step S3 and the one-shot exposure step S4. In some cases, sidewalls of the resist may be corrugated due to the influence of the standing waves of the radiation in the resist film, but in the baking step S5, the corrugation can be suppressed by the diffusion of reactants.

### (Step S6: Developing Step)

In the developing step S6, the resist film after the baking step S5 is brought into contact with a developer. The development is performed using the fact that the solubility in the developer is selectively changed in the pattern-exposed portion due to a reaction in the resist film in the baking step S5, so that a resist pattern is formed. The developer may be classified into a positive developer and a negative developer.

The positive developer may be an alkaline developer. The alkaline developer selectively dissolves a highly polar portion of the resist film after exposure. Examples of the alkaline developer may include potassium hydroxide, sodium hydroxide, sodium carbonate, potassium carbonate, sodium phosphate, sodium silicate, ammonia, amines (ethanolamine, etc), and tetraalkyl ammonium hydroxide (TAAH). Specifically, the alkaline developer may be TAAH. Examples of TAAH include tetramethyl ammonium hydroxide (TMAH), tetraethyl ammonium hydroxide, tetrapropyl ammonium hydroxide, tetrabutyl ammonium hydroxide, methyltriethyl ammonium hydroxide, trimethylethyl ammonium hydroxide, dimethyldiethyl ammonium hydroxide, trimethyl(2-hydroxyethyl)ammonium hydroxide (i.e., choline), triethyl(2-hydroxyethyl)ammonium hydroxide, dimethyldi(2-hydroxyethyl)ammonium hydroxide, diethyldi(2-hydroxyethyl)ammonium hydroxide, methyltri(2-hydroxyethyl)ammonium hydroxide, ethyltri(2-hydroxyethyl)ammonium hydroxide, and tetra(2-hydroxyethyl)ammonium hydroxide.

As the positive developer, an aqueous solution of 2.38 mass % of tetramethyl ammonium hydroxide (TMAH) is widely used.

In the alkaline development, a pattern is formed using a phenomenon that carboxylic acid or a hydroxyl group generated in the resist film after exposure is ionized to dissolve in an alkaline developer. After the development, a water washing treatment called rinsing is performed to remove the developer remaining on the substrate.

The negative developer may be an organic developer. The organic developer selectively dissolves a low polar portion of the resist film after the exposure. The organic developer is used for improving the resolution performance and process window through punching patterns, such as holes or trenches (grooves). In such a case, a dissolution contrast between the pattern-exposed portion and the pattern-unexposed portion is obtained due to a difference in affinity for the solvent in the resist film and the organic developer. A high polar portion remains as a resist pattern due to low solubility in the organic developer. Examples of the organic developer include 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, amyl acetate, butenyl acetate, isoamyl acetate, propyl formate, butyl formate, isobutyl formate, amyl formate, isoamyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, amyl lactate, isoamyl lactate, methyl 2-hydroxy isobutyrate, ethyl 2-hydroxy isobutyrate, methyl benzoate, ethyl benzoate, phenyl acetate, benzyl acetate, phenylmethyl acetate, benzyl formate, phenylethyl formate, 3-phenylmethyl propionate, benzyl propionate, phenylethyl acetate, and 2-phenylethyl acetate.

The resist pattern after the developing step S6 (including the rinsing treatment) is heated (also referred to as post-baking). Through the post-baking, the rinsing solution remaining after the rinsing treatment can be removed by evaporation, and the resist pattern can be cured.

### (Step S7 )

In the step S7, the substrate as a base is subjected to etching or ion injection by using the resist pattern after the developing step S6 as a mask, thereby forming a pattern. The etching may be dry etching under an atmosphere of plasma excitation or the like, or may be wet etching in which the substrate is dipped into a chemical solution. After the pattern is formed on the substrate by etching, the resist pattern is removed.

The resist pattern forming method of the present embodiment includes the pattern exposure step S3 and the one-shot exposure step S4, and thus can drastically increase the acid generated after exposure in only the pattern-exposed portion.

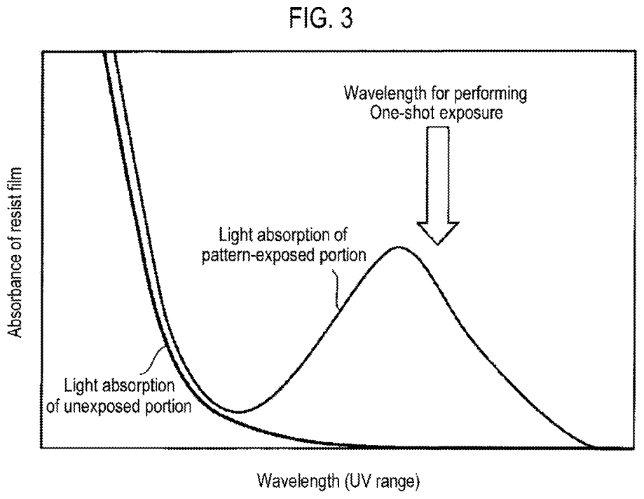

FIG. 3 is a graph showing the absorptivity of the pattern-exposed portion and the absorptivity of the unexposed portion in the resist film at the time of one-shot exposure. A portion in which the pattern is not exposed in the resist film (pattern-unexposed portion) shows an absorption of an ultraviolet radiation having a relatively short wavelength, but no absorption of an ultraviolet radiation having a relatively long wavelength. In a portion in which the pattern is exposed in the resist film (pattern-exposed portion), the light absorption wavelength of the acid-generating agent is shifted so as to absorb the second radiation, and thus an acid is generated, as described above. The acid-generating agent having a shifted light absorption wavelength absorbs a non-ionizing radiation having a wavelength exceeding 300 nm, showing an absorption of an ultraviolet radiation having a relatively long wavelength. In the one-shot exposure, the entire surface of the resist film is irradiated with a radiation without using a mask, unlike in the pattern exposure, but the pattern-unexposed portion absorbs little the second radiation in the one-shot exposure step S4. Therefore, in the one-shot exposure step S4, an acid generation reaction mainly occurs in the pattern-exposed portion. Accordingly, an acid can be continuously generated only in the pattern-exposed portion during the one-shot exposure, and thus the sensitivity can be improved while lithography characteristics are maintained.

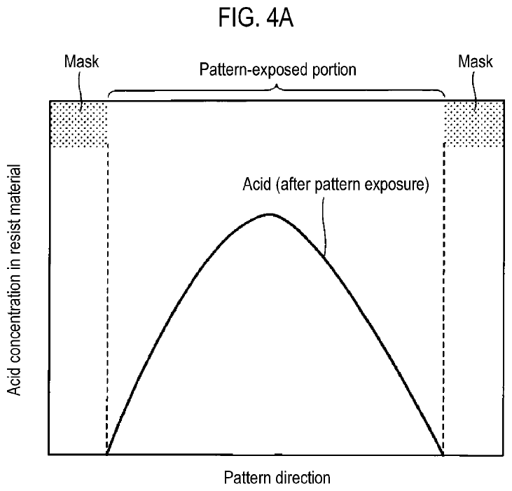

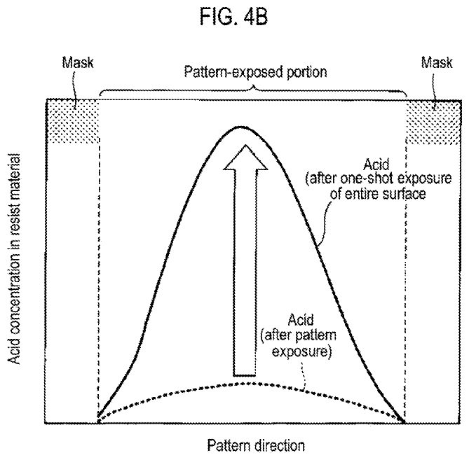

FIG. 4A is a schematic conceptual view graphically showing an acid concentration distribution by a resist pattern forming method using a conventional resist composition. In a case where only pattern exposure is performed using EUV or the like, an acid cannot be sufficiently generated, resulting in a reduction in sensitivity. If the exposure amount is increased to improve the sensitivity, a latent image of the resist pattern deteriorates (deterioration of lithography characteristics), so that both the sensitivity and the lithography characteristics are difficult to improve. FIG. 4B is a schematic conceptual view graphically showing an acid concentration distribution by the resist pattern forming method using the resist composition according to the present embodiment. In the pattern exposure, a latent image of the resist pattern is excellent, but an acid is not sufficiently generated. However, after the one-shot exposure, the amount of acid can be increased only in the pattern-exposed portion by the acid-generating agent, of which the light absorption wavelength is shifted by the pattern exposure, thereby improving the sensitivity even using a small exposure amount while maintaining an excellent latent image of the resist pattern. Since the acid generation mechanism by the acid-generating agent at the time of the one-shot exposure operates at room temperature, the blurring of the latent image at the time of generating an acid can be reduced, thereby achieving significantly high sensitivity while maintaining resolution.

As described above, according to the resist pattern forming method of the present embodiment, a resist pattern can be developed while the degradation of resolution and roughness is suppressed, and thus high sensitivity and excellent lithographic performance are obtained.

Furthermore, in the resist pattern forming method according to the present embodiment, the baking step S3 a is performed after the pattern exposure step S3 and before the one-shot exposure step S4 (see FIG. 2), so that a latent image of the resist pattern with high resolution and favorable roughness (excellent lithographic performance) can be surely formed through the exposure of the first radiation (EUV or the like). Therefore, according to the resist pattern forming method of the present embodiment, a resist pattern can be developed while the degradation of latent image resolution and roughness is surely suppressed.

### <Semiconductor Device>

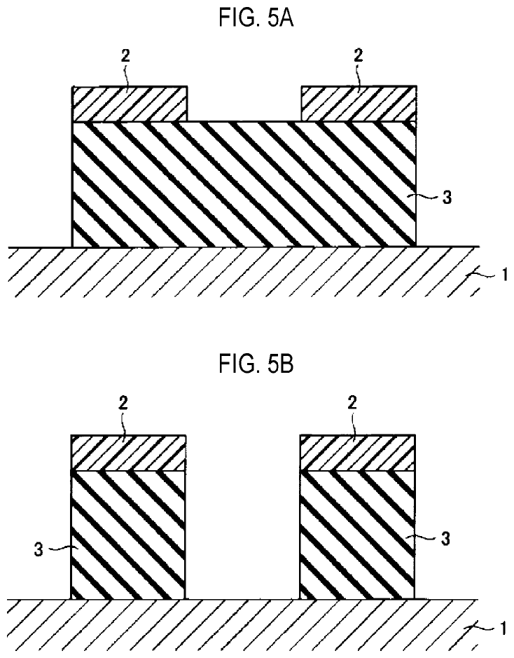

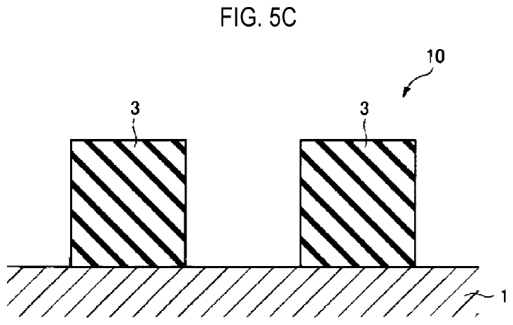

A semiconductor device according to the present embodiment is manufactured using the pattern formed by the above-described method. FIGS. 5A to 5C show cross-sectional views illustrating an example of a semiconductor device manufacturing process of the present embodiment.

FIG. 5A is a cross-sectional view showing a resist pattern forming step, which illustrates a semiconductor wafer 1, an etching target film 3 formed on the semiconductor wafer 1, and a resist pattern 2 formed on the etching target film 3 by the resist pattern forming method (the cross-sectional view corresponds to a state after the developing step S6). Examples of the etching target film may include an active layer, an underlying insulating film, a gate electrode film, and an upperlying insulating film. Between the etching target film 3 and the resist pattern 2, an antireflection film, an underlying film for resist adhesion enhancement, and an underlying film for resist shape improvement may be provided. A multilayer-mask structure may also be employed. FIG. 5B is a cross-sectional view showing an etching step, which illustrates the semiconductor wafer 1, the resist pattern 2, and the etching target film 3 which is etched using the resist pattern 2 as a mask. The etching target film 3 is etched in conformity to the shape of an opening portion of the resist pattern 2. FIG. 5C is a cross-sectional view of a patterned substrate 10 including the semiconductor wafer 1 and a pattern of the etching target film 3 which is etched after the removal of the resist pattern 2.

A semiconductor device can be formed using a substrate including the pattern of the etching target film 3. The method of forming the semiconductor device may include embedding a wiring between the patterns of the etching target film 3 from which the resist pattern 2 has been removed, and stacking a device element on the substrate.

### <Mask for Lithography>

A mask for lithography according to the present embodiment is manufactured by processing a substrate through the use of the resist pattern formed by the aforementioned method. A method of manufacturing the mask for lithography may include etching a surface of a glass substrate or a hard mask formed on the surface of the glass substrate using the resist pattern. The mask for lithography includes a transmission-type mask using ultraviolet radiation or electron beams, a reflection-type mask using EUV light, and the like. In a case where the mask for lithography is a transmission-type mask, the transmission-type mask can be manufactured by masking a light-shielded portion or a phase shift portion with the resist pattern, followed by etching. In a case where the mask for lithography is a reflection-type mask, the reflection-type mask can be manufactured by processing a light-absorbing body through etching by using the resist pattern as a mask.

### <Template for Nanoimprinting>

A template for nanoimprint according to the present embodiment may also be manufactured using the resist pattern formed by the aforementioned method. A method of manufacturing the template for nanoimprint may include forming a resist pattern on a surface of a glass substrate or a surface of a hard mask formed on the surface of the glass substrate, and processing the resist pattern by etching.

According to the present disclosure in some embodiments, it is possible to provide a resist composition and a resist pattern forming method, whereby high sensitivity and good lithographic performance are obtained even when a radiation, such as EUV, is used as an exposure light.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A resist composition comprising:
a polymer component that is capable of being made soluble or insoluble in a developer by an action of an acid;
an acid-generating agent configured to generate the acid by an exposure; and
a quencher having a basicity for the acid,
wherein, with respect to a first radiation having a wavelength of 300 nm or less and a second radiation having a wavelength of more than 300 nm, at least one of the acid-generating agent and the quencher has a light absorption wavelength, which is shifted so as to absorb the second radiation when irradiated with the first radiation and not irradiated with the second radiation, is decomposed when irradiated with the first radiation and then irradiated with second irradiation, and is not decomposed when not irradiated with the first irradiation and irradiated with the second radiation.

2. The resist composition of claim 1, wherein the at least one of the acid-generating agent and the quencher has a polarity, which is increased by the action of the acid.

3. The resist composition of claim 2, wherein the acid-generating agent generates the acid when irradiated with the first radiation, and generates no acid when not irradiated with the first radiation and irradiated with the second radiation.

4. The resist composition of claim 3, wherein the acid-generating agent includes an onium compound, which is transformed into a carbonyl compound when irradiated with the first radiation.

5. The resist composition of claim 4, wherein the onium compound includes a compound represented by any one selected from the following chemical formulas (11), (12), (13), and (14), 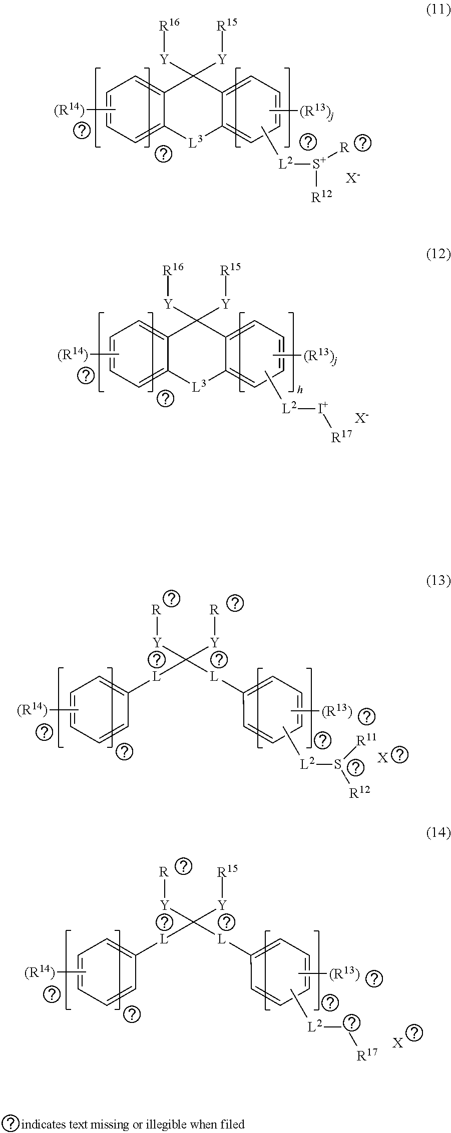
wherein in the chemical formula (11),
R¹¹ and R¹² each independently represent any one selected from the group consisting of: a linear, branched, or cyclic alkyl group of 1 to 12 carbon atoms which has a substituent; a linear, branched, or cyclic alkenyl group of 1 to 12 carbon atoms which has a substituent; an aryl group of 6 to 14 carbon atoms which has a substituent; and a heteroaryl group of 4 to 12 carbon atoms which has a substituent,
at least two of R¹¹, R¹², and the aryl group to which a sulfonium group is bound are directly joined to each other by a single bond, or are joined to each other via any one selected from a group consisting of an oxygen atom, a sulfur atom, a nitrogen atom-containing group, and a methylene group to form a cyclic structure, together with the sulfur atom to which they are bound,
a methylene group, represented by at least one of R¹¹ and R¹², is substituted with a bivalent heteroatom-containing group,
R¹³ and R¹⁴ each independently represent at least one selected from a group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom, wherein when each of R¹³ and R¹⁴ has a carbon atom, each of R¹³ and R¹⁴ has 1 to 12 carbon atoms and has a substituent,
R¹⁵ and R¹⁶ each independently represent any one selected from the group consisting of: a linear, branched, or cyclic alkyl group of 1 to 12 carbon atoms which has a substituent; a linear, branched, or cyclic alkenyl group of 1 to 12 carbon atoms which has a substituent; the aryl group of 6 to 14 carbon atoms which has a substituent; and a heteroaryl group of 4 to 12 carbon atoms which has a substituent,
R¹⁵ and R¹⁶ are directly joined to each other by a single bond, or are joined to each other via any one selected from the group consisting of an oxygen atom, a sulfur atom, and an alkylene group to form a cyclic structure,
a methylene group, represented by at least one of R¹⁵ and R¹⁶, is substituted with a bivalent heteroatom-containing group,
L² represents any one selected from groups consisting of: a direct bond; a linear, branched, or cyclic alkylene group of 1 to 12 carbon atoms; an alkenylene group of 1 to 12 carbon atoms; an arylene group of 6 to 14 carbon atoms; a heteroarylene group of 4 to 12 carbon atoms; and groups to which the groups are bound to each other via an oxygen atom, a sulfur atom, or a nitrogen atom-containing group,
L³ is selected from a group consisting of a direct bond, a methylene group, a sulfur atom, a nitrogen atom-containing group, and an oxygen atom,
Y represents an oxygen atom or a sulfur atom,
h and i each independently represent an integer of 1 to 3,
j represents an integer of 0 to 4 when h is 1, an integer of 0 to 6 when h is 2, or an integer of 0 to 8 when h is 3,
k represents an integer of 0 to 5 when i is 1, an integer of 0 to 7 when h is 2, or an integer of 0 to 9 when h is 3,
X⁻ represents a monovalent counter anion,
R¹³ to R¹⁶, L², L³, Y, h to k, and X⁻ in the chemical formula (10) are each independently selected from same options as in R¹³ to R¹⁶, L², L³, Y, h to k, and X⁻ in the chemical formula (11), and
R¹⁷ represents any one selected from the group consisting of: an aryl group which has a substituent; and a heteroaryl group which has a substituent, wherein R¹⁷ and an aryl group to which an iodonium group is bound are joined to each other to form a cyclic structure, together with an iodine atom to which they are bound;
wherein in the chemical formula (13),
R¹¹ to R¹⁶, L², Y, h to k, and X⁻ are each independently selected from same options as in R¹¹ to R¹⁶, L², Y, h to k, and X⁻ in the chemical formula (11), and L⁴ and L⁵ each independently represent any one selected from a group consisting of a direct bond, an alkenylene group of 2 carbon atoms, an alkylene group of 2 carbon atoms, and a carbonyl group; and
wherein in the chemical formula (14),
R¹³ to R¹⁷, L², Y, h to k, and X⁻ are each independently selected from same options as in R¹³ to R¹⁷, L², Y, h to k, and X⁻ in the chemical formula (12), and L⁴ and L⁵ each independently represent any one selected from a group consisting of a direct bond, an alkenylene group of 2 carbon atoms, an alkynylene group of 2 carbon atoms, and a carbonyl group.

6. The resist composition of claim 5, wherein in the chemical formulas (11) to (14), atom groups composed of R¹⁵, R¹⁶, and respective Y's each independently represent an acetal or a thioacetal.

7. The resist composition of claim 6, wherein the quencher loses the basicity for the acid when irradiated with the first radiation, and maintains the basicity for the acid when not irradiated with the first radiation and irradiated with the second radiation.

8. The resist composition of claim 7, wherein the quencher includes an onium compound, which is transformed into a carbonyl compound when irradiated with the first radiation.

9. The resist composition of claim 8, wherein the onium compound comprises a compound represented by any one selected from the above chemical formulas (21), (22), (23), and (24): 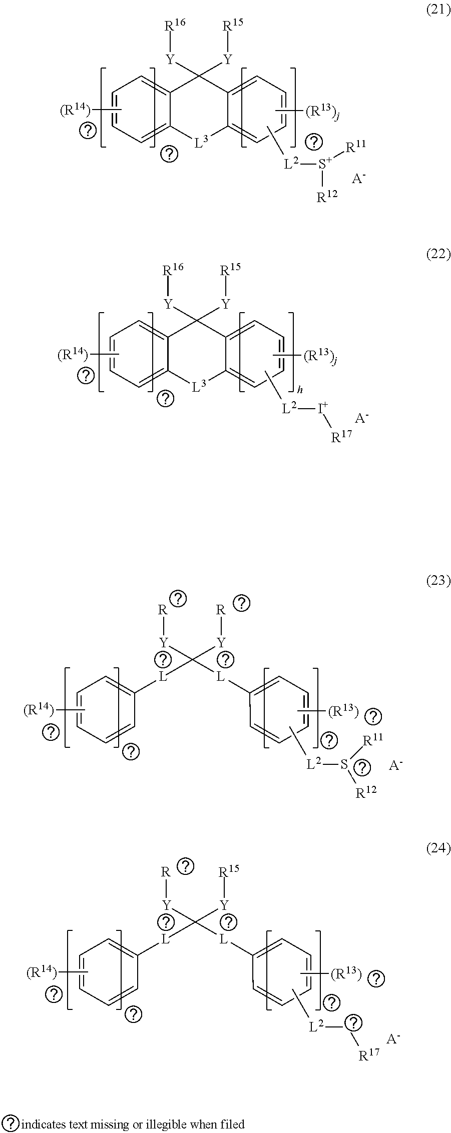
wherein in the above chemical formula (21),
R¹¹ and R¹² each independently represent any one selected from the group consisting of: a linear, branched, or cyclic alkyl group of 1 to 12 carbon atoms which has a substituent; a linear, branched, or cyclic alkenyl group of 1 to 12 carbon atoms which has a substituent; an aryl group of 6 to 14 carbon atoms which has a substituent; and a heteroaryl group of 4 to 12 carbon atoms which has a substituent,
at least two of R¹¹, R¹², and the aryl group to which a sulfonium group is bound are directly joined to each other by a single bond, or are joined to each other via any one selected from a group consisting of an oxygen atom, a sulfur atom, a nitrogen atom-containing group, and a methylene group to form a cyclic structure, together with the sulfur atom to which they are bound,
a methylene group, represented by at least one of R¹¹ and R¹², is substituted with a bivalent heteroatom-containing group,
R¹³ and R¹⁴ each independently represent at least one selected from a group consisting of an alkyl group, a hydroxy group, a mercapto group, an alkoxy group, an alkylcarbonyl group, an arylcarbonyl group, an alkoxycarbonyl group, an aryloxycarbonyl group, an arylsulfanylcarbonyl group, an arylsulfanyl group, an alkylsulfanyl group, an aryl group, a heteroaryl group, an aryloxy group, an alkylsulfinyl group, an arylsulfinyl group, an alkylsulfonyl group, an arylsulfonyl group, a (meth)acryloyloxy group, a hydroxy(poly)alkyleneoxy group, an amino group, a cyano group, a nitro group, and a halogen atom, wherein when each of R¹³ and R¹⁴ has a carbon atom, each of R¹³ and R¹⁴ has 1 to 12 carbon atoms and has a substituent,
R¹⁵ and R¹⁶ each independently represent any one selected from the group consisting of: a linear, branched, or cyclic alkyl group of 1 to 12 carbon atoms which has a substituent; a linear, branched, or cyclic alkenyl group of 1 to 12 carbon atoms which has a substituent; the aryl group of 6 to 14 carbon atoms which has a substituent; and a heteroaryl group of 4 to 12 carbon atoms which has a substituent,
R¹⁵ and R¹⁶ are directly joined to each other by a single bond, or are joined to each other via any one selected from the group consisting of an oxygen atom, a sulfur atom, and an alkylene group to form a cyclic structure,
a methylene group, represented by at least one of R¹⁵ and R¹⁶, is substituted with a bivalent heteroatom-containing group,
L² represents any one selected from groups consisting of: a direct bond; a linear, branched, or cyclic alkylene group of 1 to 12 carbon atoms; an alkenylene group of 1 to 12 carbon atoms; an arylene group of 6 to 14 carbon atoms; a heteroarylene group of 4 to 12 carbon atoms; and groups to which the groups are bound to each other via an oxygen atom, a sulfur atom, or a nitrogen atom-containing group,
L³ is selected from a group consisting of a direct bond, a methylene group, a sulfur atom, a nitrogen atom-containing group, and an oxygen atom,
Y represents an oxygen atom or a sulfur atom,
h and i each independently represent an integer of 1 to 3,
j represents an integer of 0 to 4 when h is 1, an integer of 0 to 6 when h is 2, or an integer of 0 to 8 when h is 3,
k represents an integer of 0 to 5 when i is 1, an integer of 0 to 7 when h is 2, or an integer of 0 to 9 when h is 3,
A⁻ represents a monovalent counter anion excluding X⁻ in the chemical formulas (11) to (14),
R¹³ to R¹⁶, L², L³, Y, h to k, and A⁻ in the chemical formula (22) are each independently selected from same options as in R¹³ to R¹⁶, L², L³, Y, h to k, and A⁻ in the chemical formula (21), and
R¹⁷ represents any one selected from the group consisting of: an aryl group which has a substituent; and a heteroaryl group which has a substituent, wherein R¹⁷ and an aryl group to which an iodonium group is bound are joined to each other to form a cyclic structure, together with an iodine atom to which they are bound;
wherein in the chemical formula (23),
R¹¹ to R¹⁶, L², Y, h to k, and A⁻ are each independently selected from same options as in R¹¹ to R¹⁶, L², Y, h to k, and A⁻ in the chemical formula (21), and L⁴ and L⁵ each independently represent any one selected from a group consisting of a direct bond, an alkenylene group of 2 carbon atoms, an alkylene group of 2 carbon atoms, and a carbonyl group; and
wherein in the chemical formula (24),
R¹³ to R¹⁷, L², Y, h to k, and A⁻ are each independently selected from same options as in R¹³ to R¹⁷, L², Y, h to k, and A⁻ in the chemical formula (22), and L⁴ and L⁵ each independently represent any one selected from a group consisting of a direct bond, an alkenylene group of 2 carbon atoms, an alkynylene group of 2 carbon atoms, and a carbonyl group.

10. The resist composition of claim 9, wherein in the chemical formulas (21) to (24), atom groups composed of R¹⁵, R¹⁶, and respective Y's each independently represent an acetal or a thioacetal.

11. The resist composition of claim 1, wherein the acid-generating agent generates the acid when irradiated with the first radiation, and generates no acid when not irradiated with the first radiation and irradiated with the second radiation.

12. The resist composition of claim 1, wherein the acid-generating agent includes an onium compound, which is transformed into a carbonyl compound when irradiated with the first radiation.

13. The resist composition of claim 1, wherein the quencher loses the basicity for the acid when irradiated with the first radiation, and maintains the basicity for the acid when not irradiated with the first radiation and irradiated with the second radiation.

14. The resist composition of claim 1, wherein the quencher includes an onium compound, which is transformed into a carbonyl compound when irradiated with the first radiation.

15. A resist pattern forming method comprising:
a film formation step of forming a resist film on a substrate by using the resist composition of claim 1;
a pattern exposure step of irradiating the resist film with the first radiation;
a one-shot exposure step of irradiating, with the second radiation, the resist film after the pattern exposure step;
a baking step of heating the resist film after the one-shot exposure step; and
a developing step of bringing the resist film after the baking step into contact with a developer.

16. A resist pattern forming method, comprising:
a film formation step of forming a resist film on a substrate by using the resist composition of claim 1;
a pattern exposure step of irradiating the resist film with the first radiation;
a first baking step of heating the resist film after the pattern exposure step;
a one-shot exposure step of irradiating, with the second radiation, the resist film after the first baking step;
a second baking step of heating the resist film after the one-shot exposure step;
a developing step of bringing the resist film after the second baking step into contact with a developer.
